(19) United States
(12) Patent Application Publication
(10) Pub. No.: US 2022/0013545 A1
(43) Pub. Date: Jan. 13, 2022

(54) SEMICONDUCTOR DEVICE, DISPLAY DEVICE, AND ELECTRONIC DEVICE USING THE DISPLAY DEVICE

(71) Applicant: SEMICONDUCTOR ENERGY LABORATORY CO., LTD., Atsugi-shi (JP)

(72) Inventors: Kenichi OKAZAKI, Tochigi (JP); Masami JINTYOU, Shimotsuga (JP); Takahiro IGUCHI, Kanuma (JP); Yasuharu HOSAKA, Tochigi (JP); Junichi KOEZUKA, Tochigi (JP); Hiroyuki MIYAKE, Tochigi (JP); Shunpei YAMAZAKI, Tokyo (JP)

(21) Appl. No.: 17/482,492

(22) Filed: Sep. 23, 2021

Related U.S. Application Data
(63) Continuation of application No. 15/058,354, filed on Mar. 2, 2016.

(30) Foreign Application Priority Data
Mar. 3, 2015 (JP) 2015-040972

(51) Int. Cl. H01L 27/12; H01L 29/786; G02F 1/1368; H01L 29/49; H01L 49/02; G02F 1/1362

(52) U.S. Cl. CPC H01L 27/1255; H01L 29/7869; H01L 27/1225; G02F 1/1368; H01L 29/4908; G02F 2201/40; H01L 28/60; G02F 1/136213; H01L 29/78648; H01L 27/1248; H01L 29/4966

(57) ABSTRACT

Provided is a semiconductor device with high capacitance while the aperture ratio is increased or a semiconductor device whose manufacturing cost is low. The semiconductor device includes a transistor, a first insulating film, and a capacitor including a second insulating film between a pair of electrodes. The transistor includes a gate electrode, a gate insulating film in contact with the gate electrode, a first oxide semiconductor film overlapping with the gate electrode, and a source electrode and a drain electrode electrically connected to the first oxide semiconductor film. One of the pair of electrodes of the capacitor includes a second oxide semiconductor film. The first insulating film is over the first oxide semiconductor film. The second insulating film is over the second oxide semiconductor film so that the second oxide semiconductor film is between the first insulating film and the second insulating film.

### CROSS-REFERENCE TO RELATED APPLICATIONS

This application is a continuation of U.S. application Ser. No. 15/058,354, filed Mar. 2, 2016, now pending, which claims the benefit of a foreign priority application filed in Japan as Serial No. 2015-040972 on Mar. 3, 2015, both of which are incorporated by reference.

### BACKGROUND OF THE INVENTION

### 1. Field of the Invention

The present invention relates to a semiconductor device, a display device, and an electronic device using the display device. One embodiment of the present invention relates to an object, a method, or a manufacturing method. One embodiment of the present invention relates to a process, a machine, manufacture, or a composition of matter. One embodiment of the present invention relates to a semiconductor device, a display device, an electronic device, a manufacturing method thereof, or a driving method thereof. In particular, one embodiment of the present invention relates to a semiconductor device including a transistor and a capacitor, for example.

### 2. Description of the Related Art

Transistors used for most flat panel displays typified by a liquid crystal display device and a light-emitting display device are formed using silicon semiconductors such as amorphous silicon, single crystal silicon, and polycrystalline silicon provided over glass substrates. In addition, such transistors employing such silicon semiconductors are used in integrated circuits (ICs) and the like.

In recent years, attention has been drawn to a technique of fabricating transistors in which a metal oxide exhibiting semiconductor characteristics is used instead of a silicon semiconductor. Note that in this specification, such a metal oxide exhibiting semiconductor characteristics is referred to as an oxide semiconductor. For example, such a technique is disclosed that a transistor is fabricated using zinc oxide or an In—Ga—Zn-based oxide as an oxide semiconductor and the transistor is used as a switching element or the like in a pixel of a display device (see Patent Documents 1 and 2).

### REFERENCE

### Patent Document

[Patent Document 1] Japanese Published Patent Application No. 2007-123861
[Patent Document 2] Japanese Published Patent Application No. 2007-96055

### SUMMARY OF THE INVENTION

It is an object of one embodiment of the present invention to provide a semiconductor device including an oxide semiconductor film having conductivity. It is another object of one embodiment of the present invention to provide a semiconductor device with high capacitance while the aperture ratio is increased. It is another object of one embodiment of the present invention to provide a semiconductor device at low cost. It is another object of one embodiment of the present invention to provide a novel semiconductor device or the like.

Note that the descriptions of these objects do not disturb the existence of other objects. In one embodiment of the present invention, there is no need to achieve all the objects. Other objects will be apparent from and can be derived from the description of the specification, the drawings, the claims, and the like.

One embodiment of the present invention is a semiconductor device including a transistor, a first insulating film, and a capacitor including a second insulating film between a pair of electrodes. The transistor includes a gate electrode, a gate insulating film in contact with the gate electrode, a first oxide semiconductor film overlapping with the gate electrode, and a source electrode and a drain electrode electrically connected to the first oxide semiconductor film. One of the pair of electrodes of the capacitor includes a second oxide semiconductor film. The first insulating film is over the first oxide semiconductor film. The second insulating film is over the second oxide semiconductor film so that the second oxide semiconductor film is between the first insulating film and the second insulating film.

Another embodiment of the present invention is the semiconductor device further including a conductive film and in which the other of the pair of electrodes of the capacitor includes the conductive film.

Another embodiment of the present invention is the semiconductor device in which the transistor includes the first insulating film and the second oxide semiconductor film overlapping with the first oxide semiconductor film.

Another embodiment of the present invention is the semiconductor device in which the transistor includes the first insulating film, the second insulating film, and the conductive film overlapping with the first oxide semiconductor film.

Another embodiment of the present invention is the semiconductor device in which the capacitor transmits visible light.

In the semiconductor device, each of the first oxide semiconductor film and the second oxide semiconductor film is preferably an In-M-Zn oxide where M is any of Al, Ti, Ga, Y, Zr, La, Ce, Nd, Sn, and Hf.

In the semiconductor device, the first insulating film and the second insulating film preferably contain oxygen and hydrogen.

Another embodiment of the present invention is a display device including the semiconductor device and a liquid crystal element.

Another embodiment of the present invention is an electronic device including the semiconductor device and at least one of a switch, a speaker, a display portion, and a housing.

According to one embodiment of the present invention, a semiconductor device including an oxide semiconductor film having conductivity is provided. According to one embodiment of the present invention, a semiconductor device with high capacitance while the aperture ratio is increased is provided. According to one embodiment of the present invention, a semiconductor device is provided at low cost. According to one embodiment of the present invention, a novel semiconductor device or the like is provided.

Note that the description of these effects does not disturb the existence of other effects. One embodiment of the present invention does not necessarily achieve all the effects listed above. Other effects will be apparent from and can be derived from the description of the specification, the drawings, the claims, and the like.

### BRIEF DESCRIPTION OF THE DRAWINGS

FIGS. 1A and 1B are a top view and a cross-sectional view illustrating a semiconductor device according to one embodiment.

FIGS. 2A and 2B are cross-sectional views each illustrating a semiconductor device according to one embodiment.

FIGS. 3A to 3D are cross-sectional views illustrating a method for manufacturing the semiconductor device according to one embodiment.

FIGS. 4A to 4C are cross-sectional views illustrating the method for manufacturing the semiconductor device according to one embodiment.

FIGS. 5A to 5C are cross-sectional views illustrating the method for manufacturing the semiconductor device according to one embodiment.

FIGS. 6A and 6B are cross-sectional views illustrating the method for manufacturing the semiconductor device according to one embodiment.

FIGS. 7A and 7B are a top view and a cross-sectional view illustrating a semiconductor device according to one embodiment.

FIGS. 8A to 8D are cross-sectional views illustrating the method for manufacturing the semiconductor device according to one embodiment.

FIGS. 9A to 9C are cross-sectional views illustrating the method for manufacturing the semiconductor device according to one embodiment.

FIGS. 10A and 10B are a top view and a cross-sectional view illustrating a semiconductor device according to one embodiment.

FIGS. 11A to 11D are cross-sectional views illustrating a method for manufacturing the semiconductor device according to one embodiment.

FIGS. 12A to 12C are cross-sectional views illustrating the method for manufacturing the semiconductor device according to one embodiment.

FIGS. 13A to 13D are Cs-corrected high-resolution TEM images of a cross section of a CAAC-OS and a cross-sectional schematic view of a CAAC-OS.

FIGS. 14A to 14D are Cs-corrected high-resolution TEM images of a plane of a CAAC-OS.

FIGS. 15A to 15C show structural analysis of a CAAC-OS and a single crystal oxide semiconductor by XRD.

FIGS. 16A and 16B show electron diffraction patterns of a CAAC-OS.

FIG. 17 shows a change of crystal parts of an In-Ga—Zn oxide owing to electron irradiation.

FIG. 18 illustrates a deposition method of a CAAC-OS.

FIGS. 19A to 19C illustrate a crystal of InMZnO₄.

FIGS. 20A to 20F illustrate a deposition mechanism of a CAAC-OS.

FIGS. 21A to 21C are a top view and cross-sectional views illustrating a transistor example.

FIGS. 22A to 22D are cross-sectional views each illustrating a transistor example.

FIGS. 23A and 23B show an energy band structure.

FIGS. 24A and 24B are cross-sectional views illustrating a transistor example.

FIGS. 25A and 25B are a top view illustrating a display device and a circuit diagram of a pixel according to one embodiment.

FIG. 26 is a top view of a pixel according to one embodiment.

FIG. 27 is a cross-sectional view illustrating the pixel according to one embodiment.

FIG. 28 is a cross-sectional view illustrating a pixel according to one embodiment.

FIG. 29 is a top view illustrating a pixel according to one embodiment.

FIG. 30 is a cross-sectional view illustrating the pixel according to one embodiment.

FIG. 31 is a cross-sectional view illustrating the pixel according to one embodiment.

FIG. 32 is a top view illustrating a pixel according to one embodiment.

FIG. 33 is a cross-sectional view illustrating the pixel according to one embodiment.

FIG. 34 is a cross-sectional view illustrating the pixel according to one embodiment.

FIG. 35 is a top view illustrating a pixel according to one embodiment.

FIG. 36 is a cross-sectional view illustrating the pixel according to one embodiment.

FIG. 37 is a cross-sectional view illustrating a pixel according to one embodiment.

FIG. 38 is a cross-sectional view illustrating a pixel according to one embodiment.

FIG. 39 is a top view illustrating a pixel according to one embodiment.

FIG. 40 is a cross-sectional view illustrating the pixel according to one embodiment.

FIGS. 41A and 41B are a top view and a circuit diagram of a pixel according to one embodiment.

FIG. 42 is a cross-sectional view illustrating the pixel according to one embodiment.

FIG. 43 is a top view illustrating a pixel according to one embodiment.

FIG. 44 is a cross-sectional view illustrating the pixel according to one embodiment.

FIG. 45 is a circuit diagram illustrating the pixel according to one embodiment.

FIG. 46 is a top view illustrating a display device according to one embodiment.

FIG. 47 is a cross-sectional view illustrating a display device according to one embodiment.

FIGS. 48A and 48B illustrate display on the display device.

FIGS. 49A and 49B illustrate display on the display device.

FIGS. 50A to 50E illustrate an example of a driving method of the display device.

FIGS. 51A to 51E illustrate an example of a driving method of the display device.

FIG. 52 is a cross-sectional view illustrating a display module.

FIGS. 53A to 53G illustrate examples of an electronic device.

FIGS. 54A to 54C show changes in display luminance according to Example.

FIGS. 55A to 55C show the calculation results of changes in visual stimulation according to Example.

FIGS. 56A and 56B show the measurement results of critical fusion frequencies of subjects according to Example.

### DETAILED DESCRIPTION OF THE INVENTION

Embodiments of the present invention will be described below in detail with reference to the drawings. Note that the present invention is not limited to the description below, and it is easily understood by those skilled in the art that various changes and modifications can be made without departing from the spirit and scope of the invention. Therefore, one embodiment of the present invention is not interpreted as being limited to the description of the embodiments described below. In addition, in the following embodiments, the same portions or portions having similar functions are denoted by the same reference numerals or the same hatching patterns in different drawings, and description thereof will not be repeated.

Note that in each drawing described in this specification, the size, the film thickness, or the region of each component may be exaggerated for clarity. Therefore, embodiments of the present invention are not limited to such a scale.

In this specification and the like, ordinal numbers such as “first” and “second” are used in order to avoid confusion among components, and the terms do not limit the components numerically. Therefore, for example, the term “first” can be replaced with the term “second”, “third”, or the like as appropriate.

In this specification and the like, the terms “film” and “layer” can be interchanged with each other depending on the case or circumstances. For example, the term “conductive layer” can be changed into the term “conductive film” in some cases. The term “insulating film” can be changed into the term “insulating layer” in some cases.

In addition, if a “semiconductor” in this specification and the like has a sufficiently low conductivity, for example, the “semiconductor” can have characteristics of an “insulator”. A “semiconductor” and an “insulator” cannot be strictly distinguished from each other because the border therebetween is not clear. Thus, a “semiconductor” in this specification and the like can be called an “insulator”. Similarly, an “insulator” in this specification and the like can be called a “semiconductor”. An “insulator” in this specification and the like can be called a “semi-insulator” in some cases.

In addition, if a “semiconductor” in this specification and the like has a sufficiently high conductivity, for example, the “semiconductor” can have characteristics of a “conductor”. A “semiconductor” and a “conductor” cannot be strictly distinguished from each other because the border therebetween is not clear. Thus, a “semiconductor” in this specification and the like can be called a “conductor”. Similarly, a “conductor” in this specification and the like can be called a “semiconductor”.

Note that functions of a “source” and a “drain” of a transistor can be replaced with each other when a transistor of opposite polarity is used or when the direction of current flowing is changed in circuit operation, for example. Therefore, the terms “source” and “drain” can be used to denote the drain and the source, respectively, in this specification.

In this specification and the like, patterning is assumed to be performed by a photolithography process. Note that processes other than a photolithography process can be used for patterning without limitation. In addition, a mask formed in the photolithography process is assumed to be removed after etching treatment.

Note that in this specification and the like, a silicon oxynitride film refers to a film in which the proportion of oxygen is higher than that of nitrogen. The silicon oxynitride film preferably contains oxygen, nitrogen, silicon, and hydrogen in the ranges of 55 atomic % to 65 atomic %, 1 atomic % to 20 atomic %, 25 atomic % to 35 atomic %, and 0.1 atomic % to 10 atomic %, respectively. Furthermore, a silicon nitride oxide film refers to a film in which the proportion of nitrogen is higher than that of oxygen. The silicon nitride oxide film preferably contains nitrogen, oxygen, silicon, and hydrogen in the ranges of 55 atomic % to 65 atomic %, 1 atomic % to 20 atomic %, 25 atomic % to 35 atomic %, and 0.1 atomic % to 10 atomic %, respectively.

### Embodiment 1

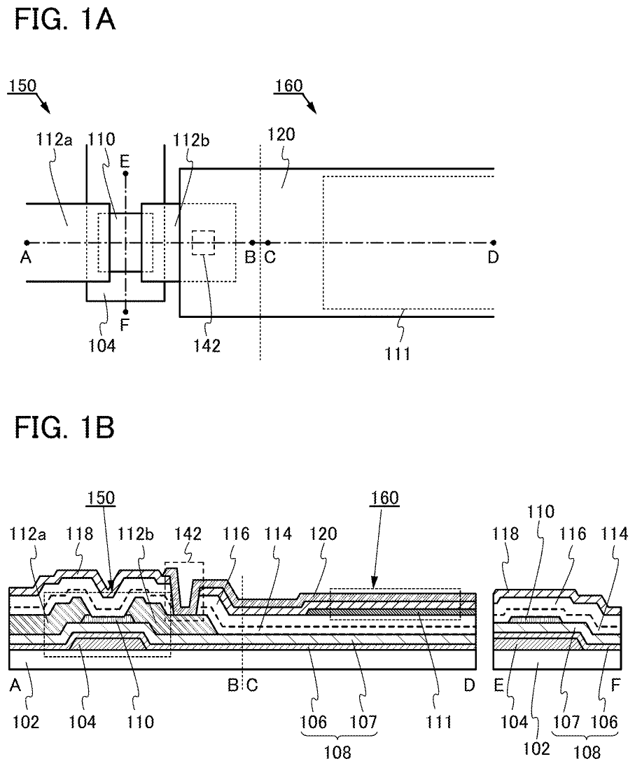

In this embodiment, a semiconductor device of one embodiment of the present invention will be described with reference to FIGS. 1A and 1B, FIGS. 2A and 2B, FIGS. 3A to 3D, FIGS. 4A to 4C, FIGS. 5A to 5C, FIGS. 6A and 6B, FIGS. 7A and 7B, FIGS. 8A to 8D, FIGS. 9A to 9C, FIGS. 10A and 10B, FIGS. 11A to 11D, and FIGS. 12A to 12C.

### <Example of Structure of Semiconductor Device>

FIG. 1A is a top view of the semiconductor device of one embodiment of the present invention. FIG. 1B is a cross-sectional view taken along the dashed-dotted lines A-B, C-D, and E-F shown in FIG. 1A. Note that in FIG. 1A, some components of the semiconductor device (e.g., a gate insulating film) are not illustrated to avoid complexity. Note that as in FIG. 1A, some components are not illustrated in some cases in top views of transistors described below.

The direction of the dashed-dotted line A-B in FIG. 1A is referred to as a channel length direction of a transistor 150. The direction of the dashed-dotted line E-F is referred to as a channel width direction of the transistor 150. Note that in this specification, the channel length direction of a transistor means a direction in which carriers move between a source (source region or source electrode) and a drain (drain region or drain electrode). The channel width direction means a direction perpendicular to the channel length direction in a plane parallel to a substrate.

The semiconductor device shown in FIGS. 1A and 1B includes the transistor 150 including a first oxide semiconductor film 110 and a capacitor 160 including an insulating film between a pair of electrodes. Note that in the capacitor 160, one of the pair of electrodes is a second oxide semiconductor film 111, and the other of the pair of electrodes is a conductive film 120.

The transistor 150 includes a gate electrode 104 over a substrate 102, an insulating film 108 serving as a gate insulating film over the gate electrode 104, the first oxide semiconductor film 110 overlapping with the gate electrode 104 over the insulating film 108, and a source electrode 112a and a drain electrode 112b over the first oxide semiconductor film 110. In other words, the transistor 150 includes the first oxide semiconductor film 110, the insulating film 108 serving as a gate insulating film in contact with the first oxide semiconductor film 110, the gate electrode 104 overlapping with the first oxide semiconductor film 110 and being in contact with the insulating film 108, and the source electrode 112a and the drain electrode 112b electrically connected to the first oxide semiconductor film 110. Note that the transistor 150 shown in FIGS. 1A and 1B has a bottom-gate structure.

In addition, over the transistor 150, specifically over the first oxide semiconductor film 110, the source electrode 112a, and the drain electrode 112b, insulating films 114, 116, and 118 are formed. The insulating films 114, 116, and 118 function as protective insulating films for the transistor 150. In addition, an opening 142 reaching the drain electrode 112b is formed in the insulating films 114, 116, and 118. The conductive film 120 is formed over the insulating film 118 to cover the opening 142. The conductive film 120 functions as a pixel electrode, for example.

The capacitor 160 includes the second oxide semiconductor film 111 serving as the one of the pair of electrodes over the insulating film 116, the insulating film 118 serving as a dielectric film over the second oxide semiconductor film 111, and the conductive film 120 serving as the other of the pair of electrodes, which overlaps with the second oxide semiconductor film 111, with the insulating film 118 provided between the conductive film 120 and the second oxide semiconductor film 111. In other words, the conductive film 120 serves as the pixel electrode and the electrode of the capacitor.

Note that the first oxide semiconductor film 110 serves as a channel region of the transistor 150. In addition, the second oxide semiconductor film 111 serves as the one of the pair of electrodes of the capacitor 160. Thus, the second oxide semiconductor film 111 has resistivity lower than the first oxide semiconductor film 110. In addition, the first oxide semiconductor film 110 and the second oxide semiconductor film 111 preferably contain the same metal element. When the first oxide semiconductor film 110 and the second oxide semiconductor film 111 each contain the same metal element, a common manufacturing apparatus (e.g., a deposition apparatus or a processing apparatus) can be used and accordingly the manufacturing cost can be reduced.

In addition, the second oxide semiconductor film 111 may be connected to a wiring or the like formed of a metal film or the like. For example, when the semiconductor device shown in FIGS. 1A and 1B is used for a transistor and a capacitor in a pixel portion of a display device, a lead wiring, a gate wiring, or the like may be formed using the metal film to be connected to the second oxide semiconductor film 111. Since the lead wiring, the gate wiring, or the like is formed using the metal film, the wiring resistance is reduced and accordingly signal delay or the like can be suppressed.

In addition, the capacitor 160 has a light-transmitting property. In other words, each of the second oxide semiconductor film 111, the conductive film 120, and the insulating film 118 which are included in the capacitor 160 are formed of a material with a light-transmitting property. Since the capacitor 160 has a light-transmitting property, the capacitor 160 can be formed large (in a large area) in the pixel except a region where the transistor is formed; thus, the semiconductor device can have increased capacitance while improving the aperture ratio. Accordingly, the semiconductor device can have excellent display quality.

Note that as the insulating film 118 over the transistor 150 and included in the capacitor 160, an insulating film containing at least hydrogen is used. In addition, as the insulating film 107 included in the transistor 150 and the insulating films 114 and 116 over the transistor 150, insulating films containing at least oxygen are used. As described above, these insulating films are used as the insulating films provided over the transistor 150 and included in the capacitor 160, and provided over the transistor 150 and below the capacitor 160, so that the resistivity of the first oxide semiconductor film 110 included in the transistor 150 and the resistivity of the second oxide semiconductor film 111 included in the capacitor 160 can be controlled.

In addition, when the insulating films included in the capacitor 160 and provided over the transistor 150 and the capacitor 160 are provided as follows, the planarity of the conductive film 120 can be increased. Specifically, the insulating films 114 and 116 are provided over the first oxide semiconductor film 110, and the insulating film 118 is provided over the second oxide semiconductor film 111 with the second oxide semiconductor film 111 provided between the insulating film 116 and the insulating film 118. With such a structure, the resistivity of the second oxide semiconductor film 111 is controlled without providing an opening in the insulating films 114 and 116 overlapping with the second oxide semiconductor film 111, and thus the planarity of the conductive film 120 can be increased. Thus, when the semiconductor device with such a structure shown in FIGS. 1A and 1B is used for a transistor and a capacitor in a pixel portion of a liquid crystal display device, the alignment of liquid crystals over the conductive film 120 can be improved.

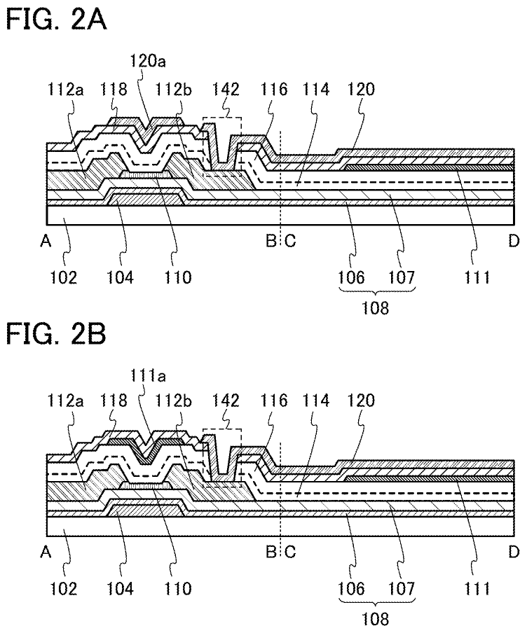

Note that as another example, a conductive film 120a simultaneously deposited, etched, and formed with the conductive film 120 may overlap with the channel region of the transistor. FIG. 2A shows the example. The conductive film 120a contains the same material as the conductive film 120 because the conductive film 120a is deposited, formed, and etched simultaneously with the conductive film 120; thus, the number of steps is not increased. Note that one embodiment of the present invention is not limited to the example. The conductive film 120a can be formed in a different step from the conductive film 120. The conductive film 120a includes an area overlapping with the channel region of the transistor. Thus, the conductive film 120a serves as a second gate electrode of the transistor, and may be connected to the gate electrode 104. Alternatively, the conductive film 120a cannot be connected to the gate electrode 104 so that different signals or potentials may be supplied to them. Such a structure can further increase the current driving ability of the transistor 150. In that case, the insulating films 114, 116, and 118 serve as gate insulating films for the second gate electrode.

As another example, a second oxide semiconductor film 111a formed and etched simultaneously with the second oxide semiconductor film 111 may overlap with the channel region of the transistor. FIG. 2B shows the example. The second oxide semiconductor film 111a contains the same material as the second oxide semiconductor film 111 because the second oxide semiconductor film 111a is deposited, formed, and etched simultaneously with the second oxide semiconductor film 111; thus, the number of steps is not increased. Note that one embodiment of the present invention is not limited to the example. The second oxide semiconductor film 111a can be formed in a different step from the second oxide semiconductor film 111. The second oxide semiconductor film 111a includes an area overlapping with the first oxide semiconductor film 110 serving as the channel region of the transistor 150. Thus, the second oxide semiconductor film 111a serves as a second gate electrode of the transistor, and may be connected to the gate electrode 104. Alternatively, the second oxide semiconductor film 111a cannot be connected to the gate electrode 104 so that different signals or potentials may be supplied to them. With such a structure, the insulating films 114 and 116 serve as gate insulating films for the second gate electrode; thus, the current driving ability of the transistor 150 can be higher than that of the transistor in FIG. 2A.

Note that the first oxide semiconductor film 110 has higher resistivity than the second oxide semiconductor film 111 because it is used as the channel region in the transistor 150. The second oxide semiconductor film 111 has lower resistivity than the first oxide semiconductor film 110 because it serves as an electrode.

A method of controlling the resistivity of the first oxide semiconductor film 110 and the second oxide semiconductor film 111 is described below.

### <Method of Controlling Resistivity of Oxide Semiconductor Film>

Oxide semiconductor films used as the first oxide semiconductor film 110 and the second oxide semiconductor film 111 are semiconductor materials capable of controlling the resistivity depending on oxygen vacancies in the films and/or the concentrations of impurity such as hydrogen or water in the films. Thus, treatment to be performed on the first oxide semiconductor film 110 and the second oxide semiconductor film 111 is selected from the following to control the resistivity of each films formed through the same steps: treatment for increasing oxygen vacancies and/or impurity concentration and treatment for reducing oxygen vacancies and/or impurity concentration.

Specifically, plasma treatment is performed on the oxide semiconductor film used as the second oxide semiconductor film 111 serving as the electrode of the capacitor 160 to increase oxygen vacancies and/or impurities such as hydrogen or water in the oxide semiconductor film, so that the oxide semiconductor film can have a high carrier density and low resistivity. Alternatively, an insulating film containing hydrogen is formed in contact with the oxide semiconductor film to diffuse hydrogen from the insulating film containing hydrogen, such as the insulating film 118, to the oxide semiconductor film, so that the oxide semiconductor film can have a high carrier density and a low resistance. As described above, the second oxide semiconductor film 111 serves as a semiconductor before the step for increasing oxygen vacancies or diffusing hydrogen in the films, whereas it serves as a conductor after the step.

As the plasma treatment, for example, plasma treatment using a gas containing one or more kinds of a rare gas (He, Ne, Ar, Kr, or Xe), hydrogen, and nitrogen is typically used. Specifically, plasma treatment in an Ar atmosphere, plasma treatment in a mixed gas atmosphere of Ar and hydrogen, plasma treatment in an ammonia atmosphere, plasma treatment in a mixed gas atmosphere of Ar and ammonia, plasma treatment in a nitrogen atmosphere, or the like can be used. By the plasma treatment, an oxygen vacancy is formed in a lattice from which oxygen is released (or in a portion from which oxygen is released) in the oxide semiconductor film. This oxygen vacancy can cause carrier generation. Furthermore, when hydrogen is supplied from an insulating film that is in the vicinity of the oxide semiconductor film, specifically, that is in contact with the lower surface or the upper surface of the oxide semiconductor film, and hydrogen is bonded to the oxygen vacancy, an electron serving as a carrier might be generated.

In addition, for example, an insulating film containing hydrogen, that is, an insulating film for releasing hydrogen, typically, a silicon nitride film, is used as the insulating film 118, whereby hydrogen is supplied to the second oxide semiconductor film 111. The insulating film for releasing hydrogen preferably contains hydrogen at a concentration of greater than or equal to 1×10²² atoms/cm³. Such an insulating film in contact with the second oxide semiconductor film 111 allows the second oxide semiconductor film 111 to effectively contain hydrogen.

Hydrogen contained in the oxide semiconductor film reacts with oxygen bonded to a metal atom to be water, and also causes oxygen vacancies in a lattice from which oxygen is released (or a portion from which oxygen is released). Due to entry of hydrogen into the oxygen vacancy, an electron serving as a carrier is generated in some cases. In some cases, bonding of part of hydrogen to oxygen bonded to a metal atom causes generation of an electron serving as a carrier. Therefore, the second oxide semiconductor film 111 in contact with the insulating film containing hydrogen has a higher carrier density than the first oxide semiconductor film 110.

Note that to make an oxide semiconductor film with low resistivity, an ion implantation method, an ion doping method, a plasma immersion ion implantation method, or the like can be used to inject hydrogen, boron, phosphorus, or nitrogen into the oxide semiconductor film.

In contrast, the first oxide semiconductor film 110 serving as a channel region of the transistor 150 is not in contact with the insulating films 106 and 118 containing hydrogen with the insulating film 107, 114, and 116 provided between the first oxide semiconductor film 111 and each of the insulating films 106 and 108. An insulating film containing oxygen, that is, an insulating film for releasing hydrogen is used as at least one of the insulating films 107, 114, and 116, so that oxygen can be supplied to the first oxide semiconductor film 110. The first oxide semiconductor film 110 supplied with oxygen becomes an oxide semiconductor film with high resistivity in which oxygen vacancies in the film or at the interface are filled. Note that as the insulating film for releasing oxygen, a silicon oxide film or a silicon oxynitride film can be used, for example.

As described above, the resistivity of the oxide semiconductor films is controlled depending on the structures of the insulating films in contact with the first oxide semiconductor film 110 and the second oxide semiconductor film 111. Note that a material similar to the insulating film 118 may be used for the insulating film 106. The use of silicon nitride for the insulating film 106 prevents the gate electrode 104 from being supplied with oxygen diffused from the insulating film 107 and being oxidized.

The oxide semiconductor film in which oxygen vacancies are compensated with oxygen and the hydrogen concentration is reduced can be referred to as a highly purified intrinsic or substantially highly purified intrinsic oxide semiconductor film. Here, the term “substantially intrinsic” refers to a state where an oxide semiconductor has a carrier density lower than 8×10¹¹/cm³, preferably lower than 1×10¹¹/cm³, more preferably lower than 1×10¹⁰/cm³, more preferably lower than 1×10⁻⁹/cm³. A highly purified intrinsic or substantially highly purified intrinsic oxide semiconductor film has few carrier generation sources, and thus can have a low carrier density. The highly purified intrinsic or substantially highly purified intrinsic oxide semiconductor film has a low density of defect states and accordingly can have a low density of trap states.

The highly purified intrinsic or substantially highly purified intrinsic oxide semiconductor film has an extremely low off-state current; even when an element has a channel width of 1×10⁶ m and a channel length of 10 m, the off-state current can be less than or equal to the measurement limit of a semiconductor parameter analyzer, i.e., less than or equal to 1×10⁻¹³ A, at a voltage (drain voltage) between a source electrode and a drain electrode ranging from 1 V to 10 V. Accordingly, the transistor 150 in which the channel region is formed in the first oxide semiconductor film 110 that is a highly purified intrinsic or substantially highly purified intrinsic oxide semiconductor film, can have a small variation in electrical characteristics and high reliability.

In the first oxide semiconductor film 110 where the channel region of the transistor 150 is formed, it is preferable to reduce hydrogen as much as possible. Specifically, in the first oxide semiconductor film 110, the hydrogen concentration which is measured by SIMS is set to lower than or equal to 2×10²⁰ atoms/cm³, preferably lower than or equal to 5×10¹⁹ atoms/cm³, more preferably lower than or equal to 1×10¹⁹ atoms/cm³, more preferably lower than or equal to 5×10¹⁸ atoms/cm³, more preferably lower than or equal to 1×10¹⁸ atoms/cm³, more preferably lower than or equal to 5×10¹⁷ atoms/cm³, more preferably lower than or equal to 1×10¹⁶ atoms/cm³.

The second oxide semiconductor film 111 that functions as the electrode of the capacitor 160 is an oxide semiconductor film that has a higher hydrogen concentration and/or a larger number of oxygen vacancies, and has a lower resistivity than the first oxide semiconductor film 110. The hydrogen concentration in the second oxide semiconductor film 111 is greater than or equal to 8×10¹⁹ atoms/cm³, preferably greater than or equal to 1×10²⁰ atoms/cm³, more preferably greater than or equal to 5×10²⁰ atoms/cm³. The hydrogen concentration in the second oxide semiconductor film 111 is greater than or equal to 2 times, preferably greater than or equal to 10 times the hydrogen concentration in the first oxide semiconductor film 110. The resistivity of the second oxide semiconductor film 111 is preferably greater than or equal to 1×10⁻⁸ times and less than 1×10⁻¹ times the resistivity of the first oxide semiconductor film 110, typically greater than or equal to 1×10⁻³ Ωcm and less than 1×10⁴ Ωcm, preferably greater than or equal to 1×10⁻³ Ωcm and less than 1×10⁻¹ Ωcm.

Details of other components included in the semiconductor device illustrated in FIGS. 1A and 1B are described below.

### <Substrate>

There is no particular limitation on the property of a material and the like of the substrate 102 as long as the material has heat resistance high enough to withstand at least heat treatment to be performed later. For example, a glass substrate, a ceramic substrate, a quartz substrate, or a sapphire substrate may be used as the substrate 102. Alternatively, a single crystal semiconductor substrate or a polycrystalline semiconductor substrate made of silicon, silicon carbide, or the like, a compound semiconductor substrate made of silicon germanium or the like, an SOI (silicon on insulator) substrate, or the like may be used as the substrate 102. In the case where a glass substrate is used as the substrate 102, a glass substrate having any of the following sizes can be used: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large-sized display device can be manufactured. Alternatively, a flexible substrate may be used as the substrate 102, and a transistor 150, a capacitor 160, and the like may be formed directly over the flexible substrate.

Other than the above, a transistor can be formed using various substrates as the substrate 102. There is no particular limitation on the type of a substrate. Examples of the substrate include a plastic substrate, a metal substrate, a stainless steel substrate, a substrate including stainless steel foil, a tungsten substrate, a substrate including tungsten foil, a flexible substrate, an attachment film, paper including a fibrous material, and a base film. Examples of the glass substrate include a barium borosilicate glass substrate, an aluminoborosilicate glass substrate, and a soda lime glass substrate. Examples of the flexible substrate include a flexible synthetic resin such as plastics typified by polyethylene terephthalate (PET), polyethylene naphthalate (PEN), and polyether sulfone (PES), and acrylic. Examples of the attachment film include polypropylene, polyester, polyvinyl fluoride, and polyvinyl chloride. Examples of the material for the base film include polyester, polyamide, polyimide, an inorganic vapor deposition film, and paper. Specifically, the use of semiconductor substrates, single crystal substrates, SOI substrates, or the like enables the manufacture of small-sized transistors with a small variation in characteristics, size, shape, or the like and with high current capability. A circuit using such transistors achieves lower power consumption of the circuit or higher integration of the circuit.

Note that a transistor may be formed using one substrate, and then the transistor may be transferred to another substrate. Examples of the substrate to which a transistor is transferred include, in addition to the above substrate over which the transistor can be formed, a paper substrate, a cellophane substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupra, rayon, or regenerated polyester), and the like), a leather substrate, and a rubber substrate. The use of such a substrate enables formation of a transistor with excellent properties, a transistor with low power consumption, or a device with high durability, high heat resistance, or a reduction in weight or thickness.

<First Oxide Semiconductor film and Second Oxide Semiconductor Film>

The first oxide semiconductor film 110 and the second oxide semiconductor film 111 preferably includes a film represented by an In-M-Zn oxide that contains at least indium (In), zinc (Zn), and M (metal such as Al, Ti, Ga, Y, Zr, La, Ce, Nd, Sn, or Hf). In order to reduce variations in electrical characteristics of the transistors including the oxide semiconductor, the oxide semiconductor preferably contains a stabilizer in addition to In, Zn and M.

Examples of the stabilizer, including metals that can be used as M, are gallium (Ga), tin (Sn), hafnium (Hf), aluminum (Al), and zirconium (Zr). Other examples of the stabilizer are lanthanoid such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb) and lutetium (Lu).

As an oxide semiconductor included in the first oxide semiconductor film 110 and the second oxide semiconductor film 111, any of the following can be used, for example: an In—Ga—Zn-based oxide, an In—Al—Zn-based oxide, an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, and an In—Hf—Al—Zn-based oxide.

Note that here, for example, an “In—Ga—Zn-based oxide” means an oxide containing In, Ga, and Zn as its main components and there is no limitation on the ratio of In:Ga:Zn. The In—Ga—Zn-based oxide may contain another metal element in addition to In, Ga, and Zn.

The first oxide semiconductor film 110 and the second oxide semiconductor film 111 may include the same metal element selected from metal elements contained in the above oxides. The use of the same metal element for the first oxide semiconductor film 110 and the second oxide semiconductor film 111 can reduce the manufacturing cost. For example, when metal oxide targets with the same metal composition are used, the manufacturing cost can be reduced, and the same etching gas or the same etchant can be used in processing the first oxide semiconductor film 110 and the second oxide semiconductor film 111. Note that even when the first oxide semiconductor film 110 and the second oxide semiconductor film 111 include the same metal element, they have different compositions in some cases. For example, a metal element in a film is released during the manufacturing process of the transistor and the capacitor, which might result in different metal compositions.

In the case where the first oxide semiconductor film 110 contains an In-M-Zn oxide, the proportions of In and M when the summation of In and M is assumed to be 100 atomic % are preferably as follows: the atomic percentage of In is greater than 25 atomic % and the atomic percentage of M is less than 75 atomic %, or more preferably, the atomic percentage of In is greater than 34 atomic % and the atomic percentage of M is less than 66 atomic %.

The energy gap of the first oxide semiconductor film 110 is 2 eV or more, preferably 2.5 eV or more, more preferably 3 eV or more. With the use of an oxide semiconductor having such a wide energy gap, the off-state current of the transistor 150 can be reduced.

The thickness of the first oxide semiconductor film 110 is greater than or equal to 3 nm and less than or equal to 200 nm, preferably greater than or equal to 3 nm and less than or equal to 100 nm, more preferably greater than or equal to 3 nm and less than or equal to 50 nm.

In the case where the first oxide semiconductor film 110 contains an In-M-Zn oxide (M represents Al, Ti, Ga, Y, Zr, La, Ce, Nd, Sn, or Hf), it is preferable that the atomic ratio of metal elements of a sputtering target used for forming a film of the In-M-Zn oxide satisfy In M and Zn≥M. As the atomic ratio of metal elements of such a sputtering target, In.M:Zn=1:1:1, In:M:Zn=1:1:1.2, InM:Zn=3:1:2, InM:Zn=1:3:4, and In.M:Zn=1:3:6 are preferable. Note that the atomic ratio of metal elements in the formed first oxide semiconductor film 110 varies from the above atomic ratio of metal elements of the sputtering target within a range of ±40% as an error.

An oxide semiconductor film with a low carrier density is used as the first oxide semiconductor film 110. For example, an oxide semiconductor film whose carrier density is 1×10¹⁷/cm³ or lower, preferably 1×10¹⁵/cm³ or lower, more preferably 1×10¹³/cm³ or lower, much more preferably 1×10¹¹/cm³ or lower is used as the first oxide semiconductor film 110.

Note that, without limitation to those described above, a material with an appropriate composition may be used depending on required semiconductor characteristics and electrical characteristics (e.g., field-effect mobility and threshold voltage) of a transistor. To obtain the required semiconductor characteristics of the transistor, it is preferable that the carrier density, the impurity concentration, the defect density, the atomic ratio between a metal element and oxygen, the interatomic distance, the density, and the like of the first oxide semiconductor film 110 be set to appropriate values.

When silicon or carbon that is one of elements belonging to Group 14 is contained in the first oxide semiconductor film 110, oxygen vacancies are increased in the first oxide semiconductor film 110, and the first oxide semiconductor film 110 becomes n-type. Thus, the concentration of silicon or carbon (the concentration is measured by secondary ion mass spectrometry (SIMS)) in the first oxide semiconductor film 110 is lower than or equal to 2×10¹⁸ atoms/cm³, preferably lower than or equal to 2×10¹⁷ atoms/cm³.

The concentration of alkali metal or alkaline earth metal in the first oxide semiconductor film 110, which is measured by SIMS, is lower than or equal to 1×10¹⁷ atoms/cm³, preferably lower than or equal to 2×10¹⁶ atoms/cm³. Alkali metal and alkaline earth metal might generate carriers when bonded to an oxide semiconductor, in which case the off-state current of the transistor might be increased. Therefore, it is preferable to reduce the concentration of alkali metal or alkaline earth metal in the first oxide semiconductor film 110.

When nitrogen is contained in the first oxide semiconductor film 110, electrons serving as carriers are generated and the carrier density increases, so that the first oxide semiconductor film 110 easily becomes n-type. Thus, a transistor including an oxide semiconductor which contains nitrogen is likely to be normally on. For this reason, nitrogen in the oxide semiconductor film is preferably reduced as much as possible. For example, the concentration of nitrogen which is measured by SIMS is preferably set to lower than or equal to 5×10¹⁸ atoms/cm³.

The first oxide semiconductor film 110 may have, for example, a non-single crystal structure. Examples of the non-single crystal structure include a c-axis aligned crystalline oxide semiconductor (CAAC-OS), a polycrystalline structure, a microcrystalline structure which is described later, and an amorphous structure. Among the non-single crystal structures, the amorphous structure has the highest density of defect states, whereas CAAC-OS has the lowest density of defect states.

The first oxide semiconductor film 110 may have an amorphous structure, for example. The oxide semiconductor film having the amorphous structure has disordered atomic arrangement and no crystalline component, for example. Alternatively, the oxide film having an amorphous structure has, for example, an absolutely amorphous structure and no crystal part.

Note that the first oxide semiconductor film 110 may be a mixed film including two or more of the following: a region having an amorphous structure, a region having a microcrystalline structure, a region having a polycrystalline structure, a region of CAAC-OS, and a region having a single-crystal structure. The mixed film may have a stacked-layer structure of two or more of a region having an amorphous structure, a region having a microcrystalline structure, a region having a polycrystalline structure, a CAAC-OS region, and a region having a single-crystal structure. The mixed film has a stacked-layer structure of two or more of a region having an amorphous structure, a region having a microcrystalline structure, a region having a polycrystalline structure, a CAAC-OS region, and a region having a single-crystal structure in some cases.

### <Insulating Film>

As each of the insulating films 106 and 107 functioning as a gate insulating film of the transistor 150, an insulating film including at least one of the following films formed by a plasma chemical vapor deposition (CVD) method, a sputtering method, or the like can be used: a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film. Note that the stacked structure of the insulating films 106 and 107 is not necessarily employed, and an insulating film with a single-layer structure selected from the above films may be used.

The insulating film 106 has a function of a blocking film that inhibits penetration of oxygen. For example, in the case where excess oxygen is supplied to the insulating film 107, the insulating film 114, the insulating film 116, and/or the first oxide semiconductor film 110, the insulating film 106 can inhibit penetration of oxygen.

Note that the insulating film 107 that is in contact with the first oxide semiconductor film 110 functioning as a channel region of the transistor 150 is preferably an oxide insulating film and preferably includes a region including oxygen in excess of the stoichiometric composition (an oxygen-excess region). In other words, the insulating film 107 is an insulating film which is capable of releasing oxygen. In order to provide the oxygen-excess region in the insulating film 107, the insulating film 107 is formed in an oxygen atmosphere, for example. Alternatively, the oxygen-excess region may be formed by supplying oxygen to the formed insulating film 107. As a method for supplying oxygen, an ion implantation method, an ion doping method, a plasma immersion ion implantation method, plasma treatment, or the like can be employed.

In the case where hafnium oxide is used for the insulating films 106 and 107, the following effect is attained. Hafnium oxide has a higher dielectric constant than silicon oxide and silicon oxynitride. Therefore, the thicknesses of the insulating films 106 and 107 can be made large as compared with the case where silicon oxide is used; as a result, a leakage current due to a tunnel current can be low. That is, it is possible to provide a transistor with a low off-state current. Moreover, hafnium oxide with a crystalline structure has higher dielectric constant than hafnium oxide with an amorphous structure. Therefore, it is preferable to use hafnium oxide with a crystalline structure in order to provide a transistor with a low off-state current. Examples of the crystalline structure include a monoclinic crystal structure and a cubic crystal structure. Note that one embodiment of the present invention is not limited to the above examples.

In this embodiment, a silicon nitride film is formed as the insulating film 106, and a silicon oxide film is formed as the insulating film 107. The silicon nitride film has a higher dielectric constant than a silicon oxide film and needs a larger thickness for capacitance equivalent to that of the silicon oxide film. Thus, when the silicon nitride film is included as the insulating film 108 serving as the gate insulating film of the transistor 150, the physical thickness of the insulating film can be increased. Therefore, the electrostatic breakdown of the transistor 150 can be prevented by inhibiting a reduction in the withstand voltage of the transistor 150 and improving the withstand voltage of the transistor 150.

### <Gate Electrode, Source Electrode, and Drain Electrode>

The gate electrode 104 and the source electrode 112a and drain electrode 112b can be formed to have a single-layer structure or a stacked-layer structure, using any of metals such as aluminum, titanium, chromium, nickel, copper, yttrium, zirconium, molybdenum, silver, tantalum, and tungsten, or an alloy containing any of these metals as its main component. For example, a two-layer structure in which a titanium film is stacked over an aluminum film; a two-layer structure in which a titanium film is stacked over a tungsten film; a two-layer structure in which a copper film is stacked over a molybdenum film; a two-layer structure in which a copper film is stacked over an alloy film containing molybdenum and tungsten; a two-layer structure in which a copper film is stacked over an alloy film containing copper, magnesium, and aluminum; a three-layer structure in which an aluminum film or a copper film is stacked over a titanium film or a titanium nitride film, and a titanium film or a titanium nitride film is formed thereover; a three-layer structure in which an aluminum film or a copper film is stacked over a molybdenum film or a molybdenum nitride film, and a molybdenum film or a molybdenum nitride film is formed thereover; and the like can be employed. In the case where the source electrode 112a and drain electrode 112b have a three-layer structure, it is preferable that each of the first and third layers be a film formed of titanium, titanium nitride, molybdenum, tungsten, an alloy containing molybdenum and tungsten, an alloy containing molybdenum and zirconium, or molybdenum nitride, and that the second layer be a film formed of a low-resistance material such as copper, aluminum, gold, silver, or an alloy containing copper and manganese. A light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added may be used. The materials that can be used for the gate electrode 104 and the source electrode 112a and drain electrode 112b can be formed by, for example, a sputtering method.

### <Conductive Film>

The conductive film 120 has a function of a pixel electrode. A material having a property of transmitting visible light is used for the conductive film 120, for example. Specifically, a material including one of indium (In), zinc (Zn), and tin (Sn) is preferably used. For the conductive film 120, a light-transmitting conductive material such as indium oxide containing tungsten oxide, indium zinc oxide containing tungsten oxide, indium oxide containing titanium oxide, indium tin oxide containing titanium oxide, indium tin oxide (ITO), indium zinc oxide, or indium tin oxide to which silicon oxide is added can be used. The conductive film 120 can be formed by a sputtering method, for example.

### <Protective Insulating Film>

As each of the insulating films 114, 116, and 118 functioning as a protective insulating film of the transistor 150, an insulating film including at least one of the following films formed by a plasma CVD method, a sputtering method, or the like can be used: a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film.

Note that the insulating film 114 that is in contact with the first oxide semiconductor film 110 functioning as a channel region of the transistor 150 is preferably an oxide insulating film and preferably includes a region including oxygen in excess of the stoichiometric composition (an oxygen-excess region). In other words, the insulating film 114 is an insulating film which is capable of releasing oxygen. In order to provide the oxygen-excess region in the insulating film 114, the insulating film 114 is formed in an oxygen atmosphere, for example. Alternatively, the oxygen-excess region may be formed by supplying oxygen to the formed insulating film 114. As a method for supplying oxygen, an ion implantation method, an ion doping method, a plasma immersion ion implantation method, plasma treatment, or the like can be employed.

The use of the insulating film capable of releasing oxygen as the insulating film 114 can reduce the number of oxygen vacancies in the first oxide semiconductor film 110 by transferring oxygen to the first oxide semiconductor film 110 functioning as the channel region of the transistor 150. For example, the number of oxygen vacancies in the first oxide semiconductor film 110 can be reduced by using an insulating film having the following feature: the number of oxygen molecules released from the insulating film by heat treatment at a temperature higher than or equal to 100° C. and lower than or equal to 700° C., or higher than or equal to 100° C. and lower than or equal to 500° C. is greater than or equal to 1.0×10¹⁸ molecules/cm³ when measured by thermal desorption spectroscopy (hereinafter referred to as TDS).

It is preferable that the number of defects in the insulating film 114 be small, typically the spin density corresponding to a signal that appears at g=2.001 due to a dangling bond of silicon, be lower than or equal to 3×10¹⁷ spins/cm³ by ESR measurement. This is because if the density of defects in the insulating film 114 is high, oxygen is bonded to the defects and the amount of oxygen that permeates the insulating film 114 is decreased. Furthermore, it is preferable that the amount of defects at the interface between the insulating film 114 and the first oxide semiconductor film 110 be small and typically, the spin density of a signal that appears at g=1.89 or more and 1.96 or less due to the defect in the first oxide semiconductor film 110 be lower than or equal to 1×10¹⁷ spins/cm³, more preferably lower than or equal to the lower limit of detection by ESR measurement.

Note that all oxygen entering the insulating film 114 from the outside moves to the outside of the insulating film 114 in some cases. Alternatively, some oxygen entering the insulating film 114 from the outside remains in the insulating film 114 in some cases. Furthermore, movement of oxygen occurs in the insulating film 114 in some cases in such a manner that oxygen enters the insulating film 114 from the outside and oxygen contained in the insulating film 114 moves to the outside of the insulating film 114. When an oxide insulating film which is permeable to oxygen is formed as the insulating film 114, oxygen released from the insulating film 116 provided over the insulating film 114 can be moved to the first oxide semiconductor film 110 through the insulating film 114.

The insulating film 114 can be formed using an oxide insulating film having a low density of states due to nitrogen oxide. Note that the density of states due to nitrogen oxide can be formed between the energy of the valence band maximum (E_{v_os}) and the energy of the conduction band minimum (E_{c_os}) of the oxide semiconductor film. A silicon oxynitride film that releases less nitrogen oxide, an aluminum oxynitride film that releases less nitrogen oxide, or the like can be used as the oxide insulating film.

Note that a silicon oxynitride film that releases a small amount of nitrogen oxide is a film of which the amount of released ammonia is larger than the amount of released nitrogen oxide in TDS; the amount of released ammonia is typically greater than or equal to 1×10¹⁸ molecules/cm³ and less than or equal to 5×10¹⁹ molecules/cm³. The amount of released ammonia corresponds to the released amount caused by heat treatment at a film surface temperature higher than or equal to 50° C. and lower than or equal to 650° C., preferably higher than or equal to 50° C. and lower than or equal to 550° C.

Nitrogen oxide (NOₓ; x is greater than 0 and less than or equal to 2, preferably greater than or equal to 1 and less than or equal to 2), typically NO₂ or NO, forms levels in the insulating film 114, for example. The levels are positioned in the energy gap of the first oxide semiconductor film 110. Therefore, when nitrogen oxide is diffused to the interface between the insulating film 114 and the first oxide semiconductor film 110, an electron is trapped by the level on the insulating film 114 side. As a result, the trapped electron remains in the vicinity of the interface between the insulating film 114 and the first oxide semiconductor film 110; thus, the threshold voltage of the transistor is shifted in the positive direction.

Nitrogen oxide reacts with ammonia and oxygen in heat treatment. Since nitrogen oxide contained in the insulating film 114 reacts with ammonia contained in the insulating film 216 in heat treatment, nitrogen oxide contained in the insulating film 114 is reduced. Therefore, an electron is hardly trapped at the interface between the insulating film 114 and the first oxide semiconductor film 110.

In a transistor using the oxide insulating film as the insulating film 114, the shift in threshold voltage can be reduced, which leads to a smaller change in electrical characteristics of the transistor.

Note that in an ESR spectrum obtained at 100 K or lower of the insulating film 114, by heat treatment in a manufacturing process of the transistor, typically heat treatment at a temperature lower than 400° C. or lower than 375° C. (preferably higher than or equal to 340° C. and lower than or equal to 360° C.), a first signal that appears at a g-factor of greater than or equal to 2.037 and less than or equal to 2.039, a second signal that appears at a g-factor of greater than or equal to 2.001 and less than or equal to 2.003, and a third signal that appears at a g-factor of greater than or equal to 1.964 and less than or equal to 1.966 are observed. The split width of the first and second signals and the split width of the second and third signals, which are obtained by ESR measurement using an X-band, are each approximately 5 mT. The sum of the spin densities of the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 is less than 1×10¹⁸ spins/cm³, typically greater than or equal to 1×10¹⁷ spins/cm³ and less than 1×10¹⁸ spins/cm³.

In the ESR spectrum at 100 K or lower, the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 correspond to signals attributed to nitrogen oxide (NOₓ; x is greater than 0 and less than or equal to 2, preferably greater than or equal to 1 and less than or equal to 2). Typical examples of nitrogen oxide include nitrogen monoxide and nitrogen dioxide. In other words, the smaller the sum of the spin densities of the first signal that appears at a g-factor greater than or equal to 2.037 and less than or equal to 2.039, the second signal that appears at a g-factor greater than or equal to 2.001 and less than or equal to 2.003, and the third signal that appears at a g-factor greater than or equal to 1.964 and less than or equal to 1.966 is, the lower the content of nitrogen oxide in the oxide insulating film is.

The nitrogen concentration of the oxide insulating film measured by SIMS is lower than or equal to 6×10²⁰ atoms/cm³.

The oxide insulating film is formed by a PECVD method at a substrate temperature higher than or equal to 220° C. and lower than or equal to 350° C. using silane and dinitrogen monoxide, whereby a dense and hard film can be formed.

The insulating film 116 in contact with the insulating film 114 is formed using an oxide insulating film whose oxygen content is in excess of that in the stoichiometric composition. Part of oxygen is released from the oxide insulating film whose oxygen content is in excess of that in the stoichiometric composition by heating. The oxide insulating film whose oxygen content is in excess of that in the stoichiometric composition is an oxide insulating film of which the amount of released oxygen converted into oxygen atoms is greater than or equal to 1.0×10¹⁹ atoms/cm³, preferably greater than or equal to 3.0×10²⁰ atoms/cm³ in TDS. Note that the temperature of the film surface in the TDS is preferably higher than or equal to 100° C. and lower than or equal to 700° C., or higher than or equal to 100° C. and lower than or equal to 500° C.

Furthermore, it is preferable that the amount of defects in the insulating film 116 be small, typically the spin density of a signal that appears at g=2.001 due to a dangling bond of silicon, be less than 1.5×10¹⁸ spins/cm³, preferably less than or equal to 1×10¹⁸ spins/cm³ by ESR measurement. Note that the insulating film 255 is provided more apart from the first oxide semiconductor film 110 than the insulating film 114 is; thus, the insulating film 116 may have higher defect density than the insulating film 114.

The thickness of the insulating film 114 can be greater than or equal to 5 nm and less than or equal to 150 nm, preferably greater than or equal to 5 nm and less than or equal to 50 nm, more preferably greater than or equal to 10 nm and less than or equal to 30 nm. The thickness of the insulating film 116 can be greater than or equal to 30 nm and less than or equal to 500 nm, preferably greater than or equal to 150 nm and less than or equal to 400 nm.

The insulating films 114 and 116 can be formed using insulating films formed of the same kinds of materials; thus, a boundary between the insulating films 114 and 116 cannot be clearly observed in some cases. Thus, in this embodiment, the boundary between the insulating films 114 and 116 is shown by a dashed line. Although a two-layer structure of the insulating films 114 and 116 is described in this embodiment, the present invention is not limited to this. For example, a single-layer structure of the insulating film 114, a single-layer structure of the insulating film 116, or a stacked-layer structure of three or more layers may be used.

The insulating film 118 functioning as a dielectric film of the capacitor 160 is preferably a nitride insulating film. The relative dielectric constant of a silicon nitride film is higher than that of a silicon oxide film, and the silicon nitride film needs to have a larger film thickness than the silicon oxide film to obtain a capacitance equivalent to that of the silicon oxide film. Thus, when the silicon nitride film is included in the insulating film 118 functioning as the dielectric film of the capacitor 160, the physical thickness of the insulating film can be increased. Accordingly, a reduction in the withstand voltage of the capacitor 160 can be inhibited. Furthermore, the electrostatic breakdown of the capacitor 160 can be prevented by improving the withstand voltage. Note that the insulating film 118 also has a function of decreasing the resistivity of the second oxide semiconductor film 111 that functions as the electrode of the capacitor 160.

The insulating film 118 has a function of blocking oxygen, hydrogen, water, an alkali metal, an alkaline earth metal, or the like. By providing the insulating film 118, it is possible to prevent outward diffusion of oxygen from the first oxide semiconductor film 110, outward diffusion of oxygen contained in the insulating films 114 and 116, and entry of hydrogen, water, or the like into the first oxide semiconductor film 110 from the outside. Note that instead of the nitride insulating film having a blocking effect against oxygen, hydrogen, water, an alkali metal, an alkaline earth metal, and the like, an oxide insulating film having a blocking effect against oxygen, hydrogen, water, and the like, may be provided. As the oxide insulating film having a blocking effect against oxygen, hydrogen, water, and the like, an aluminum oxide film, an aluminum oxynitride film, a gallium oxide film, a gallium oxynitride film, an yttrium oxide film, an yttrium oxynitride film, a hafnium oxide film, and a hafnium oxynitride film can be given.

### <Method for Manufacturing Display Device>

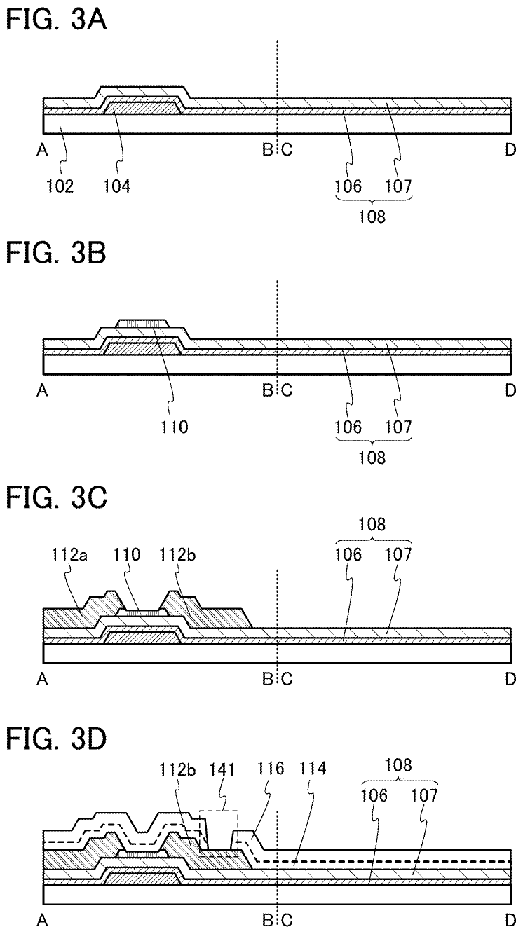

Next, an example of a method for manufacturing the semiconductor device illustrated in FIGS. 1A and 1B is described with reference to FIGS. 3A to 3D, FIGS. 4A to 4C, FIGS. 5A to 5C, and FIGS. 6A and 6B.

First, the gate electrode 104 is formed over the substrate 102. After that, the insulating film 108 including the insulating films 106 and 107 is formed over the substrate 102 and the gate electrode 104 (see FIG. 3A).

Note that the substrate 102, the gate electrode 104, and the insulating films 106 and 107 can be selected from the materials which are described above. In this embodiment, a glass substrate is used as the substrate 102; a tungsten film is used as a conductive film for the gate electrode 104; a silicon nitride film releasing hydrogen is used as the insulating film 106; and a silicon oxynitride film releasing oxygen is used as the insulating film 107.

To form the gate electrode 104, a conductive film is formed over the substrate 102, is patterned so that a desired region thereof remains, and unnecessary regions are etched.

Next, the first oxide semiconductor film 110 is formed in a region overlapping with the gate electrode 104 over the insulating film 108 (see FIG. 3B).

The first oxide semiconductor film 110 can be formed using any of the materials described above. In this embodiment, as the first oxide semiconductor film 110, an In-Ga—Zn oxide film, which is formed using a metal oxide target with In:Ga:Zn=1:1:1.2, is used.

The first oxide semiconductor film 110 can be formed in such a manner that an oxide semiconductor film is formed over the insulating film 108, the oxide semiconductor film is patterned so that a desired region thereof remains, and then unnecessary regions are etched.

After formation of the first oxide semiconductor film 110, heat treatment is preferably performed. The heat treatment is preferably performed at a temperature of higher than or equal to 250° C. and lower than or equal to 650° C., preferably higher than or equal to 300° C. and lower than or equal to 500° C., more preferably higher than or equal to 350° C. and lower than or equal to 450° C., in an inert gas atmosphere, an atmosphere containing an oxidizing gas at 10 ppm or more, or a reduced pressure atmosphere. Alternatively, the heat treatment may be performed first in an inert gas atmosphere, and then another heat treatment is performed in an atmosphere containing an oxidizing gas at 10 ppm or more in order to compensate oxygen released from the first oxide semiconductor film 110. By this heat treatment, impurities such as hydrogen and water can be removed from at least one of the insulating film 106, the insulating film 107, and the first oxide semiconductor film 110. Note that the above-described heat treatment may be performed before the first oxide semiconductor film 110 is processed into an island shape.

Note that stable electrical characteristics can be effectively imparted to the transistor 150 in which the first oxide semiconductor film 110 serves as a channel region by reducing the concentration of impurities in the first oxide semiconductor film 110 to make the first oxide semiconductor film 110 intrinsic or substantially intrinsic.

Next, a conductive film is formed over the insulating film 108 and the first oxide semiconductor film 110 and is patterned so that a desired region thereof remains and unnecessary regions are etched, whereby the source electrode 112a and the drain electrode 112b are formed over the insulating film 108 and the first oxide semiconductor film 110 (see FIG. 3C).

The source electrode 112a and the drain electrode 112b can be formed using a material selected from the above-described materials. Note that in this embodiment, a three-layered structure including a tungsten film, an aluminum film, and a titanium film can be used for the source electrode 112a and the drain electrode 112b.

After the source electrode 112a and the drain electrode 112b are formed, a surface of the first oxide semiconductor film 110 may be cleaned. The cleaning may be performed, for example, using a chemical solution such as phosphoric acid. The cleaning using a chemical solution such as a phosphoric acid can remove impurities (e.g., elements contained in the source electrode 112a and the drain electrode 112b) attached to the surface of the first oxide semiconductor film 110. Note that the cleaning is not necessarily performed, and thus the cleaning may be unnecessary.

In addition, in the step of forming the source electrode 112a and the drain electrode 112b and/or the cleaning step, the thickness of a region of the first oxide semiconductor film 110 which is not covered by the source electrode 112a and the drain electrode 112b might be reduced.

Next, the insulating films 114 and 116 are formed over the insulating film 108, the first oxide semiconductor film 110, the source electrode 112a, and the drain electrode 112b. Then, the insulating films 114 and 116 are patterned so that a desired region thereof remains and unnecessary regions are etched, whereby an opening 141 is formed (see FIG. 3D).

Note that after the insulating film 114 is formed, the insulating film 116 is preferably formed in succession without exposure to the air. After the insulating film 114 is formed, the insulating film 116 is formed in succession by adjusting at least one of the flow rate of a source gas, pressure, a high-frequency power, and a substrate temperature without exposure to the air, whereby the concentration of impurities attributed to the atmospheric component at the interface between the insulating film 114 and the insulating film 116 can be reduced, and oxygen in the insulating films 114 and 116 can be moved to the first oxide semiconductor film 110; accordingly, the amount of oxygen vacancy in the first oxide semiconductor film 110 can be reduced.

Note that the insulating film 114 functions as a protective film for the first oxide semiconductor film 110 in the step of forming the insulating film 116. Consequently, the insulating film 116 can be formed using the high-frequency power having a high power density while damage to the first oxide semiconductor film 110 is reduced.

The insulating films 114 and 116 can be formed using any of the materials described above. In this embodiment, a silicon oxynitride film capable of releasing oxygen is used as the insulating films 114 and 116.

Heat treatment (hereinafter referred to as first heat treatment) is preferably performed after the insulating films 114 and 116 are formed. The first heat treatment can reduce nitrogen oxide included in the insulating films 114 and 116. By the first heat treatment, part of oxygen included in the insulating films 114 and 116 can be moved to the first oxide semiconductor film 110, so that the amount of oxygen vacancy included in the first oxide semiconductor film 110 can be reduced.

The temperature of the first heat treatment is typically lower than 400° C., preferably lower than 375° C., further preferably higher than or equal to 150° C. and lower than or equal to 350° C. The first heat treatment may be performed under an atmosphere of nitrogen, oxygen, ultra-dry air (air with a water content of 20 ppm or less, preferably 1 ppm or less, more preferably 10 ppb or less), or a rare gas (argon, helium, or the like). The atmosphere of nitrogen, oxygen, ultra-dry air, or a rare gas preferably does not contain hydrogen, water, and the like. An electric furnace, a rapid thermal annealing (RTA) apparatus, or the like can be used for the heat treatment.

The opening 141 is formed to expose part of the drain electrode 112b. The opening 141 can be formed by a dry etching method, for example. Alternatively, a wet etching method or a combination of dry etching and wet etching can be employed for formation of the opening 141. Note that the etching step for forming the opening 141 can reduce the thickness of the drain electrode 112b in some cases.

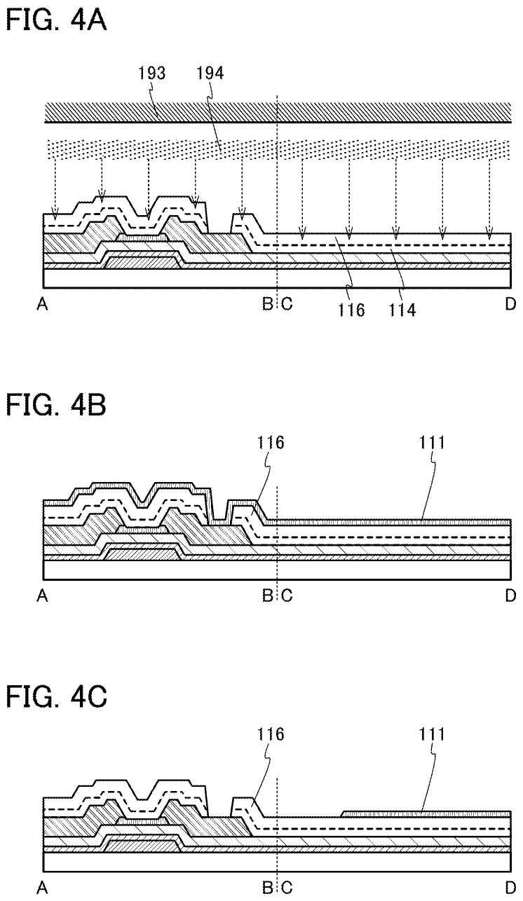

Next, an oxide semiconductor film to be the second oxide semiconductor film 111 is formed over the insulating film 116 to cover the opening 141 (see FIGS. 4A and 4B).

Note that FIG. 4A is a schematic cross-sectional view of the inside of a deposition apparatus when the oxide semiconductor film is formed over the insulating film 116. In FIG. 4A, a sputtering apparatus is used as the deposition apparatus, and a target 193 placed inside the sputtering apparatus and plasma 194 formed under the target 193 are schematically shown.

When the oxide semiconductor film is formed, plasma discharge is performed in an atmosphere containing an oxygen gas. At this time, oxygen is added to the insulating film 116 over which the oxide semiconductor film is to be formed. When the oxide semiconductor film is formed, an inert gas (e.g., a helium gas, an argon gas, or a xenon gas) and the oxygen gas may be mixed. For example, it is preferable to use the argon gas and the oxygen gas with the flow rate higher than the flow rate of the argon gas. When the flow rate of the oxygen gas is set higher, oxygen can be favorably added to the insulating film 116. As an example of the formation conditions of the oxide semiconductor film, the proportion of the oxygen gas in a whole deposition gas is higher than or equal to 50% and lower than or equal to 100%, preferably higher than or equal to 80% and lower than or equal to 100%.

In FIG. 4A, oxygen or excess oxygen added to the insulating film 116 is schematically shown by arrows of broken lines.

The oxide semiconductor film is formed at a substrate temperature higher than or equal to room temperature and lower than 340° C., preferably higher than or equal to room temperature and lower than or equal to 300° C., further preferably higher than or equal to 100° C. and lower than or equal to 250° C., still further preferably higher than or equal to 100° C. and lower than or equal to 200° C. The oxide semiconductor film is formed while being heated, so that the crystallinity of the oxide semiconductor film can be increased. On the other hand, in the case where a large-sized glass substrate (e.g., the 6th generation to the 10th generation) is used as the substrate 102 and the oxide semiconductor film is formed at a substrate temperature higher than or equal to 150° C. and lower than 340° C., the substrate 102 might be changed in shape (distorted or warped). In the case where a large-sized glass substrate is used, the change in the shape of the glass substrate can be suppressed by forming the oxide semiconductor film at a substrate temperature higher than or equal to 100° C. and lower than 150° C.

The oxide semiconductor film can be formed using any of the materials described above. In this embodiment, the oxide semiconductor film is formed by a sputtering method using an In-Ga—Zn metal oxide target (with an atomic ratio of In:Ga:Zn=1:3:6 [atomic ratio]).

Next, the oxide semiconductor film is processed into a desired shape to form the island-shaped second oxide semiconductor film 111 (see FIG. 4C).

The second oxide semiconductor film 111 can be formed in such a manner that an oxide semiconductor film is formed over the insulating film 116, the oxide semiconductor film is patterned so that a desired region thereof remains, and then unnecessary regions are etched.

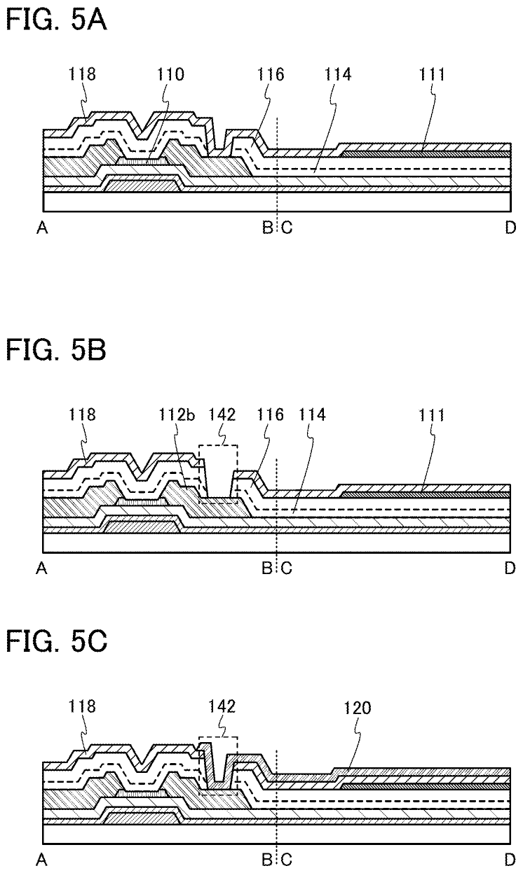

Next, the insulating film 118 is formed over the insulating film 116 and the second oxide semiconductor film 111 (see FIG. 5A).

The insulating film 118 includes one or both of hydrogen and nitrogen. As the insulating film 118, a silicon nitride film is preferably used, for example. The insulating film 118 can be formed by a sputtering method or a PECVD method, for example. In the case where the insulating film 118 is formed by a PECVD method, for example, the substrate temperature is lower than 400° C., preferably lower than 375° C., further preferably higher than or equal to 180° C. and lower than or equal to 350° C. The substrate temperature at which the insulating film 118 is formed is preferably within the above range because a dense film can be formed. Furthermore, when the substrate temperature at which the insulating film 118 is formed is within the above range, oxygen or excess oxygen in the insulating films 114 and 116 can be moved to the first oxide semiconductor film 110.

After the insulating film 118 is formed, heat treatment similar to the first heat treatment (hereinafter referred to as second heat treatment) may be performed. Through such heat treatment at lower than 400° C., preferably lower than 375° C., further preferably higher than or equal to 150° C. and lower than or equal to 350° C. after the addition of oxygen to the insulating film 116 when the oxide semiconductor film to be the second oxide semiconductor film 111 is formed, oxygen or excess oxygen in the insulating film 116 can be moved into the first oxide semiconductor film 110 and compensate oxygen vacancies in the first oxide semiconductor film 110.

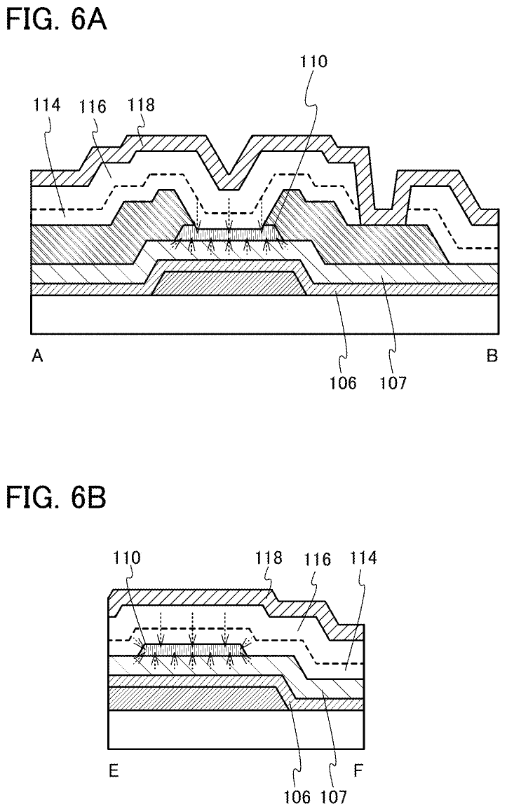

Oxygen moved to the first oxide semiconductor film 110 is described with reference to FIGS. 6A and 6B. FIGS. 6A and 6B are model diagrams illustrating oxygen moved to the first oxide semiconductor film 110 due to the substrate temperature at the time of forming the insulating film 118 (typically, lower than 375° C.) or the third heat treatment after the formation of the insulating film 118 (typically, lower than 375° C.). In FIGS. 6A and 6B, oxygen (oxygen radicals, oxygen atoms, or oxygen molecules) in the first oxide semiconductor film 110 are shown by arrows of broken lines. Note that FIGS. 6A and 6B are cross-sectional views respectively taken along dashed-dotted lines A-B and E-F in FIG. 1A, showing the state after the insulating film 118 is formed.

In the first oxide semiconductor film 110 in FIGS. 6A and 6B, oxygen vacancies are compensated with oxygen moved from films in contact with the first oxide semiconductor film 110 (here, the insulating film 107 and the insulating film 114). Specifically, in the semiconductor device of one embodiment of the present invention, the insulating film 107 includes an excess oxygen region because an oxygen gas is used at the time of forming the oxide semiconductor film to be the first oxide semiconductor film 110 by sputtering and oxygen is added to the insulating film 107. Furthermore, the insulating film 116 includes an excess oxygen region because an oxygen gas is used at the time of forming the oxide semiconductor film to be the second oxide semiconductor film 111 by sputtering and oxygen is added to the insulating film 116. In the first oxide semiconductor film 110 between the insulating films including the excess oxygen regions, oxygen vacancies can be favorably compensated.

Furthermore, the insulating film 106 is provided under the insulating film 107, and the insulating film 118 is provided over the insulating films 114 and 116. When the insulating films 106 and 118 are formed using a material having low oxygen permeability, e.g., silicon nitride, oxygen contained in the insulating films 107, 114, and 116 can be confined to the first oxide semiconductor film 110 side; thus, oxygen can be favorably moved to the first oxide semiconductor film 110. Note that the insulating layer 118 also has an advantageous effect of preventing an external impurity such as water, alkali metal, or alkaline earth metal, from diffusing into the first oxide semiconductor film 110 included in the transistor 150.

The insulating film 118 contains one or both of hydrogen and nitrogen. Thus, one or both of hydrogen and nitrogen is added to the second oxide semiconductor film 111 in contact with the formed insulating film 118, so that the second oxide semiconductor film 111 have high carrier density and can function as an oxide conductive film.

Note that since the resistivity of the second oxide semiconductor film 111 is decreased, the second oxide semiconductor film 111 in FIG. 5A is indicated by a different hatching pattern from that in FIG. 4C.

The resistivity of the second oxide semiconductor film 111 is lower than at least the resistivity of the first oxide semiconductor film 110 and is preferably higher than or equal to 1×10⁻³ Ωcm and lower than 1×10⁴ Ωcm, further preferably higher than or equal to 1×10⁻³ Ωcm and lower than 1×10⁻¹ Ωcm.

Then, the opening 142 is formed as follows: the insulating film 118 is patterned so that a desired region thereof remains and unnecessary regions are etched (see FIG. 5B).

The opening 142 is formed to expose part of the drain electrode 112b. The opening 142 can be formed by a dry etching method, for example. Alternatively, a wet etching method or a combination of dry etching and wet etching can be employed for formation of the opening 142. Note that the etching step for forming the opening 142 can reduce the thickness of the drain electrode 112b in some cases.

Note that the opening may be formed in the insulating films 114, 116, and 118 at one time in the step of forming the opening 142 without performing the step of forming the opening 141. In this case, the number of steps of manufacturing the semiconductor device of one embodiment of the present invention is reduced, resulting in a reduction of the manufacturing cost.

Then, a conductive film is formed over the insulating film 118 to cover the opening 142 and is patterned and etched so that a desired region thereof remains; thus, the conductive film 120 is formed (see FIG. 5C).

The conductive film 120 can be formed using any of the materials described above. Note that in this embodiment, an indium tin oxide film is used as the conductive film 120.

The capacitor 160 is formed concurrently with the conductive film 120. The capacitor 160 includes a dielectric layer between a pair of electrodes. One of the pair of electrodes corresponds to the second oxide semiconductor film 111, and the other electrode corresponds to the conductive film 120. In addition, the insulating film 118 serves as a dielectric layer of the capacitor 160.

Through the above steps, the transistor 150 and the capacitor 160 can be formed over one substrate.

The structures, the methods, and the like described in this embodiment can be combined as appropriate with any of the structures, the methods, and the like described in the other embodiments.

### Embodiment 2

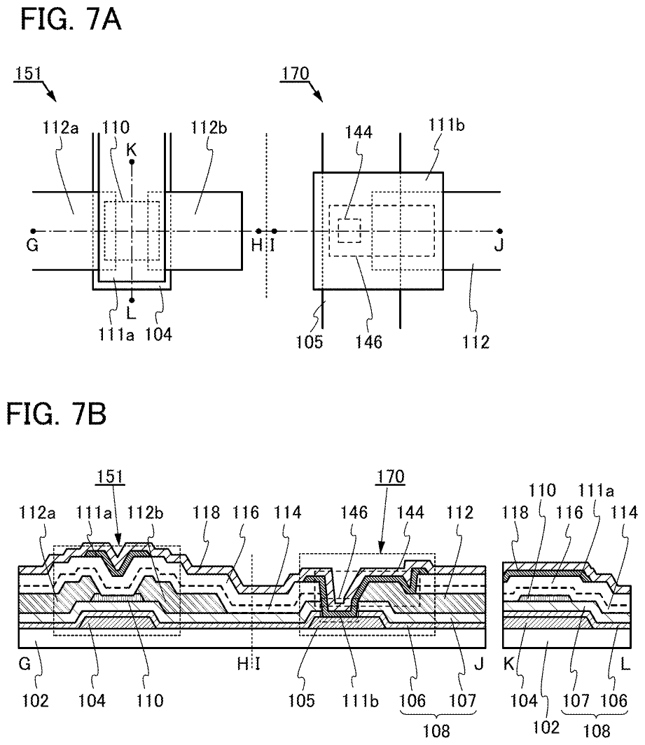

In this embodiment, a modification example of the semiconductor device of one embodiment of the present invention described in Embodiment 1 will be described with reference to FIGS. 7A and 7B, FIGS. 8A to 8D, and FIGS. 9A to 9C. Note that portions similar to or having functions similar to those in FIGS. 1A and 1B, FIGS. 2A and 2B, FIGS. 3A to 3D, and FIGS. 4A to 4C are denoted by the same reference numerals, and description thereof is not repeated.

### Structure Example of Semiconductor Device (Modification Example 1)

FIG. 7A is a top view of the semiconductor device of one embodiment of the present invention. FIG. 7B is a cross-sectional view taken along the dashed-dotted lines G-H, I-J, and K-L shown in FIG. 7A. Note that in FIG. 7A, some components of the semiconductor device (e.g., a gate insulating film) are not illustrated to avoid complexity.

The semiconductor device shown in FIGS. 7A and 7B includes a transistor 151 including the first oxide semiconductor film 110 and the second oxide semiconductor film 111a and a gate wiring contact portion 170 including a second oxide semiconductor film 111b. Note that the gate wiring contact portion 170 means a region where the gate wiring 105 is electrically connected to the wiring 112.

Note that the direction of the dashed-dotted line G-H in FIG. 7A is referred to as a channel length direction of a transistor 151. The direction of the dashed-dotted line K-L is referred to as a channel width direction of the transistor 151.

The transistor 151 includes the gate electrode 104 over the substrate 102, the insulating film 108 serving as a first gate insulating film over the gate electrode 104, the first oxide semiconductor film 110 overlapping with the gate electrode 104 over the insulating film 108, the source electrode 112a and the drain electrode 112b over the first oxide semiconductor film 110, the insulating films 114 and 116 each serving as a second gate insulating film over the first oxide semiconductor film 110, the source electrode 112a, and the drain electrode 112b, and the second oxide semiconductor film 111a overlapping with the first oxide semiconductor film 110 over the insulating film 116. The second oxide semiconductor film 111a serves as a second gate electrode in the transistor 151. In other words, the transistor 151 shown in FIGS. 7A and 7B has a double-gate structure.

In addition, over the transistor 151, specifically over the insulating film 116 and the second oxide semiconductor film 111a, the insulating film 118 is formed. The insulating films 114 and 116 each serve as not only a second gate insulating film for the transistor 151 but also a protective insulating film for the transistor 151. In addition, the insulating film 118 serves as a protective insulating film for the transistor 151.

In the gate wiring contact portion 170, the second oxide semiconductor film 111b is formed over the gate wiring 105 and the wiring 112 to cover an opening 146 in the insulating film 108 and an opening 144 in the insulating films 114 and 116.

In the semiconductor device described in this embodiment, the gate wiring 105 is electrically connected to the wiring 112 through the second oxide semiconductor film 111b in the gate wiring contact portion 170. Owing to such a structure, the opening 144 and the opening 146 are formed successively and accordingly the manufacturing process of the semiconductor device can be shortened.

In addition, if a protective film for blocking entry of oxygen is not provided over the second oxide semiconductor film 111b, the characteristics of the second oxide semiconductor film 111b may be changed under high-temperature and high-humidity environment and the resistivity of the second oxide semiconductor film 111b may be increased. The second oxide semiconductor film 111b of the semiconductor device described in this embodiment is covered by the insulating film 118; thus, high-temperature and humidity resistance of the semiconductor device is improved without forming another protective film.

Note that an insulating film containing at least hydrogen is used as the insulating film 118. In addition, an insulating film containing at least oxygen is used as each of the insulating films 107, 114, and 116. As described above, the insulating film included in the transistor 151 and the gate wiring contact portion 170 or the insulating film in contact with the transistor 151 and the gate wiring contact portion 170 have the above-described structures, whereby the resistivity of the first oxide semiconductor film 110 and the second oxide semiconductor films 111a and 111b can be controlled.

Note that the description of Embodiment 1 can be referred to for the method of controlling the resistivity of the first oxide semiconductor film 110 and the second oxide semiconductor films 111a and 111b.

The major difference between the semiconductor device described in FIGS. 1A and 1B and the semiconductor device shown in FIGS. 7A and 7B in Embodiment 1 are that the gate wiring contact portion 170 is provided instead of the capacitor 160, that the second oxide semiconductor film 111a serving as a second gate electrode is provided in the transistor 151, and that the conductive film 120 is not provided.

### Method for Manufacturing Display Device (Modification Example 1)

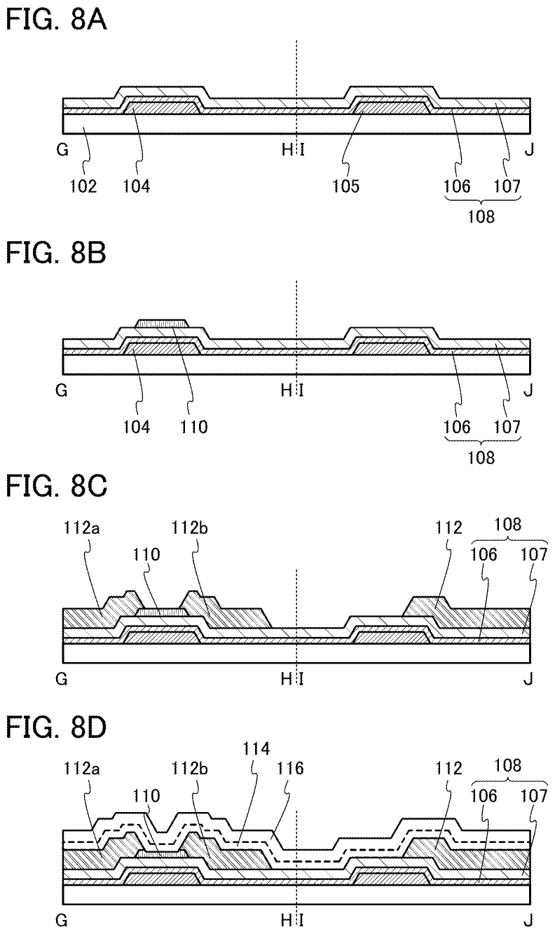

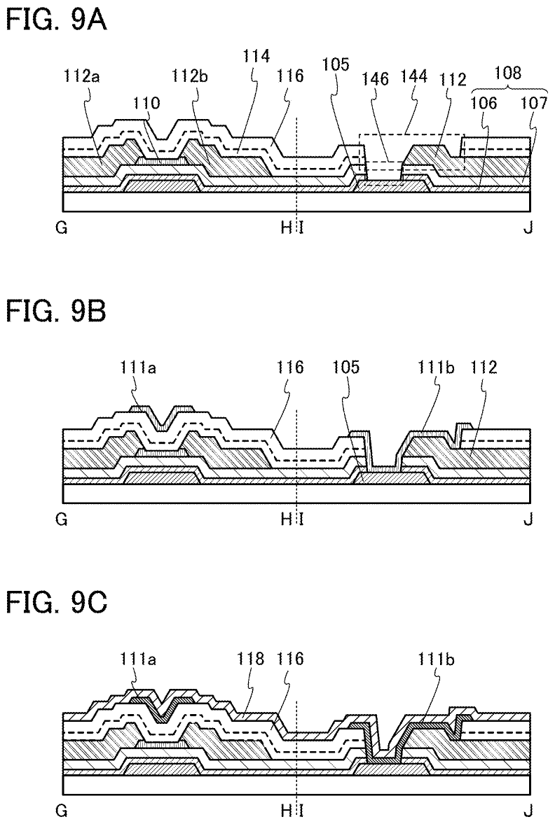

Next, an example of a method for manufacturing the semiconductor device illustrated in FIGS. 7A and 7B is described with reference to FIGS. 8A to 8D and FIGS. 9A to 9C.

First, the gate electrode 104 and the gate wiring 105 are formed over the substrate 102. Then, the insulating film 108 consisting of the insulating films 106 and 107 are formed over the gate electrode 104 and the gate wiring 105 (see FIG. 8A). The gate wiring 105 can be formed using the material similar to that of the gate electrode 104 and at the same time as the gate electrode 104.

Next, the first oxide semiconductor film 110 is formed over the insulating film 108 to overlap with the gate electrode 104 (see FIG. 8B).

The first oxide semiconductor film 110 is formed as follows: an oxide semiconductor film is formed over the insulating film 108, is patterned so that a desired region thereof remains, and unnecessary regions are etched.

Note that when the first oxide semiconductor film 110 is processed by etching, part of the insulating film 107 (a region not covered by the first oxide semiconductor film 110) might be etched and reduced in thickness because of overetching of the first oxide semiconductor film 110.

After formation of the first oxide semiconductor film 110, heat treatment is preferably performed. The description of the heat treatment after formation of the first oxide semiconductor film 110 in Embodiment 1 can be referred to for the heat treatment here.

Next, a conductive film is formed over the insulating film 108 and the first oxide semiconductor film 110, is patterned so that a desired region thereof remains and unnecessary regions are etched, whereby the source electrode 112a, the drain electrode 112b, the wiring 112 are formed (see FIG. 8C). The wiring 112 can be formed simultaneously with and using the material similar to that of the source electrode 112a and the drain electrode 112b.

Next, the insulating films 114 and 116 are formed over the insulating film 108, the first oxide semiconductor film 110, the source electrode 112a, the drain electrode 112b, and the wiring 112 (see FIG. 8D). After the insulating films 114 and 116 are formed, the first heat treatment described in Embodiment 1 is preferably performed.

Then, the opening 144 and the opening 146 are formed as follows: the insulating films 106, 107, 114, and 116 are patterned so that a desired region thereof remains and unnecessary regions are etched (see FIG. 9A).

The wiring 112 and the gate wiring 105 are formed to be exposed from the opening 144 and the opening 146. The opening 144 and the opening 146 can be formed by a dry etching method, for example. Note that there is no limitation on the formation method, and a wet etching method or a combination of dry etching and wet etching can be employed to form the opening 144 and the opening 146.

The opening 144 and the opening 146 are patterned and etched at one time, so that they are formed at the same time, leading to shortening the manufacturing process.

Next, the second oxide semiconductor film 111a is formed over the insulating film 116 to overlap with the first oxide semiconductor film 110, and concurrently, the second oxide semiconductor film 111b is formed over the insulating film 116 to cover the opening 144 and the opening 146 (see FIG. 9B). The description of the second oxide semiconductor film 111 in Embodiment 1 can be referred to for the method of forming the second oxide semiconductor film 111a and the second oxide semiconductor film lib.

The second oxide semiconductor films 111a and lib can be formed as follows: an oxide semiconductor film is formed over the insulating film 116 and is patterned so that a desired region thereof remains and unnecessary regions are etched.

Note that when the second oxide semiconductor films 111a and 111b are etched, part of the insulating film 116 (a region not covered by the second oxide semiconductor films 111a and 111b) might be etched and reduced in thickness because of the overetching of the second oxide semiconductor films 111a and 111b.

Next, the insulating film 118 is formed over the insulating film 116 and the second oxide semiconductor films 111a and 111b (see FIG. 9C). Hydrogen contained in the insulating film 118 is diffused into the second oxide semiconductor films 111a and 111b, so that the resistivity of the second oxide semiconductor films 111a and 111b is decreased. Note that since the resistivity of the second oxide semiconductor films 111a and 111b is decreased, the second oxide semiconductor films 111a and 111b in FIG. 9B is indicated by a different hatching pattern from that in FIG. 9C. In addition, the second heat treatment described in Embodiment 1 may be performed after the insulating film 118 is formed.

Through the above steps, the transistor 151 and the gate wiring contact portion 170 are formed over one substrate.

The structures, the methods, and the like described in this embodiment can be combined as appropriate with any of the structures, the methods, and the like described in the other embodiments.

### Embodiment 3

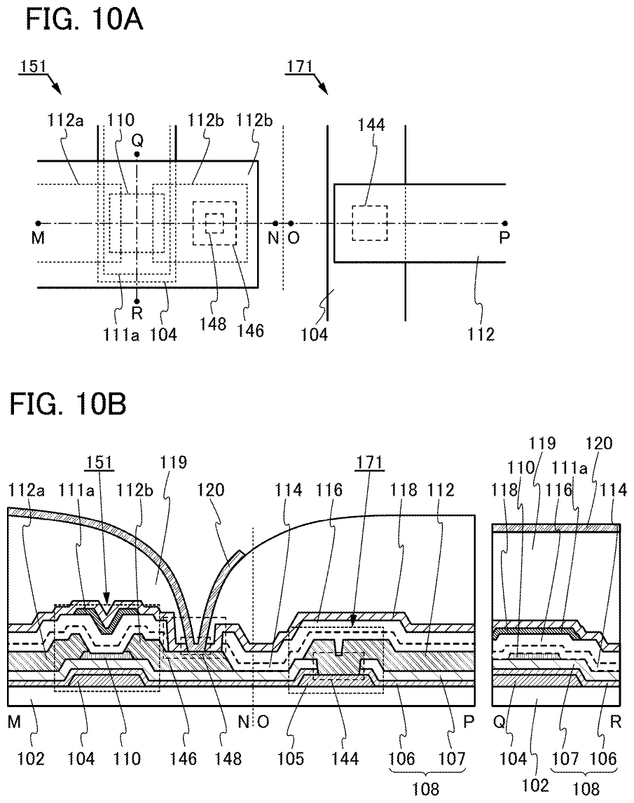

In this embodiment, as semiconductor devices of embodiments of the present invention, variations of the structure that is described in Embodiment 1 are described with reference to FIGS. 10A and 10B, FIGS. 11A to 11C, and FIGS. 12A to 12C. Note that portions similar to or having functions similar to those in FIGS. 1A and 1B, FIGS. 2A and 2B, FIGS. 3A to 3D, and FIGS. 4A to 4C, which are used in Embodiment 1, are denoted by the same reference numerals, and description thereof is not repeated.

### Structure Example of Semiconductor Device (Modification Example 2)

FIG. 10A is a top view of the semiconductor device of one embodiment of the present invention. FIG. 10B is a cross-sectional view taken along the dashed-dotted lines M-N, O-P, and Q-R shown in FIG. 10A. Note that in FIG. 10A, some components of the semiconductor device (e.g., a gate insulating film) are not illustrated to avoid complexity.

The semiconductor device shown in FIGS. 10A and 10B includes a transistor 151 including the first oxide semiconductor film 110 and the second oxide semiconductor film 111a and a gate wiring contact portion 171. Note that the gate wiring contact portion 171 means a region where the gate wiring 105 is electrically connected to the wiring 112.

Note that the direction of the dashed-dotted line M-N in FIG. 10A is referred to as a channel length direction of a transistor 151. The direction of the dashed-dotted line Q-R is referred to as a channel width direction of the transistor 151.

The transistor 151 includes the gate electrode 104 over the substrate 102, the insulating film 108 serving as a first gate insulating film over the gate electrode 104, the first oxide semiconductor film 110 overlapping with the gate electrode 104 over the insulating film 108, the source electrode 112a and the drain electrode 112b over the first oxide semiconductor film 110, the insulating films 114 and 116 each serving as a second gate insulating film over the first oxide semiconductor film 110, the source electrode 112a, and the drain electrode 112b, and the second oxide semiconductor film 111a overlapping with the first oxide semiconductor film 110 over the insulating film 116. The second oxide semiconductor film 111a serves as a second gate electrode in the transistor 151. In other words, the transistor 151 shown in FIGS. 10A and 10B has a double-gate structure.

In addition, over the transistor 151, specifically over the insulating film 116 and the second oxide semiconductor film 111a, the insulating film 118 and an insulating film 119 are formed. The insulating films 114 and 116 each serve as not only a second gate insulating film for the transistor 151 but also a protective insulating film for the transistor 151. The insulating film 118 serves as a protective insulating film for the transistor 151. The insulating film 119 serves as a planarization film. In addition, an opening reaching the drain electrode 112b is formed in the insulating films 114, 116, 118, and 119. The conductive film 120 is formed over the insulating film 119 to cover the opening. The opening in the insulating films 114 and 116 is an opening 146, and the opening in the insulating film 119 is an opening 148. The conductive film 120 serves as a pixel electrode, for example.

In the gate wiring contact portion 171, the wiring 112 is formed over the gate wiring 105 to cover the opening 144 in the insulating film 108.

In the semiconductor device described in this embodiment, the edges of the insulating films 118 and 119 are substantially aligned in the opening 148. Since the semiconductor device has such a structure, the number of masks used for patterning can be reduced and accordingly the manufacturing cost can be reduced.

Note that an insulating film containing at least hydrogen is used as the insulating film 118. In addition, an insulating film containing at least oxygen is used as each of the insulating films 107, 114, and 116. As described above, the insulating film included in the transistor 151 or the insulating film in contact with the transistor 151 have the above-described structures, whereby the resistivity of the first oxide semiconductor film 110 and the second oxide semiconductor film 111a included in the transistor 151 is controlled.

Note that the description of Embodiment 1 can be referred to for the method of controlling the resistivity of the first oxide semiconductor film 110 and the second oxide semiconductor film 111a.

The major difference between the semiconductor device described in FIGS. 1A and 1B and the semiconductor device shown in FIGS. 10A and 10B in Embodiment 1 are that the gate wiring contact portion 171 is provided instead of the capacitor 160, that the second oxide semiconductor film 111a serving as a second gate electrode is provided in the transistor 151, and that the insulating film 119 is provided.

### Method for Manufacturing Display Device (Modification Example 2)

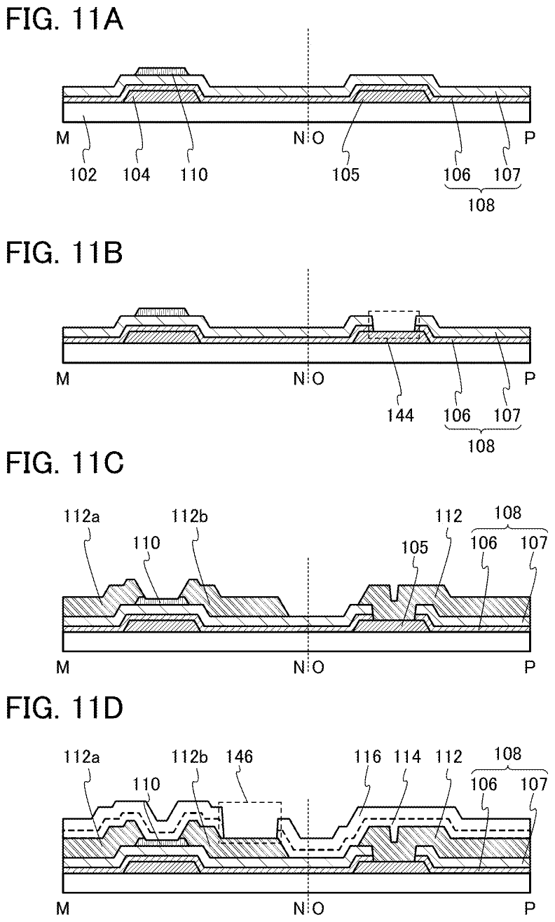

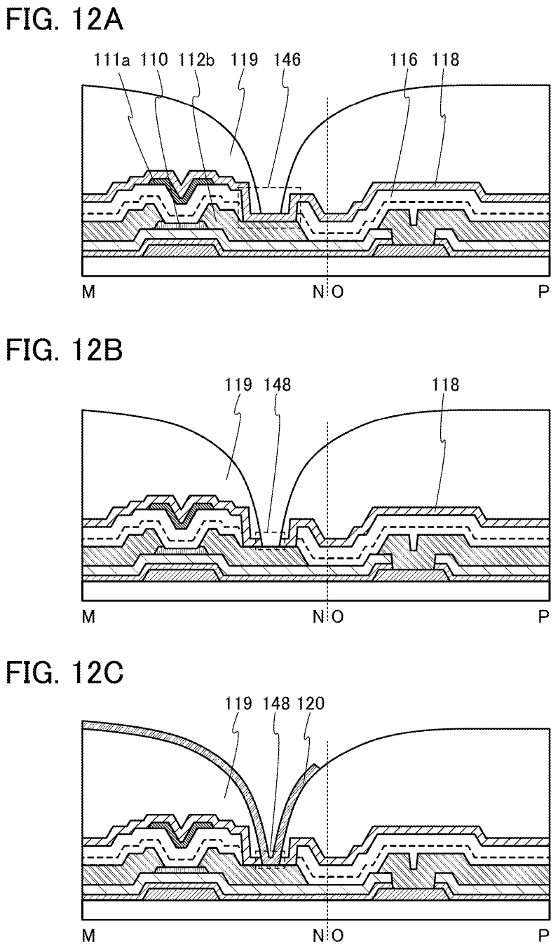

Next, an example of a method for manufacturing the semiconductor device illustrated in FIGS. 10A and 10B is described with reference to FIGS. 11A to 11D and FIGS. 12A to 12C. First, the gate electrode 104 and the gate wiring 105 are formed over the substrate 102. Then, the insulating film 108 consisting of the insulating films 106 and 107 are formed over the gate electrode 104 and the gate wiring 105. The gate wiring 105 can be formed using the material similar to that of the gate electrode 104 and at the same time as the gate electrode 104.

Next, the first oxide semiconductor film 110 is formed over the insulating film 108 to overlap with the gate electrode 104 (see FIG. 11A).

The first oxide semiconductor film 110 is formed as follows: an oxide semiconductor film is formed over the insulating film 108, is patterned so that a desired region thereof remains, and unnecessary regions are etched.

Nota that when the first oxide semiconductor film 110 is processed by etching, part of the insulating film 108 (a region not covered by the first oxide semiconductor film 110) might be etched and reduced in thickness because of overetching of the first oxide semiconductor film 110.

After formation of the first oxide semiconductor film 110, heat treatment is preferably performed. The description of the heat treatment after formation of the first oxide semiconductor film 110 in Embodiment 1 can be referred to for the heat treatment here.

Then, the opening 144 is formed as follows: the insulating films 106 and 107 are patterned so that a desired region thereof remains and then unnecessary regions are etched (see FIG. 11B).

The gate wiring 105 is formed to be exposed from the opening 144. The opening 144 can be formed by a dry etching method, for example. Note that there is no limitation on the formation method, and a wet etching method or a combination of dry etching and wet etching can be employed to form the opening 144.

Next, a conductive film is formed over the insulating film 108, the gate wiring 105, and the first oxide semiconductor film 110, is patterned so that a desired region thereof remains and unnecessary regions are etched, whereby the source electrode 112a, the drain electrode 112b, the wiring 112 are formed (see FIG. 11C). The wiring 112 can be formed simultaneously with and using the material similar to that of the source electrode 112a and the drain electrode 112b.

Next, the insulating films 114 and 116 are formed over the insulating film 108, the first oxide semiconductor film 110, the source electrode 112a, the drain electrode 112b, and the wiring 112. After the insulating films 114 and 116 are formed, the first heat treatment described in Embodiment 1 is preferably performed.

Then, the opening 146 is formed as follows: the insulating films 114 and 116 are patterned so that a desired region thereof remains and unnecessary regions are etched (see FIG. 11D).

The drain electrode 112b is formed to be exposed from the opening 146. The opening 146 can be formed by a dry etching method, for example. Note that there is no limitation on the formation method, and a wet etching method or a combination of dry etching and wet etching can be employed to form the opening 146.

Next, the second oxide semiconductor film 111a is formed over the insulating film 116 to overlap with the first oxide semiconductor film 110. The description of the second oxide semiconductor film 111 in Embodiment 1 can be referred to for the method of the second oxide semiconductor film 111a.

The second oxide semiconductor film 111a can be formed in such a manner that an oxide semiconductor film is formed over the insulating film 116, the oxide semiconductor film is patterned so that a desired region thereof remains, and then unnecessary regions are etched.

Note that when the second oxide semiconductor film 111a is etched, part of the insulating film 116 (a region not covered by the second oxide semiconductor film 111a) might be etched and reduced in thickness because of the overetching of the second oxide semiconductor film 111a.

Next, the insulating film 118 is formed over the insulating film 116, the second oxide semiconductor film 111a, and the drain electrode 112b. Hydrogen contained in the insulating film 118 is diffused into the second oxide semiconductor film 111a, so that the resistivity of the second oxide semiconductor film 111a is decreased.

Next, the insulating film 119 is formed over the insulating film 118 (see FIG. 12A). The insulating film 119 can be formed using a heat-resistant organic material, such as a polyimide resin, an acrylic resin, a polyimide amide resin, a benzocyclobutene resin, a polyamide resin, or an epoxy resin. An organic resin film is formed over the insulating film, is patterned so that a desired region thereof remains, and unnecessary regions are etched, whereby an opening overlapping with the opening 146 is formed.

Then, the insulating film 118 is etched using the insulating film 119 having the opening as a mask, whereby the opening 148 is formed (see FIG. 12B). Because the insulating film 119 can be used as a mask, there is no need to use another mask for forming the opening 148 and to perform patterning, which results in a reduction in manufacturing cost of the semiconductor device.

Then, a conductive film is formed over the insulating film 119 to cover the opening 148 and is patterned and etched so that a desired region thereof remains; thus, the conductive film 120 is formed (see FIG. 12C).

Through the above steps, the transistor 151 and the gate wiring contact portion 171 are formed over one substrate.

The structures, the methods, and the like described in this embodiment can be combined as appropriate with any of the structures, the methods, and the like described in the other embodiments.

### Embodiment 4

Described in this embodiment is an example of an oxide semiconductor which can be used for the transistor, the capacitor, and the gate wiring contact portion of the semiconductor device of one embodiment of the present invention.

The structure of an oxide semiconductor is described below.

In this specification, the term “parallel” indicates that the angle formed by two straight lines is greater than or equal to −10° and less than or equal to 10°, and is greater than or equal to −5° and less than or equal to 5°. The term “substantially parallel” indicates that the angle formed by two straight lines is greater than or equal to −30° and less than or equal to 30°. In addition, the term “perpendicular” indicates that the angle formed by two straight lines is greater than or equal to 80° and less than or equal to 100°, and is greater than or equal to 85° and less than or equal to 95°. The term “substantially perpendicular” indicates that the angle formed between two straight lines is greater than or equal to 60° and less than or equal to 120°.

In this specification, trigonal and rhombohedral crystal systems are included in a hexagonal crystal system.

An oxide semiconductor is classified into a single crystal oxide semiconductor and a non-single-crystal oxide semiconductor. Examples of a non-single-crystal oxide semiconductor include a c-axis aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

From another perspective, an oxide semiconductor is classified into an amorphous oxide semiconductor and a crystalline oxide semiconductor. Examples of a crystalline oxide semiconductor include a single crystal oxide semiconductor, a CAAC-OS, a polycrystalline oxide semiconductor, and an nc-OS.

It is known that an amorphous structure is generally defined as being metastable and unfixed, and being isotropic and having no non-uniform structure. In other words, an amorphous structure has a flexible bond angle and a short-range order but does not have a long-range order.

This means that an inherently stable oxide semiconductor cannot be regarded as a completely amorphous oxide semiconductor. Moreover, an oxide semiconductor that is not isotropic (e.g., an oxide semiconductor that has a periodic structure in a microscopic region) cannot be regarded as a completely amorphous oxide semiconductor. Note that an a-like OS has a periodic structure in a microscopic region, but at the same time has a void and has an unstable structure. For this reason, an a-like OS has physical properties similar to those of an amorphous oxide semiconductor.

### <CAAC-OS>

First, a CAAC-OS is described.

A CAAC-OS is one of oxide semiconductors having a plurality of c-axis aligned crystal parts (also referred to as pellets).

In a combined analysis image (also referred to as a high-resolution TEM image) of a bright-field image and a diffraction pattern of a CAAC-OS, which is obtained using a transmission electron microscope (TEM), a plurality of pellets can be observed. However, in the high-resolution TEM image, a boundary between pellets, that is, a grain boundary is not clearly observed. Thus, in the CAAC-OS, a reduction in electron mobility due to the grain boundary is less likely to occur.

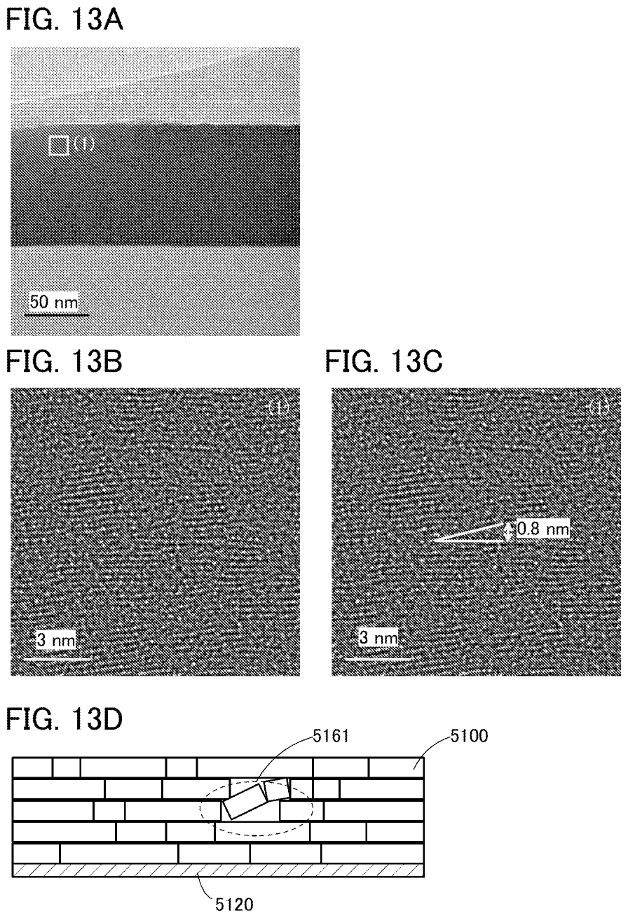

A CAAC-OS observed with TEM is described below. FIG. 13A shows a high-resolution TEM image of a cross section of the CAAC-OS which is observed from a direction substantially parallel to the sample surface. The high-resolution TEM image is obtained with a spherical aberration corrector function. The high-resolution TEM image obtained with a spherical aberration corrector function is particularly referred to as a Cs-corrected high-resolution TEM image. The Cs-corrected high-resolution TEM image can be obtained with, for example, an atomic resolution analytical electron microscope JEM-ARM200F manufactured by JEOL Ltd.

FIG. 13B is an enlarged Cs-corrected high-resolution TEM image of a region (1) in FIG. 13A. FIG. 13B shows that metal atoms are arranged in a layered manner in a pellet. Each metal atom layer has a configuration reflecting unevenness of a surface over which the CAAC-OS is formed (hereinafter, the surface is referred to as a formation surface) or a top surface of the CAAC-OS, and is arranged parallel to the formation surface or the top surface of the CAAC-OS.

As shown in FIG. 13B, the CAAC-OS has a characteristic atomic arrangement. The characteristic atomic arrangement is denoted by an auxiliary line in FIG. 13C. FIGS. 13B and 13C prove that the size of a pellet is greater than or equal to 1 nm or greater than or equal to 3 nm, and the size of a space caused by tilt of the pellets is approximately 0.8 nm. Therefore, the pellet can also be referred to as a nanocrystal (nc). Note that a CAAC-OS can be referred to as an oxide semiconductor including c-axis aligned nanocrystals (CANC).

Here, according to the Cs-corrected high-resolution TEM images, the schematic arrangement of pellets 5100 of a CAAC-OS over a substrate 5120 is illustrated by such a structure in which bricks or blocks are stacked (see FIG. 13D). The part in which the pellets are tilted as observed in FIG. 13C corresponds to a region 5161 shown in FIG. 13D.

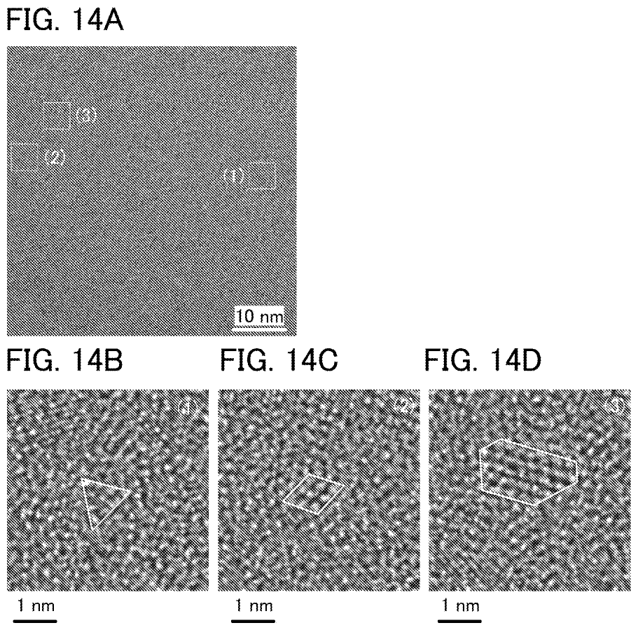

FIG. 14A shows a Cs-corrected high-resolution TEM image of a plane of the CAAC-OS observed from a direction substantially perpendicular to the sample surface. FIGS. 14B, 14C, and 14D are enlarged Cs-corrected high-resolution TEM images of regions (1), (2), and (3) in FIG. 14A, respectively. FIGS. 14B, 14C, and 14D indicate that metal atoms are arranged in a triangular, quadrangular, or hexagonal configuration in a pellet. However, there is no regularity of arrangement of metal atoms between different pellets.

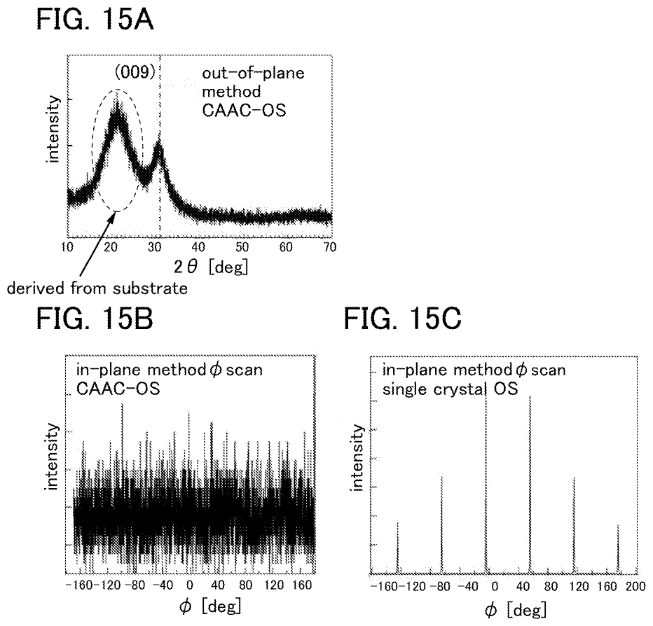

Next, a CAAC-OS analyzed by X-ray diffraction (XRD) is described. For example, when the structure of a CAAC-OS including an InGaZnO₄ crystal is analyzed by an out-of-plane method, a peak appears at a diffraction angle (2θ) of around 31° as shown in FIG. 15A. This peak is derived from the (009) plane of the InGaZnO₄ crystal, which indicates that crystals in the CAAC-OS have c-axis alignment, and that the c-axes are aligned in a direction substantially perpendicular to the formation surface or the top surface of the CAAC-OS.

Note that in structural analysis of the CAAC-OS by an out-of-plane method, another peak may appear when 2θ is around 36°, in addition to the peak at 2θ of around 31°. The peak at 2θ of around 36° indicates that a crystal having no c-axis alignment is included in part of the CAAC-OS. It is preferable that in the CAAC-OS analyzed by an out-of-plane method, a peak appear when 2θ is around 31° and that a peak not appear when 2θ is around 36°.

On the other hand, in structural analysis of the CAAC-OS by an in-plane method in which an X-ray is incident on a sample in a direction substantially perpendicular to the c-axis, a peak appears when 2θ is around 56°. This peak is attributed to the (110) plane of the InGaZnO₄ crystal. In the case of the CAAC-OS, when analysis (ϕ scan) is performed with 20 fixed at around 560 and with the sample rotated using a normal vector of the sample surface as an axis (ϕ axis), as shown in FIG. 15B, a peak is not clearly observed. In contrast, in the case of a single crystal oxide semiconductor of InGaZnO₄, when ϕ scan is performed with 20 fixed at around 56°, as shown in FIG. 15C, six peaks which are derived from crystal planes equivalent to the (110) plane are observed. Accordingly, the structural analysis using XRD shows that the directions of a-axes and b-axes are irregularly oriented in the CAAC-OS.

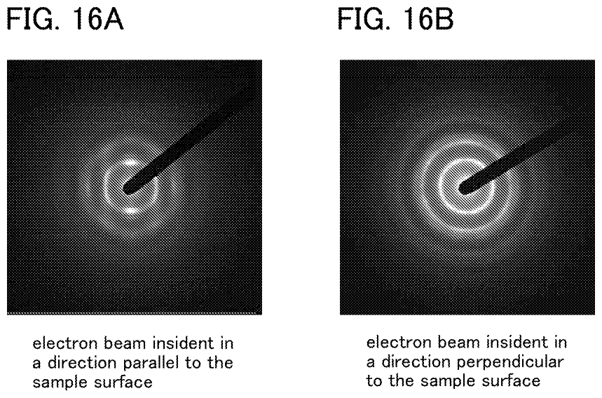

Next, a CAAC-OS analyzed by electron diffraction is described. For example, when an electron beam with a probe diameter of 300 nm is incident on a CAAC-OS including an InGaZnO₄ crystal in a direction parallel to the sample surface, a diffraction pattern (also referred to as a selected-area transmission electron diffraction pattern) shown in FIG. 16A can be obtained. In this diffraction pattern, spots derived from the (009) plane of an InGaZnO₄ crystal are included. Thus, the electron diffraction also indicates that pellets included in the CAAC-OS have c-axis alignment and that the c-axes are aligned in a direction substantially perpendicular to the formation surface or the top surface of the CAAC-OS. Meanwhile, FIG. 16B shows a diffraction pattern obtained in such a manner that an electron beam with a probe diameter of 300 nm is incident on the same sample in a direction perpendicular to the sample surface. As shown in FIG. 16B, a ring-like diffraction pattern is observed. Thus, the electron diffraction also indicates that the a-axes and b-axes of the pellets included in the CAAC-OS do not have regular alignment. The first ring in FIG. 16B is considered to be derived from the (010) plane, the (100) plane, and the like of the InGaZnO₄ crystal. The second ring in FIG. 16B is considered to be derived from the (110) plane and the like.

As described above, the CAAC-OS is an oxide semiconductor with high crystallinity. Entry of impurities, formation of defects, or the like might decrease the crystallinity of an oxide semiconductor. This means that the CAAC-OS has small amounts of impurities and defects (e.g., oxygen vacancies).

Note that the impurity means an element other than the main components of the oxide semiconductor, such as hydrogen, carbon, silicon, or a transition metal element. For example, an element (specifically, silicon or the like) having higher strength of bonding to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

The characteristics of an oxide semiconductor having impurities or defects might be changed by light, heat, or the like. Impurities contained in the oxide semiconductor might serve as carrier traps or carrier generation sources, for example. Furthermore, oxygen vacancies in the oxide semiconductor serve as carrier traps or serve as carrier generation sources when hydrogen is captured therein.

The CAAC-OS having small amounts of impurities and oxygen vacancies is an oxide semiconductor with low carrier density. Specifically, the carrier density is lower than 8×10¹¹/cm³, preferably lower than 1×10¹¹/cm³, more preferably lower than 1×10¹⁰/cm³, and is higher than or equal to 1×10¹¹/cm³. A CAAC-OS has a low impurity concentration and a low density of defect states. Thus, the CAAC-OS can be referred to as an oxide semiconductor having stable characteristics.

<nc-OS>

Next, an nc-OS is described.

An nc-OS has a region in which a crystal part is observed and a region in which a crystal part is not clearly observed in a high-resolution TEM image. In most cases, the size of a crystal part included in the nc-OS is greater than or equal to 1 nm and less than or equal to 10 nm, or greater than or equal to 1 nm and less than or equal to 3 nm. Note that an oxide semiconductor including a crystal part whose size is greater than 10 nm and less than or equal to 100 nm is sometimes referred to as a microcrystalline oxide semiconductor. In a high-resolution TEM image of the nc-OS, for example, a grain boundary is not clearly observed in some cases. Note that there is a possibility that the origin of the nanocrystal is the same as that of a pellet in a CAAC-OS. Therefore, a crystal part of the nc-OS may be referred to as a pellet in the following description.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not observed. Accordingly, the nc-OS cannot be distinguished from an a-like OS or an amorphous oxide semiconductor, depending on an analysis method. For example, when the nc-OS is analyzed by an out-of-plane method using an X-ray beam having a diameter larger than the size of a pellet, a peak which shows a crystal plane does not appear. Furthermore, a diffraction pattern like a halo pattern is observed when the nc-OS is subjected to electron diffraction using an electron beam with a probe diameter (e.g., 50 nm or larger) that is larger than the size of a pellet. Meanwhile, spots appear in a nanobeam electron diffraction pattern of the nc-OS when an electron beam having a probe diameter close to or smaller than the size of a pellet is applied. Moreover, in a nanobeam electron diffraction pattern of the nc-OS, regions with high luminance in a circular (ring) pattern are shown in some cases. Also in a nanobeam electron diffraction pattern of the nc-OS, a plurality of spots is shown in a ring-like region in some cases.

Since there is no regularity of crystal orientation between the pellets (nanocrystals) as mentioned above, the nc-OS can also be referred to as an oxide semiconductor including random aligned nanocrystals (RANC) or an oxide semiconductor including non-aligned nanocrystals (NANC).

The nc-OS is an oxide semiconductor that has high regularity as compared with an amorphous oxide semiconductor. Therefore, the nc-OS is likely to have a lower density of defect states than an a-like OS and an amorphous oxide semiconductor. Note that there is no regularity of crystal orientation between different pellets in the nc-OS. Therefore, the nc-OS has a higher density of defect states than the CAAC-OS.

<a-Like OS>

An a-like OS is an oxide semiconductor having a structure between the nc-OS and the amorphous oxide semiconductor.

In a high-resolution TEM image of the a-like OS, a void may be observed. Furthermore, in the high-resolution TEM image, there are a region where a crystal part is clearly observed and a region where a crystal part is not observed.

The a-like OS has an unstable structure because it contains a void. To verify that an a-like OS has an unstable structure as compared with a CAAC-OS and an nc-OS, a change in structure caused by electron irradiation is described below.

An a-like OS (referred to as Sample A), an nc-OS (referred to as Sample B), and a CAAC-OS (referred to as Sample C) are prepared as samples subjected to electron irradiation. Each of the samples is an In-Ga—Zn oxide.

First, a high-resolution cross-sectional TEM image of each sample is obtained. The high-resolution cross-sectional TEM images show that all the samples have crystal parts.

Note that which part is regarded as a crystal part is determined as follows. It is known that a unit cell of the InGaZnO₄ crystal has a structure in which nine layers including three In—O layers and six Ga—Zn—O layers are stacked in the c-axis direction. The distance between the adjacent layers is equivalent to the lattice spacing on the (009) plane (also referred to as d value). The value is calculated to be 0.29 nm from crystal structural analysis. Accordingly, a portion where the lattice spacing between lattice fringes is greater than or equal to 0.28 nm and less than or equal to 0.30 nm is regarded as a crystal part of InGaZnO₄. Each of lattice fringes corresponds to the a-b plane of the InGaZnO₄ crystal.

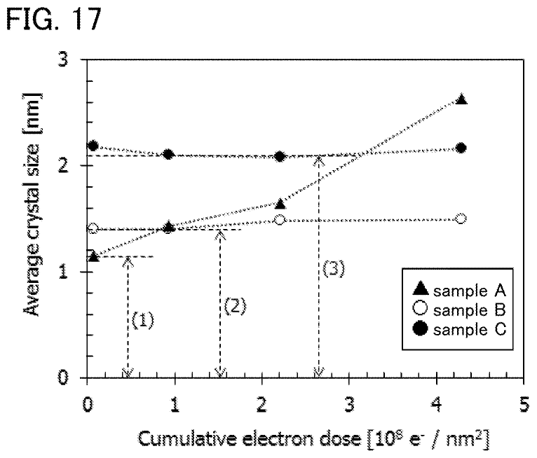

FIG. 17 shows change in the average size of crystal parts (at 22 points to 45 points) in each sample. Note that the crystal part size corresponds to the length of a lattice fringe. FIG. 17 indicates that the crystal part size in the a-like OS increases with an increase in the cumulative electron dose. Specifically, as shown by (1) in FIG. 17, a crystal part of approximately 1.2 nm (also referred to as an initial nucleus) at the start of TEM observation grows to a size of approximately 2.6 nm at a cumulative electron dose of 4.2×10⁸ e⁻/nm². In contrast, the crystal part size in the nc-OS and the CAAC-OS shows little change from the start of electron irradiation to a cumulative electron dose of 4.2×10⁸ e⁻/nm². Specifically, as shown by (2) and (3) in FIG. 17, the average crystal sizes in an nc-OS and a CAAC-OS are approximately 1.4 nm and approximately 2.1 nm, respectively, regardless of the cumulative electron dose.

In this manner, growth of the crystal part in the a-like OS is induced by electron irradiation. In contrast, in the nc-OS and the CAAC-OS, growth of the crystal part is hardly induced by electron irradiation. Therefore, the a-like OS has an unstable structure as compared with the nc-OS and the CAAC-OS.

The a-like OS has a lower density than the nc-OS and the CAAC-OS because it contains a void. Specifically, the density of the a-like OS is higher than or equal to 78.6% and lower than 92.3% of the density of the single crystal oxide semiconductor having the same composition. The density of each of the nc-OS and the CAAC-OS is higher than or equal to 92.3% and lower than 100% of the density of the single crystal oxide semiconductor having the same composition. Note that it is difficult to deposit an oxide semiconductor having a density of lower than 78% of the density of the single crystal oxide semiconductor.

For example, in the case of an oxide semiconductor having an atomic ratio of In:Ga:Zn=1:1:1, the density of single crystal InGaZnO₄ with a rhombohedral crystal structure is 6.357 g/cm³. Accordingly, in the case of the oxide semiconductor having an atomic ratio of In:Ga:Zn=1:1:1, the density of the a-like OS is higher than or equal to 5.0 g/cm³ and lower than 5.9 g/cm³. For example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that there is a possibility that an oxide semiconductor having a desired composition cannot exist in a single crystal structure. In that case, single crystal oxide semiconductors with different compositions are combined at an adequate ratio, which makes it possible to calculate density equivalent to that of a single crystal oxide semiconductor with the desired composition. The density of a single crystal oxide semiconductor having the desired composition can be calculated using a weighted average according to the combination ratio of the single crystal oxide semiconductors with different compositions. Note that it is preferable to use as few kinds of single crystal oxide semiconductors as possible to calculate the density.

As described above, oxide semiconductors have various structures and various properties. Note that an oxide semiconductor may be a stacked layer including two or more films of an amorphous oxide semiconductor, an a-like OS, an nc-OS, and a CAAC-OS, for example.

### <Method for Forming CAAC-OS>

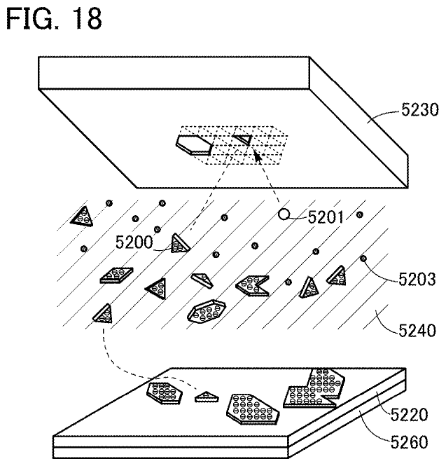

An example of a method for forming a CAAC-OS film will be described below. FIG. 18 is a schematic view of the inside of a deposition chamber. The CAAC-OS film can be formed by a sputtering method.

As shown in FIG. 18, a substrate 5220 and a target 5230 are arranged to face each other. Plasma 5240 is generated between the substrate 5220 and the target 5230. A heating mechanism 5260 is under the substrate 5220. The target 5230 is attached to a backing plate (not illustrated in the drawing). A plurality of magnets are arranged to face the target 5230 with the backing plate positioned therebetween. A sputtering method in which the deposition speed is increased by utilizing a magnetic field of magnets is referred to as a magnetron sputtering method.

The distance d between the substrate 5220 and the target 5230 (also referred to as a target-substrate distance (T-S distance)) is greater than or equal to 0.01 m and less than or equal to 1 m, preferably greater than or equal to 0.02 m and less than or equal to 0.5 m. The deposition chamber is mostly filled with a deposition gas (e.g., an oxygen gas, an argon gas, or a mixed gas containing oxygen at 5 volume % or higher) and the pressure in the deposition chamber is controlled to be higher than or equal to 0.01 Pa and lower than or equal to 100 Pa, preferably higher than or equal to 0.1 Pa and lower than or equal to 10 Pa. Here, discharge starts by application of a voltage at a certain value or higher to the target 5230, and the plasma 5240 can be observed. The magnetic field forms a high-density plasma region over the target 5230. In the high-density plasma region, the deposition gas is ionized, so that an ion 5201 is generated. Examples of the ion 5201 include an oxygen cation (O⁺) and an argon cation (Ar⁺).

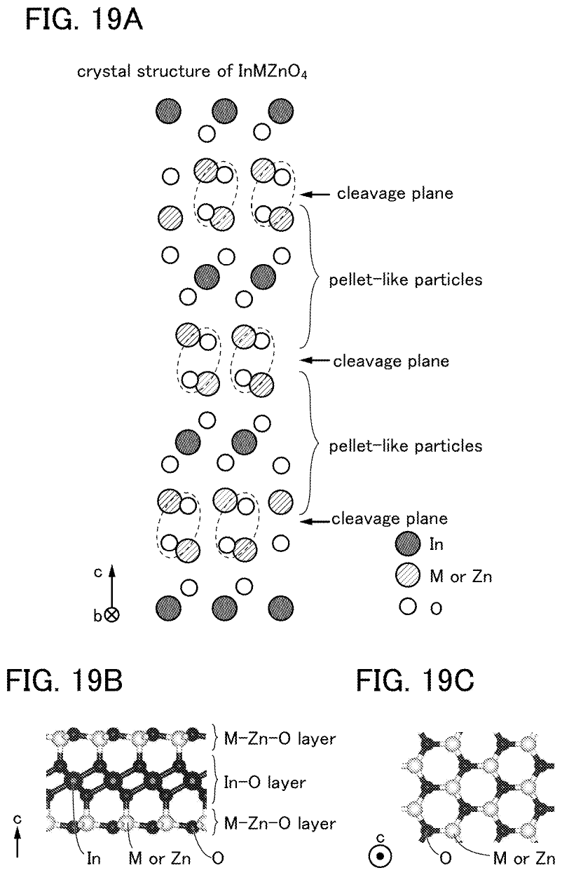

Here, the target 5230 has a polycrystalline structure which includes a plurality of crystal grains and in which a cleavage plane exists in any of the crystal grains. FIGS. 19A to 19C show a crystal structure of InMZnO₄ (the element M is Al, Ga, Y, or Sn, for example) included in the target 5230 as an example. Note that FIG. 19A illustrates the crystal structure of InMZnO₄ observed from a direction parallel to the b-axis. In the crystal of InMZnO₄, oxygen atoms are negatively charged, whereby repulsive force is generated between the two adjacent M-Zn—O layers. Thus, the InMZnO₄ crystal has a cleavage plane between the two adjacent M-Zn—O layers.

The ion 5201 generated in the high-density plasma region is accelerated toward the target 5230 side by an electric field, and then collides with the target 5230. At this time, a pellet 5200 which is a flat-plate-like or pellet-like sputtered particles is separated from the cleavage plane (FIG. 18). The pellet 5200 is between the two cleavage planes shown in FIG. 19A. Thus, when the pellet 5200 is observed, the cross-section thereof is as shown in FIG. 19B, and the top surface thereof is as shown in FIG. 19C. Note that the structure of the pellet 5200 may be distorted by an impact of collision of the ion 5201.

The pellet 5200 is a flat-plate-like (pellet-like) sputtered particle having a triangle plane, e.g., regular triangle plane. Alternatively, the pellet 5200 is a flat-plate-like (pellet-like) sputtered particle having a hexagon plane, e.g., regular hexagon plane. However, the shape of a flat plane of the pellet 5200 is not limited to a triangle or a hexagon. For example, the flat plane may have a shape formed by combining two or more triangles. For example, a quadrangle (e.g., rhombus) may be formed by combining two triangles (e.g., regular triangles).

The thickness of the pellet 5200 is determined depending on the kind of the deposition gas and the like. For example, the thickness of the pellet 5200 is greater than or equal to 0.4 nm and less than or equal to 1 nm, preferably greater than or equal to 0.6 nm and less than or equal to 0.8 nm. In addition, for example, the width of the pellet 5200 is greater than or equal to 1 nm and less than or equal to 100 nm, preferably greater than or equal to 2 nm and less than or equal to 50 nm, further preferably greater than or equal to 3 nm and less than or equal to 30 nm. For example, the ion 5201 collides with the target 5230 including the In-M-Zn oxide. Then, the pellet 5200 including three layers of an M-Zn—O layer, an In—O layer, and an M-Zn—O layer is separated. Note that along with the separation of the pellet 5200, a particle 5203 is also sputtered from the target 5230. The particle 5203 has an atom or an aggregate of several atoms. Therefore, the particle 5203 can be referred to as an atomic particle.

The pellet 5200 may receive a charge when passing through the plasma 5240, so that surfaces thereof are negatively or positively charged. For example, the pellet 5200 receives a negative charge from O²⁻ in the plasma 5240. As a result, oxygen atoms on the surfaces of the pellet 5200 may be negatively charged. In addition, when passing through the plasma 5240, the pellet 5200 is sometimes combined with indium, the element M, zinc, oxygen, or the like in the plasma 5240 to grow up.

The pellet 5200 and the particles 5203 that have passed through the plasma 5240 reach a surface of the substrate 5220. Note that some of the particles 5203 are discharged to the outside by a vacuum pump or the like because of their smallness in mass.

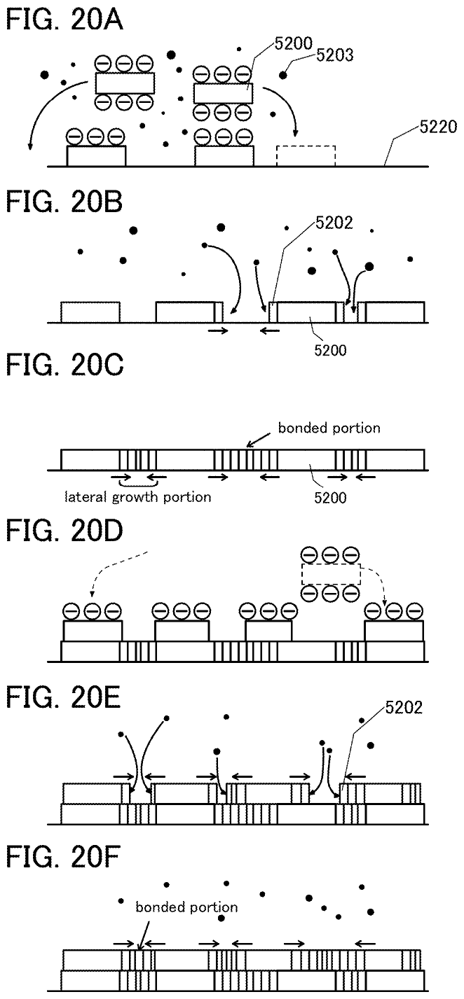

Next, deposition of the pellet 5200 and the particle 5203 over the surface of the substrate 5220 is described with reference to FIGS. 20A to 20F.

First, a first pellet 5200 is deposited over the substrate 5220. Since the pellet 5200 has a flat-plate-like shape, it is deposited so that the flat plane faces the surface of the substrate 5220. At this time, a charge on a surface of the pellet 5200 on the substrate 5220 side is lost through the substrate 5220.

Next, a second pellet 5200 reaches the substrate 5220. Since a surface of the first pellet 5200 and a surface of the second pellet 5200 are charged, they repel each other. As a result, the second pellet 5200 avoids being deposited over the first pellet 5200, and is deposited with its flat plane facing the surface of the substrate 5220 so as to be a little distance away from the first pellet 5200. With repetition of this, millions of the pellets 5200 are deposited on the surface of the substrate 5220 to have a thickness of one layer. A region where no pellet 5200 is deposited is generated between adjacent pellets 5200 (see FIG. 20A).

Then, the particles 5203 that have received energy from plasma reach the surface of the substrate 5220. The particles 5203 cannot be deposited on an active region such as the surfaces of the pellets 5200. For this reason, the particles 5203 move to regions where no pellet 5200 is deposited and are attached to side surfaces of the pellets 5200. Since available bonds of the particles 5203 are activated by energy received from plasma, the particles 5203 are chemically bonded to the pellets 5200 to form lateral growth portions 5202 (see FIG. 20B).

The lateral growth portions 5202 then further grow laterally so that the pellets 5200 are anchored to each other (see FIG. 20C). In this manner, the lateral growth portions 5202 are formed until they fill regions where no pellet 5200 is deposited. This mechanism is similar to a deposition mechanism for an atomic layer deposition (ALD) method.

Even when the deposited pellets 5200 are oriented in different directions, the particles 5203 cause a lateral growth to fill gaps between the pellets 5200; thus, no clear grain boundary is formed. In addition, as the particles 5203 make a smooth connection between the pellets 5200, a crystal structure different from single crystal and polycrystal structures is formed. In other words, a crystal structure including distortion between minute crystal regions (pellets 5200) is formed. Regions filling the gaps between the crystal regions are distorted crystal regions, and thus, it will be not appropriate to say that the regions have an amorphous structure.

Next, new pellets 5200 are deposited with their flat planes facing the surface of the substrate 5220 (see FIG. 20D). After that, the particles 5203 are deposited so as to fill regions where no pellet 5200 is deposited, thereby forming the lateral growth portions 5202 (see FIG. 20E). In such a manner, the particles 5203 are attached to side surfaces of the pellets 5200 and the lateral growth portions 5202 cause a lateral growth so that the pellets 5200 in the second layer are anchored to each other (see FIG. 20F). Deposition continues until the m-th layer (m is an integer of two or more) is formed; as a result, a stacked-layer thin film structure is formed.

A deposition way of the pellets 5200 changes according to the surface temperature of the substrate 5220 or the like. For example, if the surface temperature of the substrate 5220 is high, migration of the pellets 5200 occurs over the surface of the substrate 5220. As a result, a proportion of the pellets 5200 that are directly connected with each other without the particles 5203 increases, whereby a CAAC-OS with high orientation is made. The surface temperature of the substrate 5220 for formation of the CAAC-OS is higher than or equal to room temperature and lower than 340° C., preferably higher than or equal to room temperature and lower than or equal to 300° C., further preferably higher than or equal to 100° C. and lower than or equal to 250° C., still further preferably higher than or equal to 100° C. and lower than or equal to 200° C. Therefore, even when a large-sized substrate of the 8th generation or more is used as the substrate 5220, a warp or the like due to the deposition of the CAAC-OS hardly occurs.

In contrast, if the surface temperature of the substrate 5220 is low, the migration of the pellets 5200 over the substrate 5220 does not easily occur. As a result, the pellets 5200 are stacked to form an nc-OS or the like with low orientation. In the nc-OS, the pellets 5200 are possibly deposited with certain gaps because the pellets 5200 are negatively charged. Therefore, the nc-OS has low orientation but some regularity, and thus it has a denser structure than an amorphous oxide semiconductor.

When spaces between pellets are extremely small in a CAAC-OS, the pellets may form a large pellet. The inside of the large pellet has a single crystal structure. For example, the size of the pellet may be greater than or equal to 10 nm and less than or equal to 200 nm, greater than or equal to 15 nm and less than or equal to 100 nm, or greater than or equal to 20 nm and less than or equal to 50 nm, when seen from the above.

The pellets are considered to be deposited on the surface of the substrate according to such a deposition model. A CAAC-OS can be deposited even when a formation surface does not have a crystal structure. This indicates that the above-described deposition model, which is a growth mechanism different from an epitaxial growth, has high validity. In addition, with the above-described deposition model, a uniform film of a CAAC-OS or an nc-OS can be formed even over a large-sized glass substrate or the like. Even when the surface of the substrate (formation surface) has an amorphous structure (e.g., amorphous silicon oxide), for example, a CAAC-OS can be formed.

In addition, even when the surface of the substrate (formation surface) has an uneven shape, the pellets are aligned along the shape.

The above-described deposition model suggests that a CAAC-OS with high crystallinity can be formed in the following manner: deposition is performed in a high vacuum to have a long mean free path, plasma energy is weakened to reduce damage around a substrate, and thermal energy is applied to a formation surface to repair damage due to plasma during deposition.

The above-described deposition model can be used not only for the case where a target has a polycrystalline structure of a composite oxide with a plurality of crystal grains, such as an In-M-Zn oxide, and any of the crystal grains have a cleavage plane; but also for the case where, for example, a target of a mixture containing indium oxide, an oxide of the element M, and zinc oxide is used.

Since there is no cleavage plane in a target of a mixture, atomic particles are separated from the target by sputtering. During deposition, a high electric field region of plasma is formed around a target. Because of the high electric field region of plasma, atomic particles separated from the target are anchored to each other to cause a lateral growth. For example, indium atoms, which are atomic particles, are anchored to each other and cause a lateral growth to be a nanocrystal formed of an In—O layer, and then an M-Zn—O layer is bonded above and below the nanocrystalline In—O layer so as to complement the nanocrystalline In—O layer. In this manner, a pellet can be formed even when a target of a mixture is used. Accordingly, the above-described deposition model can also be applied to the case of using a target of a mixture. Note that in the case where a high electric field region of plasma is not formed around a target, only atomic particles separated from the targets are deposited on a substrate surface. In that case, a lateral growth of an atomic particle might occur on the substrate surface. However, since the orientations of atomic particles are not the same, the crystal orientation in the resulting thin film is not uniform. As a result, an nc-OS or the like is obtained.

### Embodiment 5

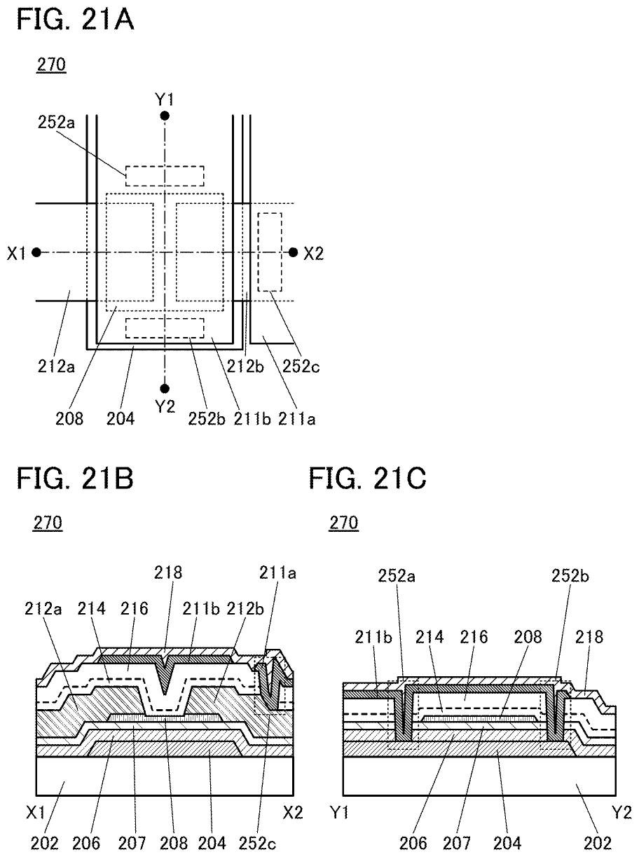

In this embodiment, a structure example different from that of the transistor described in Embodiment 1 is described with reference to FIGS. 21A to 21C, FIGS. 22A to 22D, FIGS. 23A and 23B, and FIGS. 24A and 24B.

### <Example 1 of Transistor Structure>

FIG. 21A is a top view of a transistor 270 that is a semiconductor device of one embodiment of the present invention. FIG. 21B is a cross-sectional view taken along dashed-dotted line X1-X2 in FIG. 21A, and FIG. 21C is a cross-sectional view taken along dashed-dotted line Y1-Y2 in FIG. 21A. Note that the direction of the dashed dotted line X1-X2 may be called a channel length direction, and the direction of the dashed dotted line Y1-Y2 may be called a channel width direction.

The transistor 270 includes the conductive film 204 functioning as a first gate electrode over the substrate 202, the insulating film 206 over the substrate 202 and the conductive film 204, the insulating film 207 over the insulating film 206, the oxide semiconductor film 208 over the insulating film 207, the conductive film 212a functioning as a source electrode electrically connected to the oxide semiconductor film 208, the conductive film 212b functioning as a drain electrode electrically connected to the oxide semiconductor film 208, the insulating films 214 and 216 over the oxide semiconductor film 208, the conductive films 212a and 212b, and the oxide semiconductor film 211b over the insulating film 216. In addition, the insulating film 218 is provided over the oxide semiconductor film 211b.

In the transistor 270, the insulating films 214 and 216 function as a second gate insulating film of the transistor 270. The oxide semiconductor film 211a is connected to the conductive film 212b through an opening 252c provided in the insulating films 214 and 216. The oxide semiconductor film 211a functions as, for example, a pixel electrode used for a display device. The oxide semiconductor film 211b in the transistor 270 functions as a second gate electrode (also referred to as a back gate electrode).

As illustrated in FIG. 21C, the oxide semiconductor film 211b is connected to the conductive film 204 functioning as a first gate electrode through openings 252a and 252b provided in the insulating films 206, 207, 214, and 216. Accordingly, the oxide semiconductor film 211b and the conductive film 220b are supplied with the same potential.

Note that although the structure in which the openings 252a and 252b are provided so that the oxide semiconductor film 211b and the conductive film 204 are connected to each other is described in this embodiment, one embodiment of the present invention is not limited thereto. For example, a structure in which only one of the openings 252a and 252b is provided so that the oxide semiconductor film 211b and the conductive film 204 are connected to each other, or a structure in which the openings 252a and 252b are not provided and the oxide semiconductor film 211b and the conductive film 204 are not connected to each other may be employed. Note that in the case where the oxide semiconductor film 211b and the conductive film 204 are not connected to each other, it is possible to apply different potentials to the oxide semiconductor film 211b and the conductive film 204.

As illustrated in FIG. 21B, the oxide semiconductor film 208 is positioned to face each of the conductive film 204 functioning as a first gate electrode and the oxide semiconductor film 211b functioning as a second gate electrode, and is sandwiched between the two conductive films functioning as gate electrodes. The lengths in the channel length direction and the channel width direction of the oxide semiconductor film 211b functioning as a second gate electrode are longer than those in the channel length direction and the channel width direction of the oxide semiconductor film 208. The whole oxide semiconductor film 208 is covered with the oxide semiconductor film 211b with the insulating films 214 and 216 positioned therebetween. Since the oxide semiconductor film 211b functioning as a second gate electrode is connected to the conductive film 204 functioning as a first gate electrode through the openings 252a and 252b provided in the insulating films 206 and 207 and the insulating films 214 and 216, a side surface of the oxide semiconductor film 208 in the channel width direction faces the oxide semiconductor film 211b functioning as a second gate electrode with the insulating films 214 and 216 positioned therebetween.

In other words, in the channel width direction of the transistor 270, the conductive film 204 functioning as a first gate electrode and the oxide semiconductor film 211b functioning as a second gate electrode are connected to each other through the openings provided in the insulating films 206 and 207 functioning as first gate insulating films and the insulating films 214 and 216 functioning as second gate insulating films; and the conductive film 204 and the oxide semiconductor film 211b surround the oxide semiconductor film 208 with the insulating films 206 and 207 functioning as first gate insulating films and the insulating films 214 and 216 functioning as second gate insulating films positioned therebetween.

Such a structure enables the oxide semiconductor film 208 included in the transistor 270 to be electrically surrounded by electric fields of the conductive film 204 functioning as a first gate electrode and the oxide semiconductor film 211b functioning as a second gate electrode. A device structure of a transistor, like that of the transistor 270, in which electric fields of a first gate electrode and a second gate electrode electrically surround an oxide semiconductor film where a channel region is formed can be referred to as a surrounded channel (s-channel) structure.

Since the transistor 270 has the s-channel structure, an electric field for inducing a channel can be effectively applied to the oxide semiconductor film 208 by the conductive film 204 functioning as a first gate electrode; therefore, the current drive capability of the transistor 270 can be improved and high on-state current characteristics can be obtained. Since the on-state current can be increased, it is possible to reduce the size of the transistor 270. In addition, since the transistor 270 is surrounded by the conductive film 204 functioning as a first gate electrode and the oxide semiconductor film 211b functioning as a second gate electrode, the mechanical strength of the transistor 270 can be increased.

### <Example 2 of Transistor Structure>

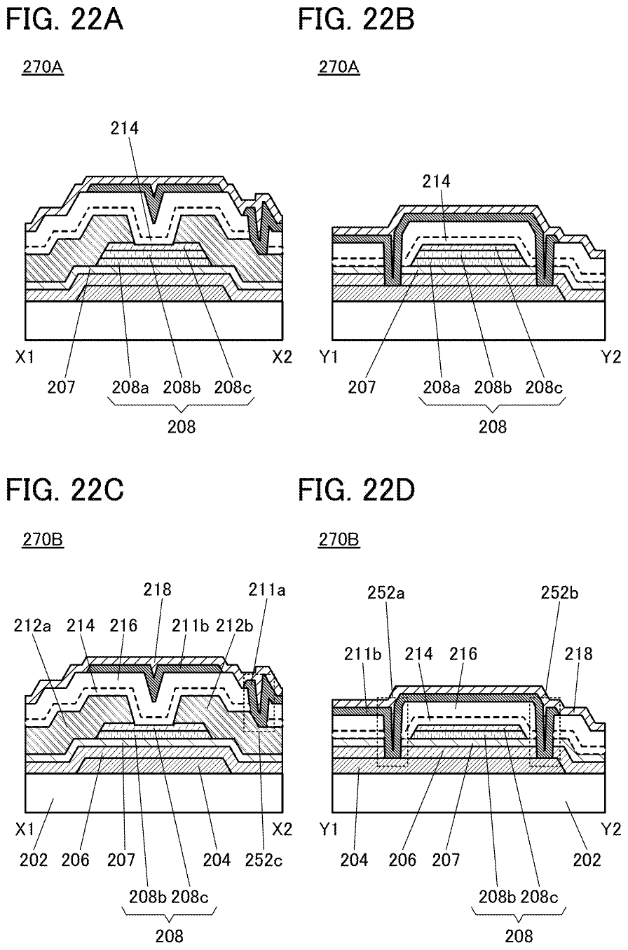

Structure examples different from that of the transistor 270 in FIGS. 21A to 21C are described with reference to FIGS. 22A to 22D.

FIGS. 22A and 22B illustrate a cross-sectional view illustrating a variation of the transistor 270 in FIGS. 21B and 21C. FIGS. 22C and 22D illustrate a cross-sectional view illustrating another variation of the transistor 270 in FIGS. 21B and 21C.

A transistor 270A in FIGS. 22A and 22B has the same structure as the transistor 270 in FIGS. 21B and 21C except that the oxide semiconductor film 208 has a three-layer structure. Specifically, the oxide semiconductor film 208 of the transistor 270A includes an oxide semiconductor film 208a, an oxide semiconductor film 208b, and an oxide semiconductor film 208c.

A transistor 270B in FIGS. 22C and 22D has the same structure as the transistor 270 in FIGS. 21B and 21C except that the oxide semiconductor film 208 has a two-layer structure. Specifically, the oxide semiconductor film 208 of the transistor 270B includes the oxide semiconductor film 208b and the oxide semiconductor film 208c.

The description of the structure of the semiconductor device in Embodiment 1 can be referred to for the structure of the transistors 270, 270A, and 270B in this embodiment. Thus, the description of the material and the manufacturing method of the substrate 102 can be referred to for those of the substrate 202. The description of the material and the manufacturing method of the gate electrode 104 can be referred to for those of the conductive film 204. The description of the material and the manufacturing method of the insulating film 106 and those of the insulating film 107 can be referred to for those of the insulating film 206 and those of the insulating film 207, respectively. The description of the material and the manufacturing method of the first oxide semiconductor film 110 can be referred to for those of the oxide semiconductor film 208. The description of the material and the manufacturing method of the second oxide semiconductor film 111 can be referred to for those of the oxide semiconductor film 211a and those of the oxide semiconductor film 211b, respectively. The description of the material and the manufacturing method of the source electrode 112a and the drain electrode 112b can be referred to for those of the conductive film 21a and the conductive film 21b. The description of the materials and the manufacturing methods of the insulating films 114, 116, and 118 can be referred to for those of the insulating films 214, 216, and 218.

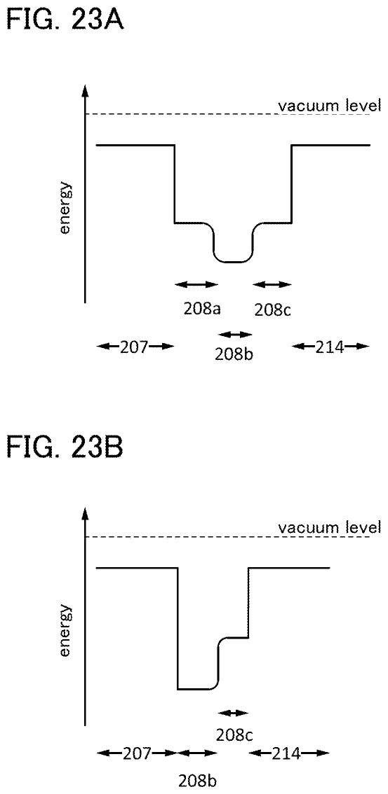

Here, a band structure including the oxide semiconductor films 208a, 208b, and 208c and insulating films in contact with the oxide semiconductor films 208b and 208c is described with reference to FIGS. 23A and 23B.

FIG. 23A shows an example of a band structure in the thickness direction of a stacked-layer structure including the insulating film 207, the oxide semiconductor films 208a, 208b, and 208c, and the insulating film 214. FIG. 23B shows an example of a band structure in the thickness direction of a stacked-layer structure including the insulating film 207, the oxide semiconductor films 208b and 208c, and the insulating film 214. For easy understanding, energy level of the conduction band minimum (Ec) of each of the insulating film 207, the oxide semiconductor films 208a, 208b, and 208c, and the insulating film 214 is shown in the band structures.

In the band structure of FIG. 23A, a silicon oxide film is used as each of the insulating film 207 and the insulating film 214, an oxide semiconductor film formed using a metal oxide target having an atomic ratio of metal elements, In:Ga:Zn=1:1:1.2, is used as the oxide semiconductor film 208a, an oxide semiconductor film formed using a metal oxide target having an atomic ratio of metal elements, In:Ga:Zn=4:2:4.1, is used as the oxide semiconductor film 208b, and an oxide semiconductor film formed using a metal oxide target having an atomic ratio of metal elements, In:Ga:Zn=1:1:1.2, is used as the oxide semiconductor film 208c.

In the band structure of FIG. 23B, a silicon oxide film is used as each of the insulating film 207 and the insulating film 214, an oxide semiconductor film formed using a metal oxide target having an atomic ratio of metal elements, In:Ga:Zn=4:2:4.1, is used as the oxide semiconductor film 208b, and an oxide semiconductor film formed using a metal oxide target having an atomic ratio of metal elements, In:Ga:Zn=1:1:1.2, is used as the oxide semiconductor film 208c.

As illustrated in FIGS. 23A and 23B, the energy level of the conduction band minimum gradually changes between the oxide semiconductor film 208a and the oxide semiconductor film 208b and between the oxide semiconductor film 208b and the oxide semiconductor film 208c. In other words, the energy level of the conduction band minimum is continuously changed or continuously connected. To obtain such a band structure, there exists no impurity, which forms a defect state such as a trap center or a recombination center, at the interface between the oxide semiconductor film 208a and the oxide semiconductor film 208b or at the interface between the oxide semiconductor film 208b and the oxide semiconductor film 208c.

To form a continuous junction between the oxide semiconductor film 208a and the oxide semiconductor film 208b and between the oxide semiconductor film 208b and the oxide semiconductor film 208c, it is necessary to form the films successively without exposure to the air by using a multi-chamber deposition apparatus (sputtering apparatus) provided with a load lock chamber.

With the band structures of FIG. 23A and FIG. 23B, the oxide semiconductor film 208b serves as a well, and a channel region is formed in the oxide semiconductor film 208b in the transistor with the stacked-layer structure.

By providing the oxide semiconductor film 208a and the oxide semiconductor film 208c, the oxide semiconductor film 208b can be distanced away from trap states.

In addition, the trap states might be more distant from the vacuum level than the energy level of the conduction band minimum (Ec) of the oxide semiconductor film 208b functioning as a channel region, so that electrons are likely to be accumulated in the trap states. When the electrons are accumulated in the trap states, the electrons become negative fixed electric charge, so that the threshold voltage of the transistor is shifted in the positive direction. Therefore, it is preferable that the trap states be closer to the vacuum level than the energy level of the conduction band minimum (Ec) of the oxide semiconductor film 208b. Such a structure inhibits accumulation of electrons in the trap states. As a result, the on-state current and the field-effect mobility of the transistor can be increased.

The energy level of the conduction band minimum of each of the oxide semiconductor films 208a and 208c is closer to the vacuum level than that of the oxide semiconductor film 208b. Typically, a difference in energy level between the conduction band minimum of the oxide semiconductor film 208b and the conduction band minimum of each of the oxide semiconductor films 208a and 208c is 0.15 eV or more or 0.5 eV or more and 2 eV or less or 1 eV or less. That is, the difference between the electron affinity of each of the oxide semiconductor films 208a and 208c and the electron affinity of the oxide semiconductor film 208b is 0.15 eV or more or 0.5 eV or more and 2 eV or less or 1 eV or less.

In such a structure, the oxide semiconductor film 208b serves as a main path of current. In other words, the oxide semiconductor film 208b serves as a channel region, and the oxide semiconductor films 208a and 208c serve as oxide insulating films. In addition, since the oxide semiconductor films 208a and 208c each include one or more metal elements included in the oxide semiconductor film 208b in which a channel region is formed, interface scattering is less likely to occur at the interface between the oxide semiconductor film 208a and the oxide semiconductor film 208b or at the interface between the oxide semiconductor film 208b and the oxide semiconductor film 208c. Thus, the transistor can have high field-effect mobility because the movement of carriers is not hindered at the interface.

To prevent each of the oxide semiconductor films 208a and 208c from functioning as part of a channel region, a material having sufficiently low conductivity is used for the oxide semiconductor films 208a and 208c. Thus, the oxide semiconductor films 208a and 208c can be referred to as oxide insulating films for such properties and/or functions. Alternatively, a material which has a smaller electron affinity (a difference in energy level between the vacuum level and the conduction band minimum) than the oxide semiconductor film 208b and has a difference in energy level in the conduction band minimum from the oxide semiconductor film 208b (band offset) is used for the oxide semiconductor films 208a and 208c. Furthermore, to inhibit generation of a difference in threshold voltage due to the value of the drain voltage, it is preferable to form the oxide semiconductor films 208a and 208c using a material whose energy level of the conduction band minimum is closer to the vacuum level than that of the oxide semiconductor film 208b. For example, a difference between the energy level of the conduction band minimum of the oxide semiconductor film 208b and the energy level of the conduction band minimum of each of the oxide semiconductor films 208a and 208c is preferably greater than or equal to 0.2 eV, further preferably greater than or equal to 0.5 eV.

It is preferable that the oxide semiconductor films 208a and 208c not have a spinel crystal structure. This is because if the oxide semiconductor films 208a and 208c have a spinel crystal structure, constituent elements of the conductive films 212a and 212b might be diffused to the oxide semiconductor film 208b at the interface between the spinel crystal structure and another region. Note that each of the oxide semiconductor film 208a and 208c is preferably a CAAC-OS, in which case a higher blocking property against constituent elements of the conductive films 212a and 212b, for example, copper elements, is obtained.

The thickness of each of the oxide semiconductor films 208a and 208c is greater than or equal to a thickness that is capable of inhibiting diffusion of the constituent elements of the conductive films 212a and 212b to the oxide semiconductor film 208b, and less than a thickness that inhibits supply of oxygen from the insulating film 214 to the oxide semiconductor film 208b. For example, when the thickness of each of the oxide semiconductor films 208a and 208c is greater than or equal to 10 nm, diffusion of the constituent elements of the conductive films 212a and 212b to the oxide semiconductor film 208b can be inhibited. When the thickness of each of the oxide semiconductor films 208a and 208c is less than or equal to 100 nm, oxygen can be effectively supplied from the insulating film 214 to the oxide semiconductor film 208b.

Although the example where an oxide semiconductor film formed using a metal oxide target having an atomic ratio of metal elements, In:Ga:Zn=1:1:1.2, is used as each of the oxide semiconductor films 208a and 208c is described in this embodiment, one embodiment of the present invention is not limited thereto. For example, an oxide semiconductor film formed using a metal oxide target having an atomic ratio of metal elements, In:Ga:Zn=1:1:1, In:Ga:Zn=1:3:2, In:Ga:Zn=1:3:4, or In:Ga:Zn=1:3:6, may be used as each of the oxide semiconductor films 208a and 208c.

When the oxide semiconductor films 208a and 208c are formed using a metal oxide target having an atomic ratio of In:Ga:Zn=1:1:1, the oxide semiconductor films 208a and 208c have an atomic ratio of In:Ga:Zn=1:β1 (0<β1≤2):P2 (0<β2≤3) in some cases. When the oxide semiconductor films 208a and 208c are formed using a metal oxide target having an atomic ratio of In:Ga:Zn=1:3:4, the oxide semiconductor films 208a and 208c have an atomic ratio of In:Ga:Zn=1:β (1≤β3≤5):P4 (2≤β4≤6) in some cases. When the oxide semiconductor films 208a and 208c are formed using a metal oxide target having an atomic ratio of In:Ga:Zn=1:3:6, the oxide semiconductor films 208a and 208c have an atomic ratio of In:Ga:Zn=1:β5 (1≤β5≤5):β6 (4≤β6≤8) in some cases.

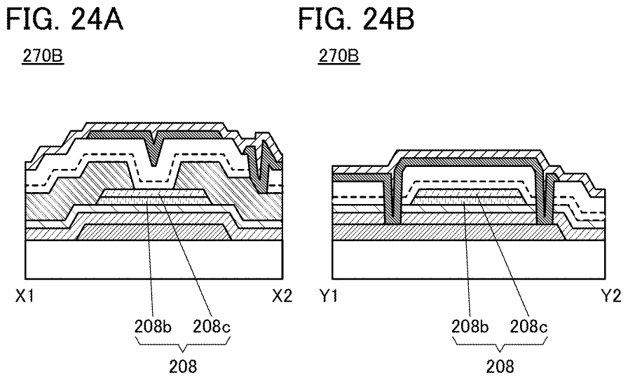

The drawings illustrate an example where the oxide semiconductor film 208 in the transistor 270 and the oxide semiconductor film 208c in the transistors 270A and 270B have a small thickness in a region which does not overlap with the conductive films 212a and 212b, that is, an example where part of the oxide semiconductor film has a depressed portion. However, one embodiment of the present invention is not limited thereto, and the oxide semiconductor film does not necessarily have a depressed region in a region which does not overlap with the conductive films 212a and 212b. FIGS. 24A and 24B illustrate examples in this case. FIGS. 24A and 24B are cross-sectional views illustrating examples of the transistor. FIGS. 24A and 24B illustrate a structure where the oxide semiconductor film 208 in the transistor 270B does not have a depressed portion.

The structures of the transistors of this embodiment can be freely combined with each other.

The structure and method described in this embodiment can be implemented by being combined as appropriate with any of the other structures and methods described in the other embodiments.

### Embodiment 6

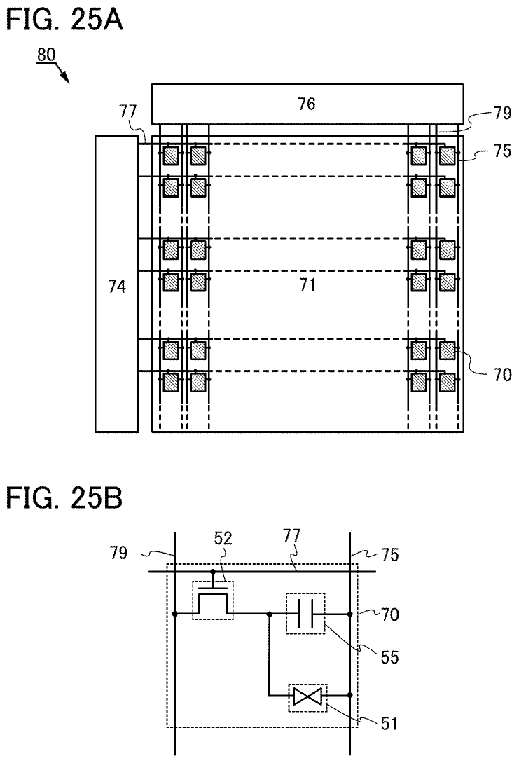

In this embodiment, a display device 80 which is one embodiment of the present invention will be described with reference to FIG. 25A to FIG. 42.

The display device 80 illustrated in FIG. 25A includes a pixel portion 71, a scan line driver circuit 74, a signal line driver circuit 76, m scan lines 77 that are arranged parallel or substantially parallel to each other and whose potentials are controlled by the scan line driver circuit 74, and n signal lines 79 that are arranged parallel or substantially parallel to each other and whose potentials are controlled by the signal line driver circuit 76. The pixel portion 71 includes a plurality of pixels 70 arranged in a matrix. Furthermore, common lines 75 arranged parallel or substantially parallel to each other are provided along the signal lines 79. The scan line driver circuit 74 and the signal line driver circuit 76 are collectively referred to as a driver circuit portion in some cases.

Each of the scan lines 77 is electrically connected to the n pixels 70 in the corresponding row among the pixels 70 arranged in m rows and n columns in the pixel portion 71. Each of the signal lines 79 is electrically connected to the m pixels in the corresponding column among the pixels 70 arranged in m rows and n columns. Note that m and n are each an integer of 1 or more. Each of the common lines 75 is electrically connected to the m pixels 70 in the corresponding row among the pixels 70 arranged in m rows and n columns.

FIG. 25B illustrates an example of a circuit configuration that can be used for the pixel 70 in the display device 80 illustrated in FIG. 25A.

The pixel 70 illustrated in FIG. 25B includes a liquid crystal element 51, a transistor 52, and a capacitor 55.

One of a pair of electrodes of the liquid crystal element 51 is connected to the transistor 52 and the potential thereof is set as appropriate in accordance with the specifications of the pixel 70. The other of the electrodes of the liquid crystal element 51 is connected to the common line 75 and a common potential is applied thereto. The alignment of liquid crystal molecules of the liquid crystal element 51 is controlled in accordance with data written to the transistor 52.

The liquid crystal element 51 controls transmission or non-transmission of light utilizing an optical modulation action of liquid crystal. Note that optical modulation action of liquid crystal is controlled by an electric field applied to the liquid crystal (including a horizontal electric field, a vertical electric field, and an oblique electric field). As the liquid crystal used for the liquid crystal element 51, thermotropic liquid crystal, low-molecular liquid crystal, high-molecular liquid crystal, polymer dispersed liquid crystal, ferroelectric liquid crystal, antiferroelectric liquid crystal, or the like can be used. These liquid crystal materials exhibit a cholesteric phase, a smectic phase, a cubic phase, a chiral nematic phase, an isotropic phase, or the like depending on conditions.

In the case where a horizontal electric field mode is employed, liquid crystal exhibiting a blue phase for which an alignment film is unnecessary may be used. A blue phase is one of liquid crystal phases, which is generated just before a cholesteric phase changes into an isotropic phase while temperature of cholesteric liquid crystal is increased. Since the blue phase appears only in a narrow temperature range, a liquid crystal composition in which several weight percent or more of a chiral material is mixed is used for the liquid crystal layer in order to improve the temperature range. The liquid crystal composition which includes liquid crystal exhibiting a blue phase and a chiral material has a short response time and has optical isotropy. In addition, the liquid crystal composition which includes liquid crystal exhibiting a blue phase does not need alignment treatment and has a small viewing angle dependence. An alignment film is not necessarily provided and rubbing treatment is thus not necessary; accordingly, electrostatic discharge damage caused by the rubbing treatment can be prevented and defects and damage of the liquid crystal display device in the manufacturing process can be reduced.

The display device 80 including the liquid crystal element 51 can be driven in a twisted nematic (TN) mode, an in-plane-switching (IPS) mode, a fringe field switching (FFS) mode, an axially symmetric aligned micro-cell (ASM) mode, an optical compensated birefringence (OCB) mode, a ferroelectric liquid crystal (FLC) mode, an antiferroelectric liquid crystal (AFLC) mode, or the like.

The display device 80 may be a normally black liquid crystal display device such as a transmissive liquid crystal display device utilizing a vertical alignment (VA) mode. Examples of the vertical alignment mode include a multi-domain vertical alignment (MVA) mode, a patterned vertical alignment (PVA) mode, and an advanced super view (ASV) mode.

In this embodiment, horizontal electric field modes typified by an FFS mode and a DPS mode are mainly described. The DPS mode will be described later.

In the pixel 70 illustrated in FIG. 25B, one of a source electrode and a drain electrode of the transistor 52 is electrically connected to the signal line 79, and the other is electrically connected to the one of the pair of electrodes of the liquid crystal element 51. A gate electrode of the transistor 52 is electrically connected to the scan line 77. The transistor 52 has a function of controlling whether to write a data signal.

In the pixel 70 illustrated in FIG. 25B, one of a pair of electrodes of the capacitor 55 is connected to the other of the source electrode and the drain electrode of the transistor 52. The other of the electrodes of the capacitor 55 is electrically connected to the common line 75. The potential of the common line 75 is set as appropriate in accordance with the specifications of the pixel 70. The capacitor 55 has a function of a storage capacitor for storing written data. In the display device 80 driven in the FFS mode, the one of the electrodes of the capacitor 55 corresponds to part or the whole of the one of the electrodes of the liquid crystal element 51, and the other of the electrodes of the capacitor 55 corresponds to part or the whole of the other of the electrodes of the liquid crystal element 51.

### <Structure Example of Element Substrate>

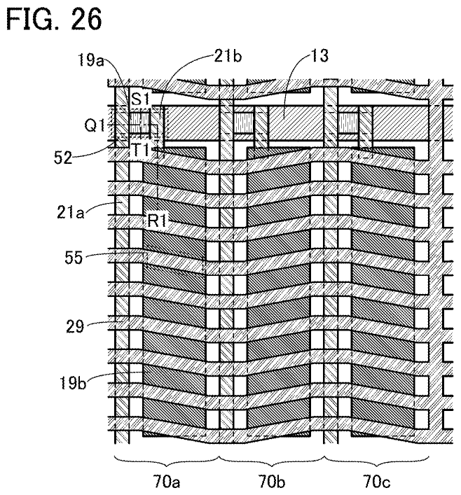

Next, a specific configuration of a pixel included in the display device 80 is described. FIG. 26 is a top view illustrating a plurality of pixels 70a, 70b, and 70c included in the display device 80 driven in the FFS mode.

In FIG. 26, a conductive film 13 functioning as a scan line extends substantially perpendicularly to the signal line (in the horizontal direction in the drawing). A conductive film 21a functioning as a signal line extends substantially perpendicularly to the scan line (in the vertical direction in the drawing). Note that the conductive film 13 functioning as a scan line is electrically connected to the scan line driver circuit 74, and the conductive film 21a functioning as a signal line is electrically connected to the signal line driver circuit 76 (see FIG. 25A).

The transistor 52 is provided near the intersection portion between the scan line and the signal line. The transistor 52 includes the conductive film 13 functioning as a gate electrode, a gate insulating film (not illustrated in FIG. 26), an oxide semiconductor film 19a, where a channel region is formed, over the gate insulating film, and the conductive film 21a and a conductive film 21b which function as a source electrode and a drain electrode. The conductive film 13 also functions as a scan line, and a region of the conductive film 13 that overlaps with the oxide semiconductor film 19a functions as the gate electrode of the transistor 52. The conductive film 21a also functions as a signal line, and a region of the conductive film 21a that overlaps with the oxide semiconductor film 19a functions as the source electrode or the drain electrode of the transistor 52. In the top view of FIG. 26, an end portion of the scan line is located on the outer side of an end portion of the oxide semiconductor film 19a. Thus, the scan line functions as a light-blocking film for blocking light from a light source such as a backlight. As a result, the oxide semiconductor film 19a included in the transistor is not irradiated with light, so that variations in electrical characteristics of the transistor can be suppressed.

The conductive film 21b is electrically connected to an oxide semiconductor film 19b having a function of a pixel electrode. A common electrode 29 is provided over the oxide semiconductor film 19b with an insulating film (not illustrated in FIG. 26) positioned therebetween.

The common electrode 29 has stripe regions extending in a direction intersecting with the signal line. The stripe region is connected to a region extending in a direction parallel or substantially parallel to the signal line. Therefore, in the plurality of pixels in the display device 80, the stripe regions of the common electrode 29 have the same potential.

The capacitor 55 is formed in a region where the oxide semiconductor film 19b and the common electrode 29 overlap each other. The oxide semiconductor film 19b and the common electrode 29 have light-transmitting properties. That is, the capacitor 55 transmits light.

Since having a light-transmitting property, the capacitor 55 can be formed large (in a large area) in the pixel 70. Accordingly, a display device having capacitance increased while increasing the aperture ratio, typically 50% or more, preferably 60% or more can be provided. For example, in a high-resolution display device such as a liquid crystal display device, the area of a pixel is small and accordingly the area of a capacitor is small. For this reason, the amount of charge accumulated in the capacitor is reduced in the high-resolution display device. However, since the capacitor 55 of this embodiment has a light-transmitting property, when the capacitor is provided in a pixel, enough capacitance can be obtained in the pixel and the aperture ratio can be increased. Typically, the capacitor 55 can be suitably used for a high-resolution display device with a pixel density of 200 ppi or more, 300 ppi or more, or furthermore, 500 ppi or more.

In a liquid crystal display device, the larger the capacitance value of a capacitor is, the longer a period during which the alignment of liquid crystal molecules of a liquid crystal element can be kept constant in the state where an electric field is applied can be. Since the period can be made longer, for displaying a still image, the number of times of rewriting image data can be reduced, leading to a reduction in power consumption. According to the structure of this embodiment, the aperture ratio can be improved even in a high-resolution display device, which makes it possible to use light from a light source such as a backlight efficiently, so that power consumption of the display device can be reduced.

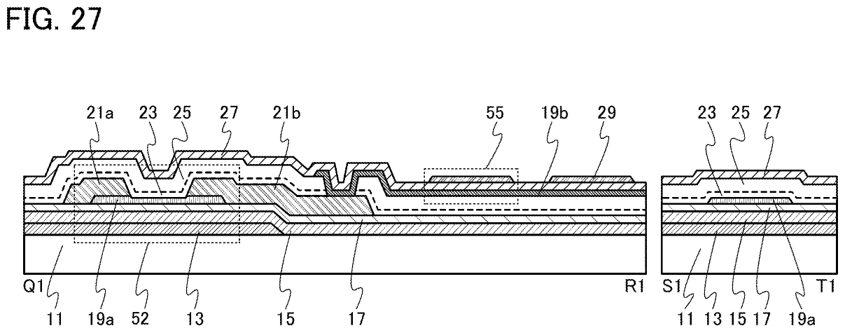

FIG. 27 is a cross-sectional view taken along the dashed-dotted line Q1-R1 and the dashed-dotted line S1-T1 in FIG. 26. The transistor 52 illustrated in FIG. 27 is a channel-etched transistor. Note that the transistor 52 in the channel length direction and the capacitor 55 are illustrated in the cross-sectional view taken along the dashed-dotted line Q1-R1, and the transistor 52 in the channel width direction is illustrated in the cross-sectional view taken along the dashed-dotted line S1-T1.

The transistor 52 in FIG. 27 has a single-gate structure and includes the conductive film 13 functioning as a gate electrode over the substrate 11. The transistor 52 further includes an insulating film 15 formed over the substrate 11 and the conductive film 13 functioning as a gate electrode, an insulating film 17 formed over the insulating film 15, the oxide semiconductor film 19a overlapping with the conductive film 13 functioning as a gate electrode with the insulating films 15 and 17 positioned therebetween, and the conductive films 21a and 21b functioning as the source electrode and the drain electrode which are in contact with the oxide semiconductor film 19a. The insulating film 23 is formed over the insulating film 17, the oxide semiconductor film 19a, and the conductive films 21a and 21b functioning as the source electrode and the drain electrode. The insulating film 25 is formed over the insulating film 23. The oxide semiconductor film 19b is formed over the insulating film 25. The oxide semiconductor film 19b is electrically connected to one of the conductive films 21a and 21b functioning as the source electrode and the drain electrode (here, the conductive film 21b) through an opening in the insulating film 23 and the insulating film 25. An insulating film 27 is formed over the insulating film 25 and the oxide semiconductor film 19b. The common electrode 29 is formed over the insulating film 27.

By providing the oxide semiconductor film 19b over the insulating film 25 in a region overlapping with the oxide semiconductor film 19a, the transistor 52 may have a double-gate structure in which the oxide semiconductor film 19b is used as a second gate electrode.

A region where the oxide semiconductor film 19b, the insulating film 27, and the common electrode 29 overlap one another functions as the capacitor 55.

Note that a cross-sectional view of one embodiment of the present invention is not limited thereto. The display device can have a variety of different structures. For example, the oxide semiconductor film 19b may have a slit. Alternatively, the oxide semiconductor film 19b may have a comb-like shape.

The description of the structure of the semiconductor device in Embodiment 1 can be referred to for the structure of the display device 80 of one embodiment of the present invention. Thus, the description of the material and the manufacturing method of the substrate 102 can be referred to for those of the substrate 11. The description of the material and the manufacturing method of the gate electrode 104 can be referred to for those of the conductive film 13. The description of the material and the manufacturing method of the insulating film 106 and those of the insulating film 107 can be referred to for those of the insulating film 15 and those of the insulating film 17, respectively. The description of the material and the manufacturing method of the first oxide semiconductor film 110 and those of the second oxide semiconductor film 111 can be referred to for those of the oxide semiconductor film 19a and those of the oxide semiconductor film 19b, respectively. The description of the material and the manufacturing method of the source electrode 112a and the drain electrode 112b can be referred to for those of the conductive film 21a and the conductive film 21b. The description of the materials and the manufacturing methods of the insulating films 114, 116, and 118 can be referred to for those of the insulating films 23, 25, and 27. The description of the material and the manufacturing method of the conductive film 120 can be referred to for those of the common electrode 29.

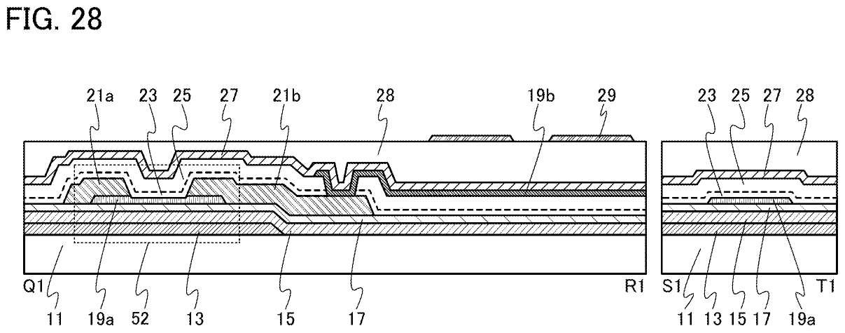

As illustrated in FIG. 28 the common electrode 29 may be provided over an insulating film 28 over the insulating film 27. The insulating film 28 has a function of a planarization film. The insulating film 119 in Embodiment 3 can be referred to for the material and formation method of the insulating film 28.

### Structure Example of Element Substrate (Modification Example 1)

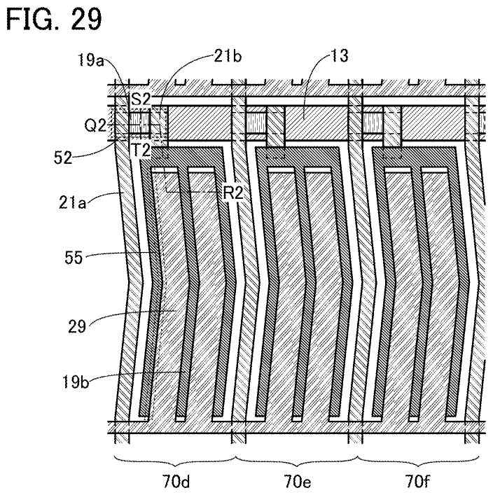

FIG. 29 is a top view illustrating pixels 70d, 70e, and 70f, which are different from the pixels illustrated in FIG. 26, included in the display device 80.

In FIG. 29, a conductive film 13 functioning as a scan line extends in the horizontal direction in the drawing. A conductive film 21a functioning as a signal line extends substantially perpendicularly to the scan line (in the vertical direction in the drawing) and has a dogleg shape (V-like shape). Note that the conductive film 13 functioning as a scan line is electrically connected to the scan line driver circuit 74, and the conductive film 21a functioning as a signal line is electrically connected to the signal line driver circuit 76 (see FIG. 25A).

The transistor 52 is provided near the intersection portion between the scan line and the signal line. The transistor 52 includes the conductive film 13 functioning as a gate electrode, a gate insulating film (not illustrated in FIG. 29), the oxide semiconductor film 19a, where a channel region is formed, over the gate insulating film, and the conductive film 21a and the conductive film 21b which function as a source electrode and a drain electrode. The conductive film 13 also functions as a scan line, and a region of the conductive film 13 that overlaps with the oxide semiconductor film 19a functions as the gate electrode of the transistor 52. The conductive film 21a also functions as a signal line, and a region of the conductive film 21a that overlaps with the oxide semiconductor film 19a functions as the source electrode or the drain electrode of the transistor 52. In the top view of FIG. 29, an end portion of the scan line is located on the outer side of an end portion of the oxide semiconductor film 19a. Thus, the scan line functions as a light-blocking film for blocking light from a light source such as a backlight. As a result, the oxide semiconductor film 19a included in the transistor is not irradiated with light, so that variations in electrical characteristics of the transistor can be suppressed.

The conductive film 21b is electrically connected to the oxide semiconductor film 19b having a function of a pixel electrode. The oxide semiconductor film 19b is formed in a comb-like shape. An insulating film (not illustrated in FIG. 29) is provided over the oxide semiconductor film 19b, and the common electrode 29 is provided over the insulating film. The common electrode 29 is formed in a comb-like shape to partly overlap and engage with the oxide semiconductor film 19b when seen from the above. The common electrode 29 is connected to a region extending in a direction parallel or substantially parallel to the scan line. Therefore, in the plurality of pixels in the display device 80, the comb-like shaped regions of the common electrode 29 have the same potential. Note that each of the oxide semiconductor film 19b and the common electrode 29 has a dogleg shape (V-like shape) bent along the signal line (the conductive film 21a).

The capacitor 55 is formed in a region where the oxide semiconductor film 19b and the common electrode 29 overlap each other. The oxide semiconductor film 19b and the common electrode 29 have light-transmitting properties. That is, the capacitor 55 transmits light.

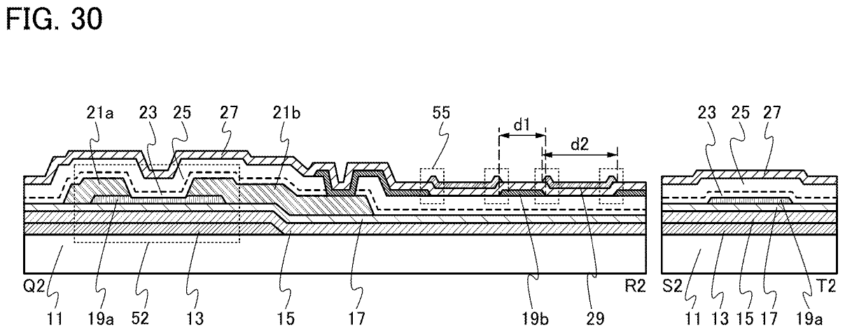

FIG. 30 is a cross-sectional view taken along the dashed-dotted line Q2-R2 and the dashed-dotted line S2-T2 in FIG. 29. The transistor 52 illustrated in FIG. 30 is a channel-etched transistor. Note that the transistor 52 in the channel length direction and the capacitor 55 are illustrated in the cross-sectional view taken along the dashed-dotted line Q2-R2, and the transistor 52 in the channel width direction is illustrated in the cross-sectional view taken along the dashed-dotted line S2-T2.

The transistor 52 in FIG. 30 has a single-gate structure and includes the conductive film 13 functioning as a gate electrode over the substrate 11. The transistor 52 further includes an insulating film 15 formed over the substrate 11 and the conductive film 13 functioning as a gate electrode, an insulating film 17 formed over the insulating film 15, the oxide semiconductor film 19a overlapping with the conductive film 13 functioning as a gate electrode with the insulating films 15 and 17 positioned therebetween, and the conductive films 21a and 21b functioning as the source electrode and the drain electrode which are in contact with the oxide semiconductor film 19a. The insulating film 23 is formed over the insulating film 17, the oxide semiconductor film 19a, and the conductive films 21a and 21b functioning as the source electrode and the drain electrode. The insulating film 25 is formed over the insulating film 23. The oxide semiconductor film 19b is formed over the insulating film 25. The oxide semiconductor film 19b is electrically connected to one of the conductive films 21a and 21b functioning as the source electrode and the drain electrode (here, the conductive film 21b) through an opening in the insulating film 23 and the insulating film 25. An insulating film 27 is formed over the insulating film 25 and the oxide semiconductor film 19b. The conductive film 29 is formed over the insulating film 27.

In the pixel shown in FIG. 30, in a region over the insulating film 27 and the common electrode 29 where the alignment of liquid crystals is controlled, the oxide semiconductor film 19b serving as a pixel electrode and the common electrode 29 are provided over the insulating film 25 and the insulating film 27, respectively. Such a driving method of a display device where an electric field is generated between a pair of electrodes over different surfaces to control the alignment of liquid crystals can be referred to as a differential plane switching (DPS) mode.

By providing the oxide semiconductor film 19b over the insulating film 25 in a region overlapping with the oxide semiconductor film 19a, the transistor 52 may have a double-gate structure in which the oxide semiconductor film 19b is used as a second gate electrode.

A region where the oxide semiconductor film 19b, the insulating film 27, and the common electrode 29 overlap one another functions as the capacitor 55.

In the liquid crystal display device illustrated in FIG. 29 and FIG. 30, with a structure in which regions including end portions of the oxide semiconductor film 19b and those of the common electrode 29 overlap each other, a capacitor in a pixel is formed. With this structure, a capacitor with a suitable size, not a too large size, can be formed in a large liquid crystal display device.

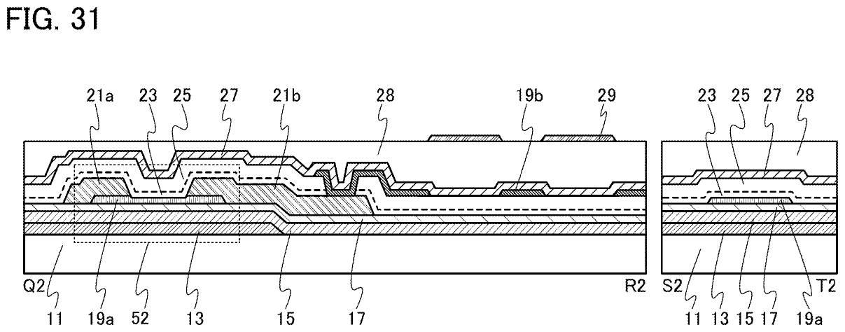

As illustrated in FIG. 31, the common electrode 29 may be provided over the insulating film 28 over the insulating film 27.

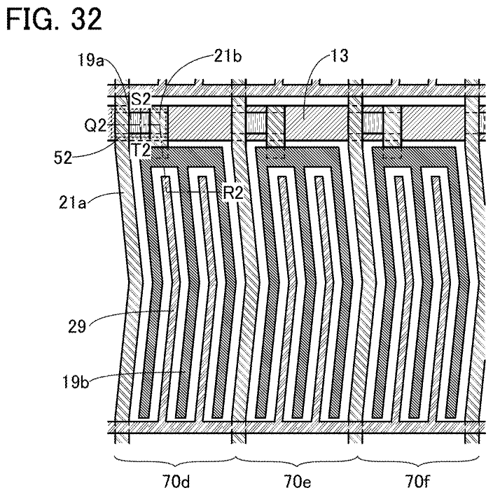

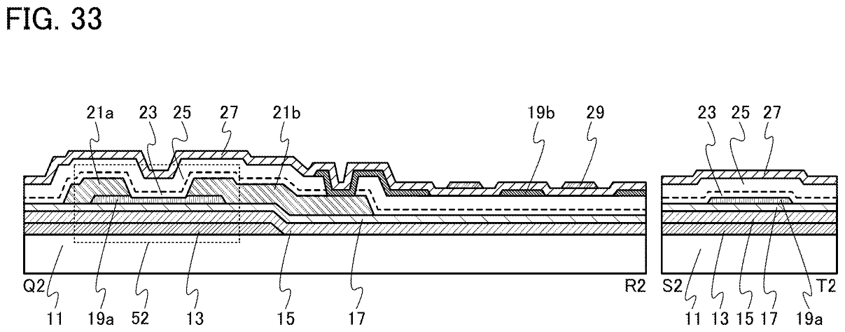

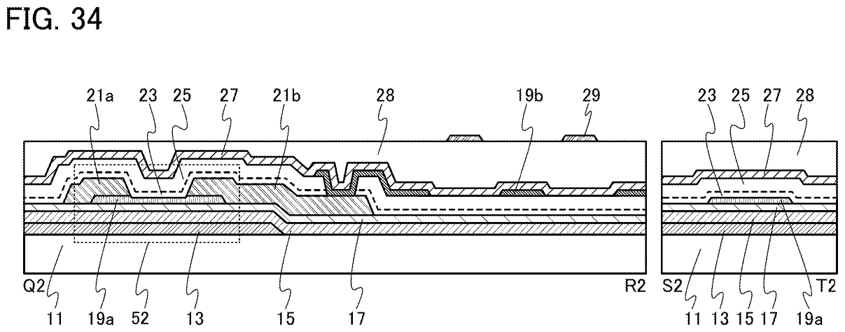

As illustrated in FIG. 32 and FIG. 33, a structure in which the oxide semiconductor film 19b and the common electrode 29 do not overlap each other may be employed. The positions of the oxide semiconductor film 19b and the common electrode 29 can be set as appropriate depending on the capacitance of the capacitor in accordance with the resolution and driving method of the display device. Note that the common electrode 29 in the display device illustrated in FIG. 33 may be provided over the insulating film 28 having a function of a planarization film (see FIG. 34).

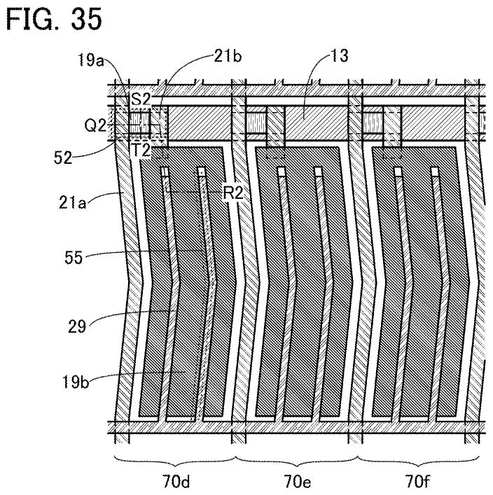

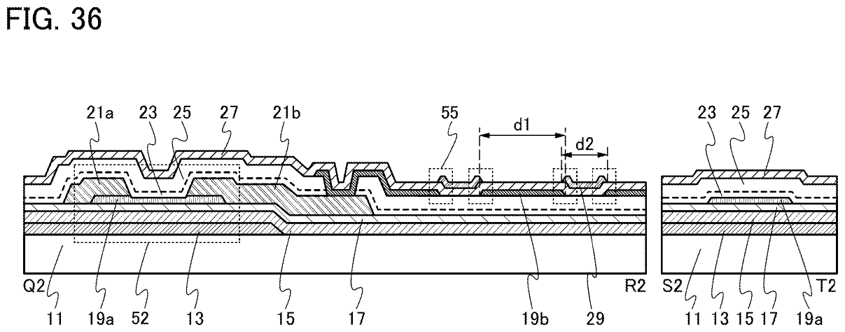

In the liquid crystal display device illustrated in FIG. 29 and FIG. 30, a width d1 of a region extending in a direction parallel or substantially parallel to the signal line (the conductive film 21a) of the oxide semiconductor film 19b is smaller than a width d2 of a region extending in a direction parallel or substantially parallel to the signal line of the common electrode 29 (see FIG. 30), but the widths are not limited to this relation. As illustrated in FIG. 35 and FIG. 36, the width d1 may be larger than the width d2. Alternatively, the width d1 may be equal to the width d2. Further alternatively, in a pixel (e.g., the pixel 70d), widths of a plurality of regions extending in a direction parallel or substantially parallel to signal lines of the oxide semiconductor film 19b and/or the common electrode 29 may be different from one another.

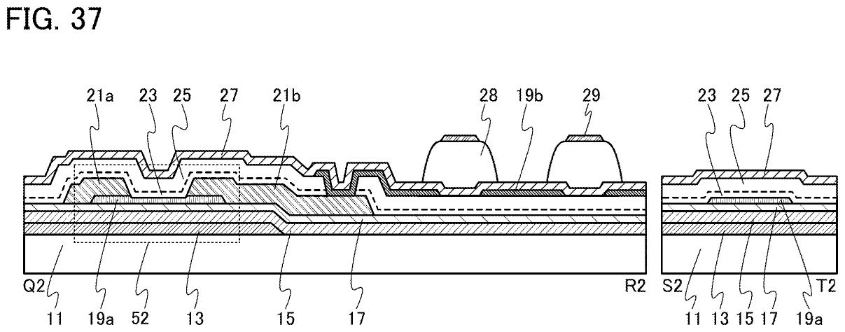

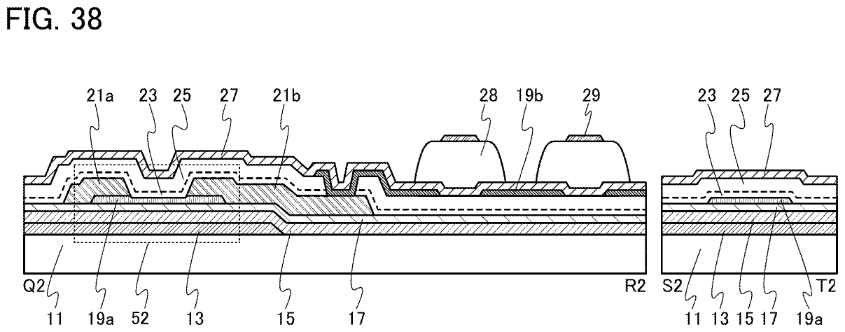

As illustrated in FIG. 37, a structure in which the insulating film 28 over the insulating film 27 is removed other than a region overlapping with the common electrode 29 over the insulating film 28 may be employed. In that case, the insulating film 28 can be etched using the common electrode 29 as a mask. Unevenness of the common electrode 29 over the insulating film 28 having a function of a planarization film can be suppressed, and the insulating film 28 can have a gentle side surface from an end portion of the common electrode 29 to the insulating film 27. As illustrated in FIG. 38, a structure in which part of a top surface of the insulating film 28 parallel to the substrate 11 is not covered with the common electrode 29 may be employed.

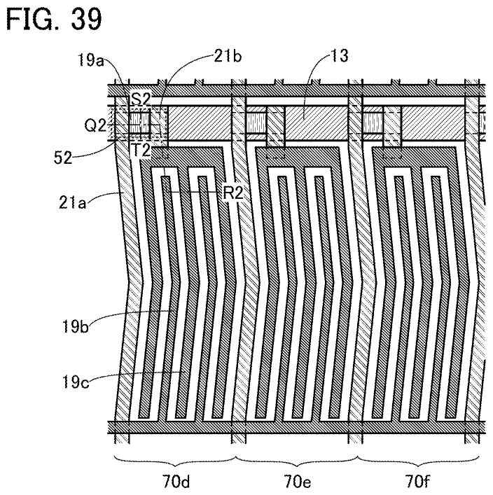

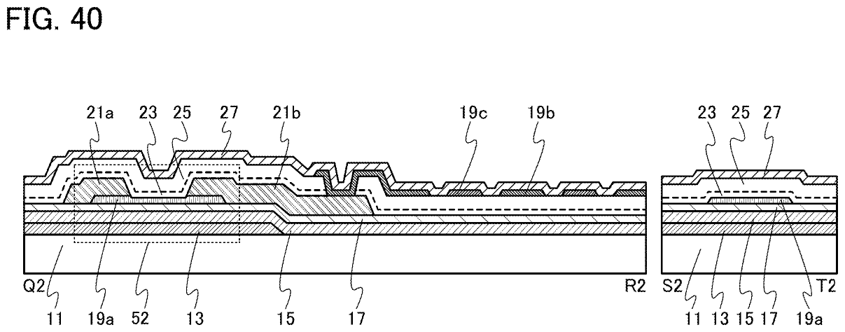

As illustrated in FIG. 39 and FIG. 40, the common electrode and the oxide semiconductor film 19b may be formed over the same layer, that is, over the insulating film 25. A common electrode 19c illustrated in FIG. 39 and FIG. 40 can be formed with the same material at the same time as the oxide semiconductor film 19b.

The description of the structure of the semiconductor device in Embodiment 1 can be referred to for the structure of the display device 80 of one embodiment of the present invention. Thus, the description of the material and the manufacturing method of the substrate 102 can be referred to for those of the substrate 11. The description of the material and the manufacturing method of the gate electrode 104 can be referred to for those of the conductive film 13. The description of the material and the manufacturing method of the insulating film 106 and those of the insulating film 107 can be referred to for those of the insulating film 15 and those of the insulating film 17, respectively. The description of the material and the manufacturing method of the first oxide semiconductor film 110 and those of the second oxide semiconductor film 111 can be referred to for those of the oxide semiconductor film 19a and those of the oxide semiconductor film 19b, respectively. The description of the material and the manufacturing method of the source electrode 112a and the drain electrode 112b can be referred to for those of the conductive film 21a and the conductive film 21b. The description of the materials and the manufacturing methods of the insulating films 114, 116, and 118 can be referred to for those of the insulating films 23, 25, and 27. The description of the material and the manufacturing method of the conductive film 120 can be referred to for those of the common electrode 29.

The insulating film 119 in Embodiment 3 can be referred to for the material and formation method of the insulating film 28.

Note that the structures, methods, and the like described in this embodiment can be used as appropriate in combination with any of the structures, methods, and the like described in the other embodiments.

### Structure Example of Element Substrate (Modification Example 2)

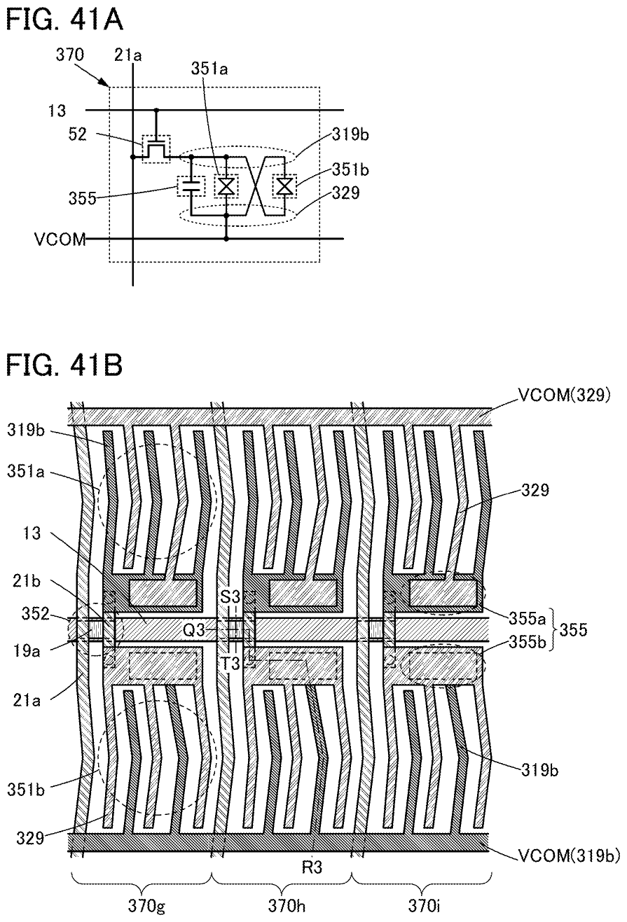

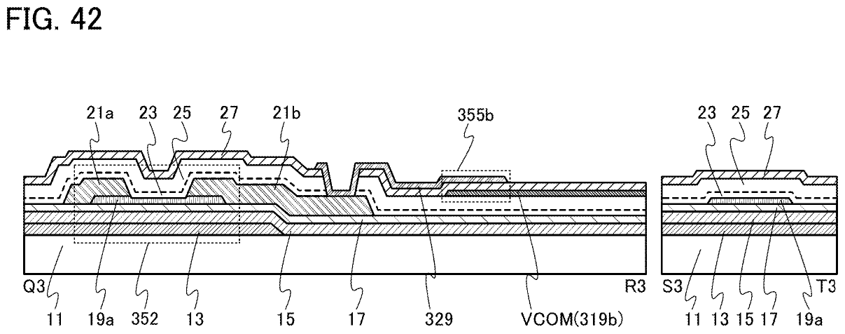

Described below is the structure of a plurality of pixels 370 which is different from that of a plurality of pixels included in the display device 80 shown in FIG. 25A. FIG. 41A is an example of a circuit configuration of the pixels 370. FIG. 41B is a top view illustrating a plurality of pixels 370g, 370i, and 370h included in the display device 80. FIG. 42 is a cross-sectional view taken along the dashed-dotted line Q3-R3 and S3-T3 in FIG. 41B.

The pixel 370 is different from the pixel 70 in FIG. 25B in that a liquid crystal element 351a and a liquid crystal element 351b connected in parallel are provided instead of the liquid crystal element 51. Here, such different structures will be described in detail, and the above description is referred to for the other similar structures. Note that the liquid crystal element 351b is not shown in the cross-sectional view of FIG. 42.

In the liquid crystal element 351a, an oxide semiconductor film 319b is electrically connected to a drain electrode of a transistor 352 and serves as a pixel electrode. In addition, a conductive film 329 is electrically connected to a wiring VCOM extending in a direction parallel or substantially parallel to the scan line (the conductive film 13) and serves as a common electrode.

In the liquid crystal element 351b, a conductive film 329 is electrically connected to the drain electrode of a transistor 352 and serves as a pixel electrode. In addition, the oxide semiconductor film 319b is electrically connected to the wiring VCOM extending in a direction parallel or substantially parallel to the scan line (the conductive film 13) and serves as a common electrode.

The wiring VCOM electrically connected to the conductive film 329 and the wiring VCOM electrically connected to the oxide semiconductor film 319b are denoted as one wiring in FIG. 41A, which is a non-limiting example. Alternatively, the wiring VCOM electrically connected to the conductive film 329 and the wiring VCOM electrically connected to the oxide semiconductor film 319b may be have the same or different potentials. For example, the wiring VCOM electrically connected to the conductive film 329 and the wiring VCOM electrically connected to the oxide semiconductor film 319b can have the same potentials when they are electrically connected to each other in the scan line driver circuit 74 (see FIG. 25A).

A capacitor 355 included in the pixel 370 includes a capacitor 355a and a capacitor 355b. One of a pair of electrodes of the capacitor 355a includes an oxide semiconductor film 319b and is electrically connected to a drain electrode of the transistor 352. The other of the pair of electrodes of the capacitor 355a includes a conductive film 329. One of a pair of electrodes of the capacitor 355b includes the conductive film 329 and is electrically connected to the drain electrode of the transistor 352. The other of the pair of electrodes of the capacitor 355b includes the oxide semiconductor film 319b.

The oxide semiconductor film 19b can be referred to for the material and formation method of the oxide semiconductor film 319b. The common electrode 29 can be referred to for the material and formation method of the conductive film 329.

The liquid crystal element 351a and the liquid crystal element 351b are connected in parallel as described above. Accordingly, characteristics of the liquid crystal elements can be prevented from being asymmetric due to the positions of the conductive film 329 and the oxide semiconductor film 319b even in the case where the liquid crystal elements are driven with the applied voltage inverted.

This embodiment can be combined with any of the other embodiments in this specification as appropriate.

### Embodiment 7

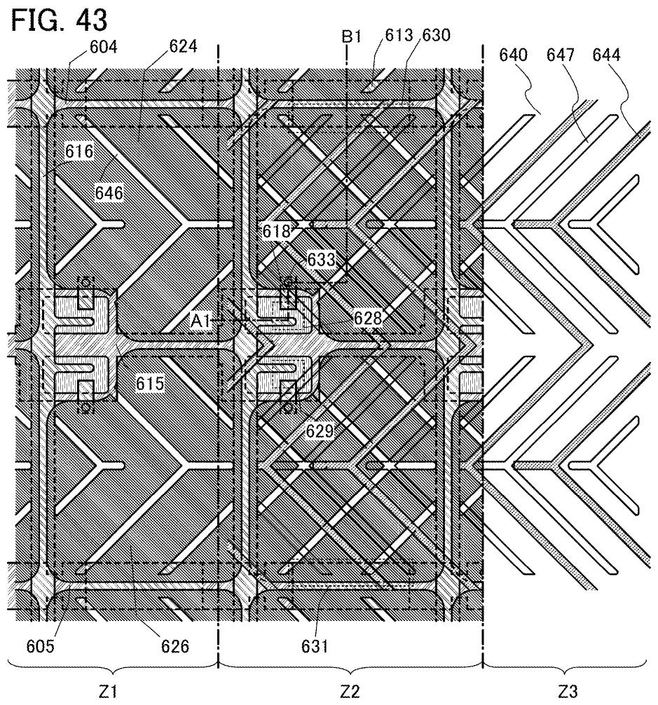

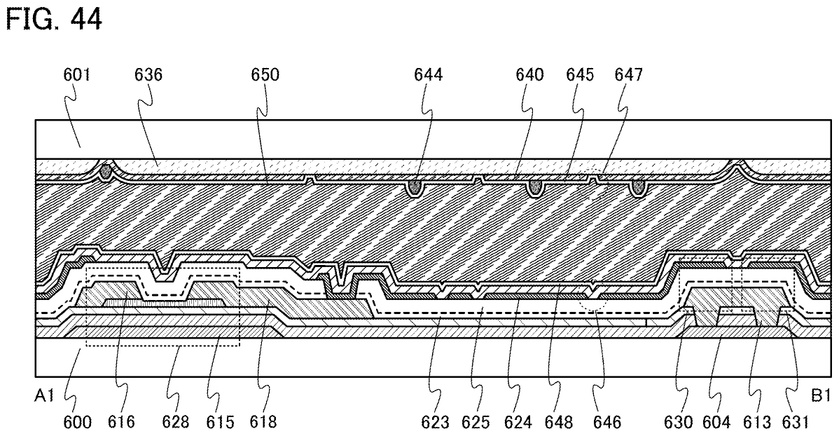

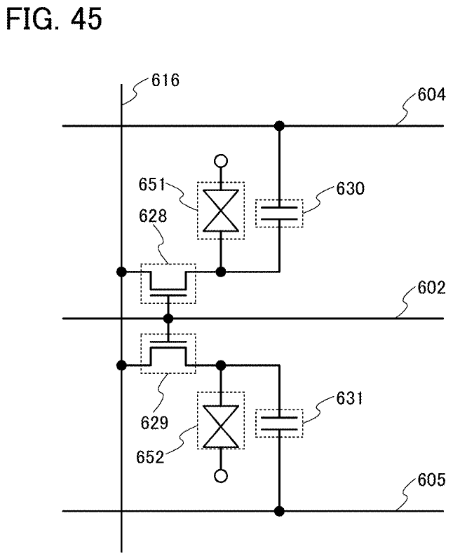

In this embodiment, a structure of a pixel including a liquid crystal element which operates in a vertical alignment (VA) mode is described with reference to FIG. 43 to FIG. 45. FIG. 43 is a top view of the pixel included in the liquid crystal display device. FIG. 44 is a side view including a cross section taken along the line Z1-Z2 in FIG. 43. FIG. 45 is an equivalent circuit diagram of the pixel included in the liquid crystal display device.

A vertical alignment (VA) is a mode for controlling alignment of liquid crystal molecules of a liquid crystal display panel. In the VA liquid crystal display device, liquid crystal molecules are aligned in a vertical direction with respect to a panel surface when no voltage is applied.

In the following description, it is devised to particularly separate pixels into some regions (sub-pixels) so that molecules are aligned in different directions in the respective regions. This is referred to as multi-domain or multi-domain design. In the following description, a liquid crystal display device with multi-domain design is described.

In FIG. 43, Z1 is a top view of a substrate 600 provided with a pixel electrode 624. Z3 is a top view of a substrate 601 provided with a common electrode 640. Z2 is a top view illustrating a state where the substrate 601 provided with the common electrode 640 is overlapped with the substrate 600 provided with the pixel electrode 624.

The transistor 628, the pixel electrode 624 connected thereto, and the capacitor 630 are formed over the substrate 600. A drain electrode 618 of the transistor 628 is electrically connected to the pixel electrode 624 through an opening 633 provided in an insulating film 623 and an insulating film 625. An insulating film 627 is provided over the pixel electrode 624.

The transistors described in Embodiments 1, 2, 3, or 5 can be used as the transistor 628.

The capacitor 630 includes a wiring 613 over a capacitor wiring 604 which is a first capacitor wiring, the insulating films 623 and 625, and the pixel electrode 624. The capacitor wiring 604 can be formed simultaneously with and using the same material as that of the gate wiring 615 of the transistor 628. In addition, the wiring 613 can be formed simultaneously with and using the same material as that of the drain electrode 618 and the wiring 616.

The oxide semiconductor film with low resistivity which is described in Embodiment 1 can be used for the pixel electrode 624. That is, the description of the material and the manufacturing method of the second oxide semiconductor film 111 in Embodiment 1, can be referred to for those of the pixel electrode 624.

The pixel electrode 624 is provided with a slit 646. The slit 646 is provided for controlling the alignment of the liquid crystals.

A transistor 629, a pixel electrode 626 connected thereto, and a capacitor 631 can be formed in manners similar to those for the transistor 628, the pixel electrode 624, and the capacitor 630, respectively. Both the transistors 628 and 629 are connected to the wiring 616. The wiring 616 functions as a source electrode in each of the transistor 628 and the transistor 629. A pixel of the liquid crystal display panel described in this embodiment includes the pixel electrodes 624 and 626. Each of the pixel electrodes 624 and 626 is a sub-pixel.

The substrate 601 is provided with a coloring film 636 and the common electrode 640, and the common electrode 640 is provided with a structure body 644. The common electrode 640 is provided with a slit 647. An alignment film 648 is formed over the pixel electrode 624. Similarly, an alignment film 645 is formed on the common electrode 640 and the structure body 644. A liquid crystal layer 650 is formed between the substrate 600 and the substrate 601.

The common electrode 640 is preferably formed using the material similar to that of the conductive film 120, which is described in Embodiment 1. The slits 647 and the protrusions 644 of the common electrode 640 control the alignment of liquid crystals.

When a voltage is applied to the pixel electrode 624 provided with the slit 646, a distorted electric field (an oblique electric field) is generated in the vicinity of the slit 646. The slit 646 and the structure body 644 on the substrate 601 side and the slit 647 are alternately arranged in an engaging manner, and thus, an oblique electric field is effectively generated to control alignment of the liquid crystal, so that a direction of alignment of the liquid crystal varies depending on location. That is, the viewing angle of a liquid crystal display panel is increased by employing multi-domain. Note that one of the structure body 644 and the slit 647 may be provided for the substrate 601.

FIG. 44 illustrates a state where the substrate 600 and the substrate 601 are overlapped with each other and liquid crystal is injected therebetween. A liquid crystal element is formed by overlapping of the pixel electrode 624, the liquid crystal layer 650, and the common electrode 640.

FIG. 45 illustrates an equivalent circuit of this pixel structure. Both the transistors 628 and 629 are connected to the gate wiring 602 and the wiring 616. In this case, by making the potential of the capacitor wiring 604 different from that of a capacitor wiring 605, operation of a liquid crystal element 651 can be different from that of a liquid crystal element 652. In other words, each potential of the capacitor wirings 604 and 605 is individually controlled, whereby orientation of liquid crystals is precisely controlled to expand a viewing angle.

This embodiment can be combined with any of the other embodiments in this specification as appropriate.

### Embodiment 8

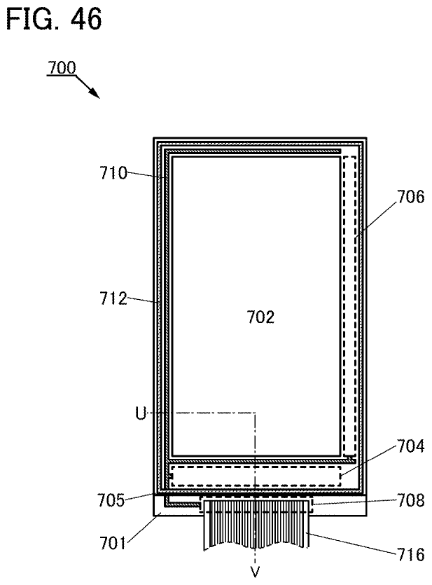

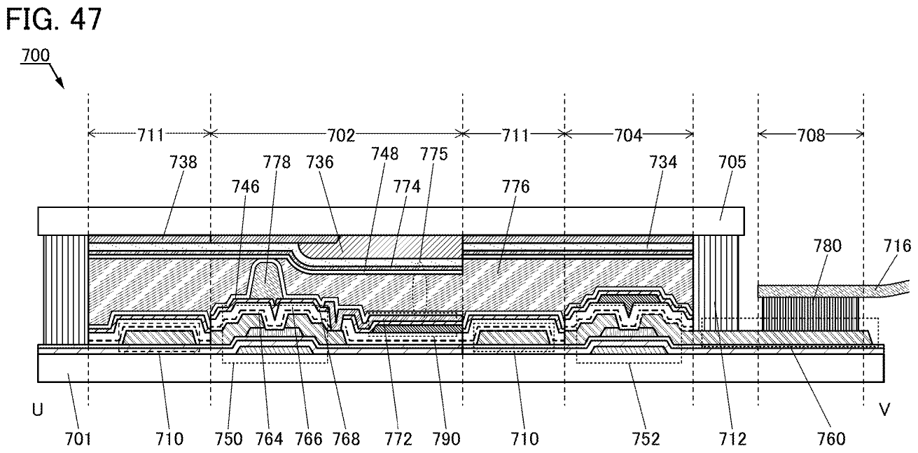

In this embodiment, an example of a display device that includes any of the transistors described in the above embodiment will be described below with reference to FIG. 46 and FIG. 47.

FIG. 46 is a top view of an example of a display device. A display device 700 illustrated in FIG. 46 includes a pixel portion 702 provided over a first substrate 701; a source driver circuit portion 704 and a gate driver circuit portion 706 provided over the first substrate 701; a sealant 712 provided to surround the pixel portion 702, the source driver circuit portion 704, and the gate driver circuit portion 706; and a second substrate 705 provided to face the first substrate 701. The first substrate 701 and the second substrate 705 are sealed with the sealant 712. That is, the pixel portion 702, the source driver circuit portion 704, and the gate driver circuit portion 706 are sealed with the first substrate 701, the sealant 712, and the second substrate 705. Although not illustrated in FIG. 46, a display element is provided between the first substrate 701 and the second substrate 705.

In the display device 700, a flexible printed circuit (FPC) terminal portion 708 electrically connected to the pixel portion 702, the source driver circuit portion 704, and the gate driver circuit portion 706 is provided in a region different from the region which is surrounded by the sealant 712 and positioned over the first substrate 701. Furthermore, an FPC 716 is connected to the FPC terminal portion 708, and a variety of signals and the like are supplied to the pixel portion 702, the source driver circuit portion 704, and the gate driver circuit portion 706 through the FPC 716. Furthermore, a signal line 710 is connected to the pixel portion 702, the source driver circuit portion 704, the gate driver circuit portion 706, and the FPC terminal portion 708. Various signals and the like are applied to the pixel portion 702, the source driver circuit portion 704, the gate driver circuit portion 706, and the FPC terminal portion 708 via the signal line 710 from the FPC 716.

A plurality of gate driver circuit portions 706 may be provided in the display device 700. An example of the display device 700 in which the source driver circuit portion 704 and the gate driver circuit portion 706 are formed over the first substrate 701 where the pixel portion 702 is also formed is described; however, the structure is not limited thereto. For example, only the gate driver circuit portion 706 may be formed over the first substrate 701 or only the source driver circuit portion 704 may be formed over the first substrate 701. In this case, a substrate where a source driver circuit, a gate driver circuit, or the like is formed (e.g., a driver circuit substrate formed using a single crystal semiconductor film or a polycrystalline semiconductor film) may be mounted on the first substrate 701. There is no particular limitation on the connection method of a separately formed driver circuit substrate; a chip on glass (COG) method, a wire bonding method, or the like can be used.

The pixel portion 702 included in the display device 700 includes a plurality of transistors and capacitors, and the semiconductor device described in Embodiment 1 can be used. In addition, the source driver circuit portion 704 and the gate driver circuit portion 706 include a plurality of transistors and wiring contact portions, and the semiconductor device described in Embodiment 2 can be used.

The display device 700 can employ various modes and can include various display elements. The display element includes at least one of an electroluminescence (EL) element (e.g., an EL element including organic and inorganic materials, an organic EL element, or an inorganic EL element) including a liquid crystal element, an LED (e.g., a white LED, a red LED, a green LED, or a blue LED), a transistor (a transistor that emits light depending on current), an electron emitting element, a liquid crystal element, an electrophoretic element, a display element using micro electro mechanical systems (MEMS) such as a grating light valve (GLV), a digital micromirror device (DMD), a digital micro shutter (DMS) element, a MIRASOL (registered trademark) display, an interferometric modulator display (IMOD) element, and a piezoelectric ceramic display, an electrowetting element, and the like. Other than the above, display media whose contrast, luminance, reflectivity, transmittance, or the like is changed by electrical or magnetic effect may be included. Alternatively, quantum dots may be used as the display element. Examples of display devices including liquid crystal elements include a liquid crystal display (e.g., a transmissive liquid crystal display, a transflective liquid crystal display, a reflective liquid crystal display, a direct-view liquid crystal display, or a projection liquid crystal display). Examples of display devices having EL elements include an EL display. Examples of display devices including electron emitters are a field emission display (FED) and an SED-type flat panel display (SED: surface-conduction electron-emitter display). Examples of display devices including quantum dots include a quantum dot display. Examples of display devices including liquid crystal elements include a liquid crystal display (e.g., a transmissive liquid crystal display, a transflective liquid crystal display, a reflective liquid crystal display, a direct-view liquid crystal display, or a projection liquid crystal display). An example of a display device including electronic ink or electrophoretic elements is electronic paper. In the case of a transflective liquid crystal display or a reflective liquid crystal display, some or all of pixel electrodes function as reflective electrodes. For example, some or all of pixel electrodes are formed to contain aluminum, silver, or the like. In such a case, a memory circuit such as an SRAM can be provided under the reflective electrodes, leading to lower power consumption.

As a display method in the display device 700, a progressive method, an interlace method, or the like can be employed. Furthermore, color elements controlled in a pixel at the time of color display are not limited to three colors: R, G, and B (R, G, and B correspond to red, green, and blue, respectively). For example, four pixels of the R pixel, the G pixel, the B pixel, and a W (white) pixel may be included. Alternatively, a color element may be composed of two colors among R, G, and B as in PenTile layout. The two colors may differ among color elements. Alternatively, one or more colors of yellow, cyan, magenta, and the like may be added to RGB. Note that the sizes of display regions may be different between respective dots of color elements. Embodiments of the disclosed invention are not limited to a display device for color display; the disclosed invention can also be applied to a display device for monochrome display.

A coloring layer (also referred to as a color filter) may be used in order to obtain a full-color display device in which white light (W) for a backlight (e.g., an organic EL element, an inorganic EL element, an LED, or a fluorescent lamp) is used. As the coloring layer, red (R), green (G), blue (B), yellow (Y), or the like may be combined as appropriate, for example. With the use of the coloring layer, higher color reproducibility can be obtained than in the case without the coloring layer. In this case, by providing a region with the coloring layer and a region without the coloring layer, white light in the region without the coloring layer may be directly utilized for display. By partly providing the region without the coloring layer, a decrease in luminance due to the coloring layer can be suppressed, and 20% to 30% of power consumption can be reduced in some cases when an image is displayed brightly. Note that in the case where full-color display is performed using a self-luminous element such as an organic EL element or an inorganic EL element, elements may emit light of their respective colors R, G, B, Y, and W. By using a self-luminous element, power consumption can be further reduced as compared to the case of using the coloring layer in some cases.

In this embodiment, structures of a display device including a liquid crystal element as display elements are described with reference to FIG. 47.

FIG. 47 is a cross-sectional view taken along dashed dotted line U-V in FIG. 46. The display device 700 illustrated in FIG. 47 includes a lead wiring portion 711, the pixel portion 702, the source driver circuit portion 704, and the FPC terminal portion 708. Note that the lead wiring portion 711 includes a wiring 710. The pixel portion 702 includes a transistor 750 and a capacitor 790. The source driver circuit portion 704 includes a transistor 752.

For example, the transistor 150 in Embodiment 1 can be used as the transistor 750. The transistor 151 in Embodiment 2 can be used as the transistor 752.

The transistors used in this embodiment each include an oxide semiconductor film which is highly purified and in which formation of oxygen vacancy is suppressed. In the transistors, the current in an off state (off-state current) can be made small. Accordingly, an electrical signal such as an image signal can be held for a longer period, and a writing interval can be set longer in an on state. Accordingly, the frequency of refresh operation can be reduced, which leads to an effect of reducing power consumption.

In addition, the transistors used in this embodiment can have relatively high field-effect mobility and thus are capable of high-speed operation. For example, with such a transistor that can operate at high speed used for a liquid crystal display device, a switching transistor in a pixel portion and a driver transistor in a driver circuit portion can be formed over one substrate. That is, a semiconductor device formed using a silicon wafer or the like is not additionally needed as a driver circuit, by which the number of components of the semiconductor device can be reduced. In addition, the transistor that can operate at high speed can be used also in the pixel portion, whereby a high-quality image can be provided.

The capacitor 160 in Embodiment 1 can be used as the capacitor 790. Owing to the light-transmitting property of the capacitor 790, the capacitor 790 can be formed large (in a large area) in a pixel included in the pixel portion 702. Accordingly, the display device can have increased capacitance and aperture ratio.

In FIG. 47, insulating films 764, 766, and 768 are formed over the transistor 750.

The insulating films 764, 766, and 768 can be formed using materials and methods similar to those of the insulating films 114, 116, and 118 described in Embodiment 1, respectively. A planarization film may be formed over the insulating film 768. The planarization film can be formed using the material and method similar to those of the insulating film 119 described in Embodiment 3.

The wiring 710 is formed through the same process as conductive films functioning as the source electrode and the drain electrode of the transistor 750 or 752. Note that the signal line 710 may be formed using a conductive film which is formed through a different process from the source electrode and the drain electrode of the transistor 750 or 752, e.g., a conductive film functioning as a gate electrode. In the case where the wiring 710 is formed using a material containing a copper element, signal delay or the like due to wiring resistance is reduced, which enables display on a large screen.

The FPC terminal portion 708 includes a connection electrode 760, an anisotropic conductive film 780, and the FPC 716. Note that the connection electrode 760 is formed through the same process as the conductive films functioning as the source electrode and the drain electrode of the transistor 750 or 752. The connection electrode 760 is electrically connected to a terminal included in the FPC 716 through the anisotropic conductive film 780.

For example, a glass substrate can be used as the first substrate 701 and the second substrate 705. The first substrate 701 and the second substrate 705 can be formed using the material and method similar to those of the substrate 102 described in Embodiment 1.

A light-blocking film 738 functioning as a black matrix, a coloring film 736 functioning as a color filter, and an insulating film 734 in contact with the light-blocking film 738 and the coloring film 736 are provided on the second substrate 705 side.

A structure 778 is provided between the first substrate 701 and the second substrate 705. The structure 778 is a columnar spacer obtained by selective etching of an insulating film and is provided to control the thickness (cell gap) between the first substrate 701 and the second substrate 705. Note that a spherical spacer may be used as the structure 778.

Although the structure in which the structure body 778 is provided on the first substrate 701 side is described as an example in this embodiment, one embodiment of the present invention is not limited thereto. For example, a structure in which the structure body 778 is provided on the second substrate 705 side, or a structure in which both of the first substrate 701 and the second substrate 705 are provided with the structure body 778 may be employed.

The display device 700 includes a liquid crystal element 775. The liquid crystal element 775 includes the conductive film 772, a conductive film 774, and a liquid crystal layer 776. The conductive film 774 is provided on the second substrate 705 side and functions as a counter electrode. The display device 700 is capable of displaying an image in such a manner that transmission or non-transmission is controlled by change in the alignment state of the liquid crystal layer 776 depending on a voltage applied to the conductive film 772 and the conductive film 774.

The conductive film 772 is connected to the conductive film functioning as a source or drain electrode included in the transistor 750. The conductive film 772 is formed over the insulating film 768 to function as a pixel electrode, i.e., one electrode of the display element. The display device 700 is a transmissive color liquid crystal display device in which a back light, a side light, or the like is provided on the substrate 701 side to perform display through the liquid crystal element 775 and the coloring film 736.

A conductive film that transmits visible light or a conductive film that reflects visible light can be used for the conductive film 772 and the conductive film 774. A material including one kind selected from indium (In), zinc (Zn), and tin (Sn) is preferably used for the conductive film that transmits visible light. The conductive film 772 and the conductive film 774 can be formed using the material similar to that of the conductive film 120 described in Embodiment 1.

Note that the display device 700 in FIG. 46 and FIG. 47 is a reflective color liquid crystal display device, but the display type is not limited thereto. For example, a transmissive color liquid crystal display device in which the conductive film 772 is a conductive film that transmits visible light may be used.

Although not illustrated in FIG. 47, an optical member (optical substrate) and the like such as a polarizing member, a retardation member, or an anti-reflection member may be provided as appropriate. For example, circular polarization may be employed by using a polarizing substrate and a retardation substrate.

The description of the liquid crystals used for the liquid crystal element 51 described in Embodiment 6 can be referred to for liquid crystals used for the liquid crystal layer 776. In addition, the driving methods described in Embodiment 6 can be used for driving the display device including the liquid crystal element.

This embodiment can be combined with any of the other embodiments in this specification as appropriate.

### Embodiment 9

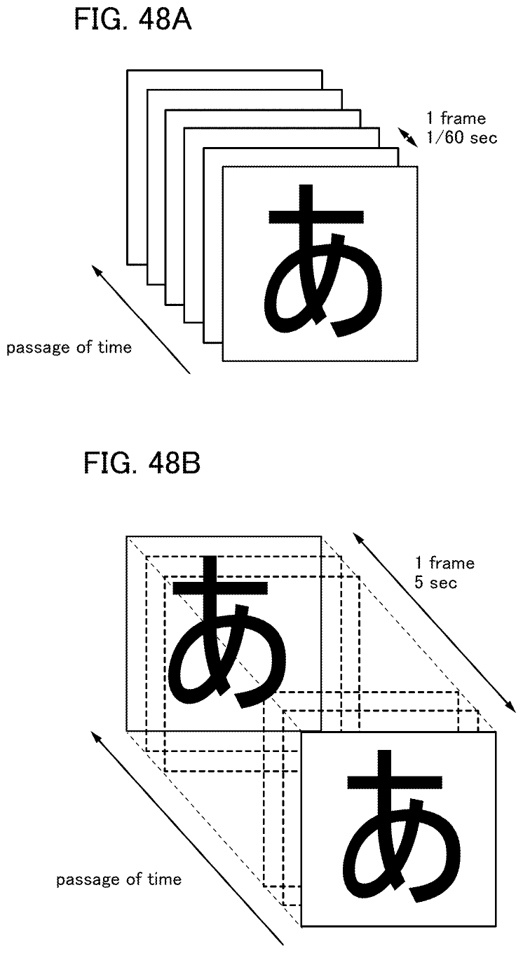

In this embodiment, a display device of one embodiment of the present invention and a method for driving the display device will be described with reference to FIGS. 48A and 48B, FIGS. 49A and 49B, FIGS. 50A to 50E, and FIGS. 51A to 51E.

Note that the display device of one embodiment of the present invention may include an information processing portion, an arithmetic portion, a memory portion, a display portion, an input portion, and the like.

In the display device of one embodiment of the present invention, power consumption can be reduced by reducing the number of times of writing signals for the same image (also referred to as “refresh operation”) in the case where the same image (still image) is continuously displayed. Note that the frequency of refresh operations is referred to as a refresh rate (also referred to as scan frequency or vertical synchronization frequency). A display device in which the refresh rate is reduced and which causes little eye fatigue is described below.

The eye fatigue is divided into two categories: nervous fatigue and muscle fatigue. The nervous fatigue is caused by prolonged looking at light emitted from a display device or blinking images. This is because brightness stimulates and fatigues the retina and nerve of the eye and the brain. The muscle fatigue is caused by overuse of a ciliary muscle which works for adjusting the focus.

FIG. 48A is a schematic view showing display on a conventional display device. As illustrated in FIG. 48A, for the display of the conventional display device, image rewriting is performed 60 times every second. Prolonged looking at such a screen might stimulate the retina and nerve of the eye and the brain of a user and lead to eye fatigue.

In the display device of one embodiment of the present invention, a transistor including an oxide semiconductor, for example, a transistor including a CAAC-OS, is used in a pixel portion. The off-state current of the transistor is extremely low. Thus, the luminance of the display device can be maintained even when the refresh rate of the display device is lowered.

That is, as shown in FIG. 48B, an image can be rewritten as less frequently as once every five seconds, for example. This enables the user to see the same one image as long as possible, so that flicker on the screen perceived by the user is reduced. Consequently, a stimulus to the retina or the nerve of an eye or the brain of the user is relieved, resulting in less nervous fatigue.

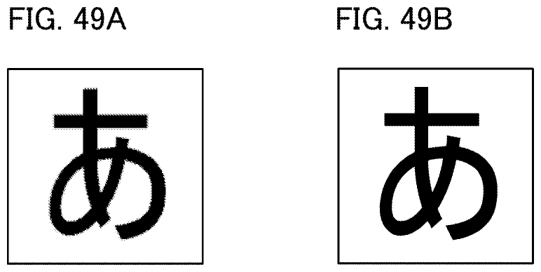

In addition, as shown in FIG. 49A, when the size of each pixel is large (for example, when the resolution is less than 150 ppi), a character displayed on the display device is blurred. When a user keeps looking at a blurred character displayed on the display device for a long time, it continues to be difficult to focus the eye on the character even though the ciliary muscle constantly moves in order to focus the eye, which might put strain on the eye.

In contrast, as shown in FIG. 49B, the display device of one embodiment of the present invention is capable of high-resolution display because the size of each pixel is small; thus, precise and smooth display can be achieved. The precise and smooth display enables ciliary muscles to adjust the focus more easily, and reduces muscle fatigue of a user. When the resolution of the display device is 150 ppi or more, preferably 200 ppi or more, further preferably 300 ppi or more, the user's muscle fatigue can be effectively reduced.

Methods for quantifying eye fatigue have been studied. For example, critical flicker (fusion) frequency (CFF) is known as an indicator for evaluating nervous fatigue. Further, focus adjustment time, near point distance, and the like are known as indicators for evaluating muscle fatigue.

Other methods for evaluating eye fatigue include electroencephalography, thermography, counting the number of times of blinking, measuring the amount of tears, measuring the speed of contractile response of the pupil, and questionnaires for surveying subjective symptoms.

By any of the variety of methods above, the effect of the reduction of eye fatigue by employing the driving method of the display device of one embodiment of the present invention can be evaluated.

### <Method for Driving Display Device>

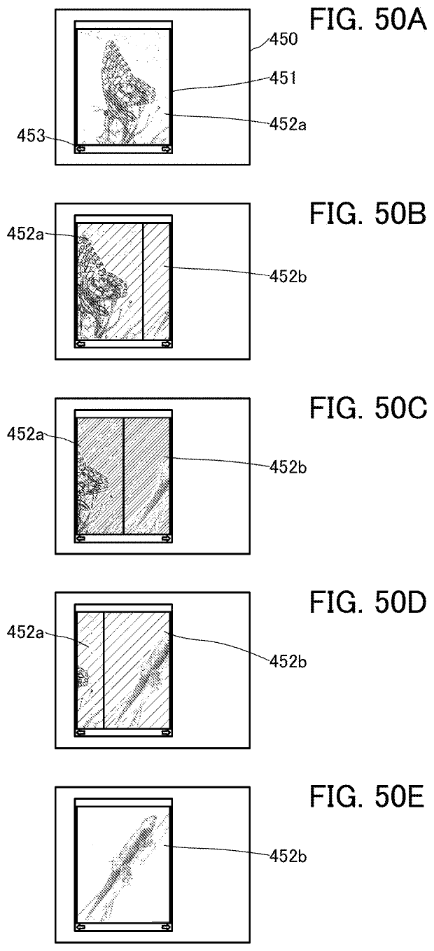

Now, a method for driving the display device of one embodiment of the present invention is described with reference to FIGS. 50A to 50E.

### [Display Example of Image Data]

An example of displaying two images including different image data by being transferred is described below.

FIG. 50A illustrates an example in which a window 451 and a first image 452a which is a still image displayed in the window 451 are displayed on a display portion 450.

At this time, display is preferably performed at the first refresh rate. Note that the first refresh rate can be higher than or equal to 1.16×10⁻⁵ Hz (about once per day) and lower than or equal to 1 Hz, higher than or equal to 2.78×10⁻⁴ Hz (about once per hour) and lower than or equal to 0.5 Hz, or higher than or equal to 1.67×10⁻² Hz (about once per minute) and lower than or equal to 0.1 Hz.

When frequency of rewriting an image is reduced by setting the first refresh rate to an extremely small value, display substantially without flicker can be achieved, and eye fatigue of a user can be more effectively reduced.

The window 451 is displayed by, for example, executing application software for image display and includes a display region where an image is displayed.

Further, in a lower part of the window 451, a button 453 for switching a displayed image data to a different image data is displayed. When a user performs operation in which the button 453 is selected, an instruction of transferring an image can be supplied to the information processing portion of the display device.

Note that the operation method performed by the user may be set in accordance with an input unit. For example, in the case where a touch panel provided to overlap with the display portion 450 is used as the input unit, it is possible to perform operation of touching the button 453 with a finger, a stylus, or the like or input operation by a gesture where an image is made to slide. In the case where the input operation is performed with gesture or sound, the button 453 is not necessarily displayed.

When the information processing portion of the display device receives the instruction of transferring an image, transfer of the image displayed in the window 451 starts (see FIG. 50B).

Note that in the case where display is performed at the first refresh rate in the state of FIG. 50A, the refresh rate is preferably changed to the second refresh rate before transfer of the image starts. The second refresh rate is a value necessary for displaying a moving image. For example, the second refresh rate can be higher than or equal to 30 Hz and lower than or equal to 960 Hz, preferably higher than or equal to 60 Hz and lower than or equal to 960 Hz, further preferably higher than or equal to 75 Hz and lower than or equal to 960 Hz, still further preferably higher than or equal to 120 Hz and lower than or equal to 960 Hz, yet still further preferably higher than or equal to 240 Hz and lower than or equal to 960 Hz.

When the second refresh rate is set to a value higher than that of the first refresh rate, a moving image can be displayed further smoothly and naturally. In addition, flicker which accompanies rewriting of data is less likely to be perceived by a user, whereby eye fatigue of a user can be reduced.

At this time, an image where the first image 452a and a second image 452b that is to be displayed next are combined is displayed in the window 451. The combined image is transferred unidirectionally (leftward in this case), and part of the first image 452a and part of the second image 452b are displayed in the window 451.

Further, when the combined image transfers, luminance of the image displayed in the window 451 is gradually lowered from the initial luminance at the time of the state in FIG. 50A.

FIG. 50C illustrates a state where the image displayed in the window 451 reaches a position of the predetermined coordinates. Thus, the luminance of the image displayed in the window 451 at this time is lowest.

Note that the predetermined coordinates in FIG. 50C is set so that half of the first image 452a and half of the second image 452b are displayed; however, the coordinates are not limited to the above, and it is preferable that the coordinates be set freely by a user.

For example, the predetermined coordinates may be set so that the ratio of the distance from the initial coordinates of the image to the distance between the initial coordinates and the final coordinates is higher than 0 and lower than 1.

In addition, it is also preferable that luminance when the image reaches the position of the predetermined coordinates be set freely by a user. For example, the ratio of the luminance when the image reaches the position of the predetermined coordinates to the initial luminance may be higher than 0 and lower than 1, preferably higher than or equal to 0 and lower than or equal to 0.8, further preferably higher than or equal to 0 and lower than or equal to 0.5.

Next, in the window 451, the combined image transfers with the luminance increasing gradually (FIG. 50D).

FIG. 50E illustrates a state when the combined image reaches the position of the final coordinates. In the window 451, only the second image 452b is displayed with luminance equal to the initial luminance.

Note that after the transfer of the image is completed, the refresh rate is preferably changed from the second refresh rate to the first refresh rate.

Since the luminance of the image is lowered in such a display mode, even when a user follows the motion of the image with his/her eyes, the user is less likely to suffer from eye fatigue. Thus, with such a driving method, eye-friendly display can be achieved.

### [Display Example of Document Information]

Next, an example in which document information whose dimension is larger than a display window is displayed by scrolling is described below.

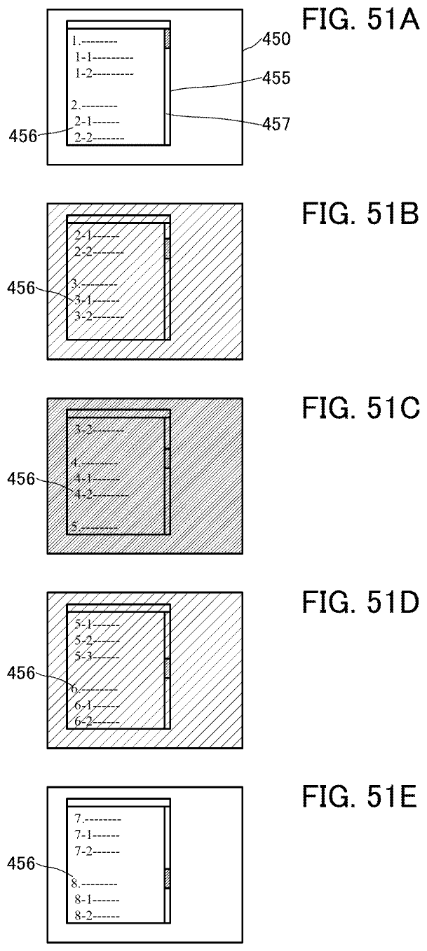

FIG. 51A illustrates an example in which a window 455 and part of document information 456 which is a still image displayed in the window 455 are displayed on the display portion 450.

At this time, display is preferably performed at the first refresh rate.

The window 455 is displayed by, for example, executing application software for document display, application software for document preparation, or the like and includes a display region where document information is displayed.

The dimension of an image of the document information 456 is larger than the display region of the window 455 in the longitudinal direction. That is, part of the document information 456 is displayed in the window 455. Further, as illustrated in FIG. 51A, the window 455 may be provided with a scroll bar 457 which indicates which part of the document information 456 is displayed.

When an instruction of transferring an image (here, also referred to as scroll instruction) is supplied to the display device by the input portion, transfer of the document information 456 starts (FIG. 51B). In addition, luminance of the displayed image is gradually lowered.

Note that in the case where display is performed at the first refresh rate in the state of FIG. 51A, the refresh rate is preferably changed to the second refresh rate before transfer of the document information 456.

In this state, not only the luminance of the image displayed in the window 455 but also the luminance of the whole image displayed on the display portion 450 is lowered.

FIG. 51C illustrates a state when the document information 456 reaches a position of the predetermined coordinates. At this time, the luminance of the whole image displayed on the display portion 450 is lowest.

Then, the document information 456 is displayed in the window 455 while being transferred (FIG. 51D). Under this condition, the luminance of the whole image displayed on the display portion 450 is gradually increased.

FIG. 51E illustrates a state where the document information 456 reaches a position of the final coordinates. In the window 455, a region of the document information 456, which is different from the region displayed in an initial state, is displayed with luminance equal to the initial luminance.

Note that after transfer of the document information 456 is completed, the refresh rate is preferably changed to the first refresh rate.

Since the luminance of the image is lowered in such a display mode, even when a user follows the motion of the image with his/her eyes, the user can be less likely to suffer from eye fatigue. Thus, with such a driving method, eye-friendly display can be achieved.

In particular, display of document information or the like, which has high contrast, gives a user eye fatigue significantly; thus, it is preferable to apply such a driving method to the display of document information.

This embodiment can be combined with any of the other embodiments disclosed in this specification as appropriate.

### Embodiment 10

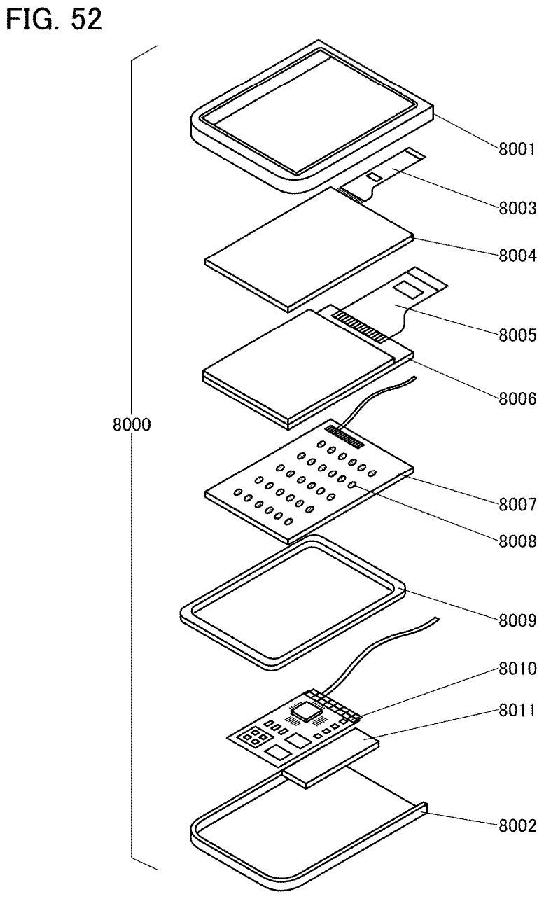

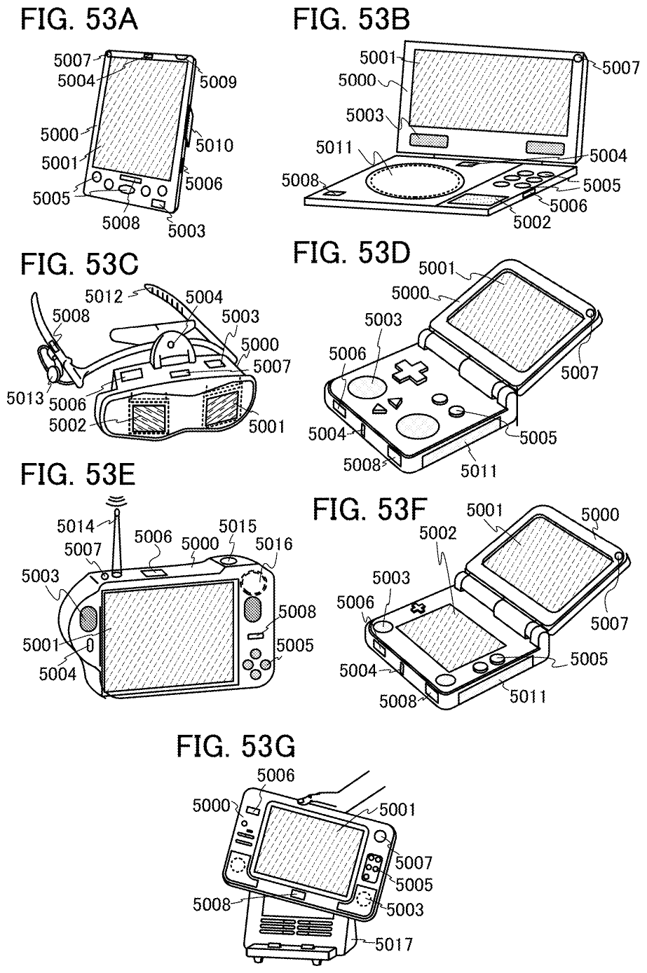

In this embodiment, a display module and electronic devices that include the semiconductor device of one embodiment of the present invention will be described with reference to FIG. 52 and FIGS. 53A to 53G.

In a display module 8000 illustrated in FIG. 52, a touch panel 8004 connected to an FPC 8003, a display panel 8006 connected to an FPC 8005, a backlight 8007, a frame 8009, a printed board 8010, and a battery 8011 are provided between an upper cover 8001 and a lower cover 8002.

The display device of one embodiment of the present invention can be used for, for example, the display panel 8006.

The shapes and sizes of the upper cover 8001 and the lower cover 8002 can be changed as appropriate in accordance with the sizes of the touch panel 8004 and the display panel 8006.

The touch panel 8004 can be a resistive touch panel or a capacitive touch panel and can be formed to overlap with the display panel 8006. A counter substrate (sealing substrate) of the display panel 8006 can have a touch panel function. A photosensor may be provided in each pixel of the display panel 8006 to form an optical touch panel.

The backlight 8007 includes light sources 8008. Note that although a structure in which the light sources 8008 are provided over the backlight 8007 is illustrated in FIG. 52, one embodiment of the present invention is not limited to this structure. For example, a structure in which the light sources 8008 are provided at an end portion of the backlight 8007 and a light diffusion plate is further provided may be employed. Note that the backlight 8007 need not be provided in the case where a self-luminous light-emitting element such as an organic EL element is used or in the case where a reflective panel or the like is employed.

The frame 8009 protects the display panel 8006 and also functions as an electromagnetic shield for blocking electromagnetic waves generated by the operation of the printed board 8010. The frame 8009 may function as a radiator plate.

The printed board 8010 is provided with a power supply circuit and a signal processing circuit for outputting a video signal and a clock signal. As a power source for supplying power to the power supply circuit, an external commercial power source or a power source using the battery 8011 provided separately may be used. The battery 8011 can be omitted in the case of using a commercial power source.

The display module 8000 may be additionally provided with a member such as a polarizing plate, a retardation plate, or a prism sheet.

FIGS. 53A to 53G illustrate electronic devices. These electronic devices can each include a housing 5000, a display portion 5001, a speaker 5003, an LED lamp 5004, an operation key 5005 (including a power switch or an operation switch), a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, power, radiation, flow rate, humidity, gradient, oscillation, odor, or infrared rays), a microphone 5008, and the like.

FIG. 53A illustrates a mobile computer which can include a switch 5009, an infrared port 5010, and the like in addition to the above components. FIG. 53B illustrates a portable image reproducing device (e.g., a DVD player) provided with a memory medium, and the image reproducing device can include a second display portion 5002, a memory medium reading portion 5011, and the like in addition to the above components. FIG. 53C illustrates a goggle-type display which can include the second display portion 5002, a support 5012, an earphone 5013, and the like in addition to the above components. FIG. 53D illustrates a portable game machine which can include the recording medium reading portion 5011 and the like in addition to the above objects. FIG. 53E illustrates a digital camera with a television reception function which can include an antenna 5014, a shutter button 5015, an image reception portion 5016, and the like in addition to the above objects. FIG. 53F illustrates a portable game machine which can include the second display portion 5002, the memory medium reading portion 5011, and the like in addition to the above objects. FIG. 53G illustrates a portable television receiver which can include a charger 5017 capable of transmitting and receiving signals and the like in addition to the above objects.

The electronic appliances illustrated in FIGS. 53A to 53G can have a variety of functions. For example, there are a function of displaying a variety of information (e.g., a still image, a moving image, and a text image) on a display portion, a touch panel function, a function of displaying a calendar, date, time, and the like, a function of controlling processing with a variety of software (programs), a wireless communication function, a function of being connected to a variety of computer networks with a wireless communication function, a function of transmitting and receiving a variety of data with a wireless communication function, and a function of reading program or data stored in a recording medium and displaying the program or data on a display portion. Furthermore, the electronic device including a plurality of display portions can have a function of displaying image information mainly on one display portion while displaying text information on another display portion, a function of displaying a three-dimensional image by displaying images where parallax is considered on a plurality of display portions, or the like. Furthermore, the electronic device including an image receiving portion can have a function of photographing a still image, a function of photographing a moving image, a function of automatically or manually correcting a photographed image, a function of storing a photographed image in a memory medium (an external memory medium or a memory medium incorporated in the camera), a function of displaying a photographed image on the display portion, or the like. Note that functions which can be provided for the electronic devices illustrated in FIGS. 53A to 53G are not limited to the above-described functions, and the electronic devices can have a variety of functions.

Electronic devices described in this embodiment are characterized by having a display portion for displaying some sort of information. The display device described in Embodiment 4 can be applied to the display portion.

The structure described in this embodiment can be used in appropriate combination with the structure described in any of the other embodiments.

### Example

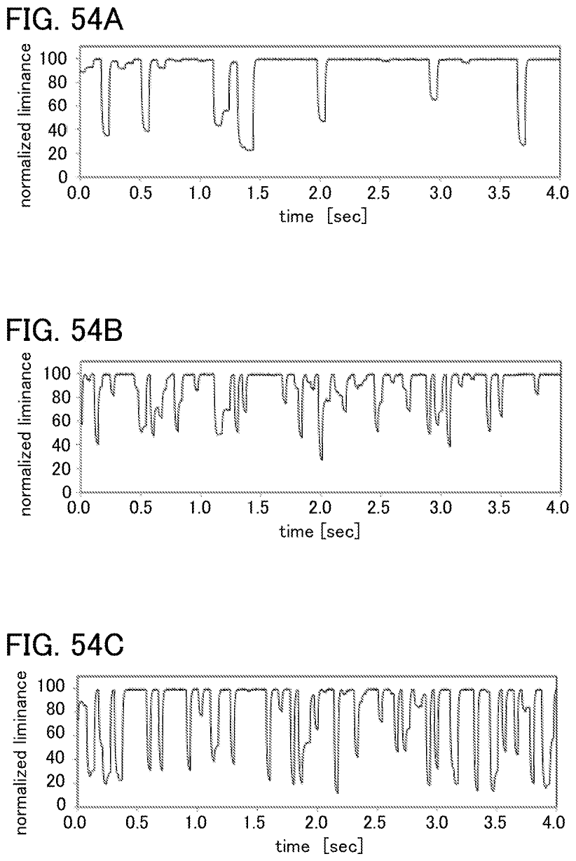

In this example, examination results of the driving method of a display system in Embodiment 9 will be described with reference to FIGS. 54A to 54C, FIGS. 55A to 55C, and FIGS. 56A and 56B.

FIGS. 54A to 54C show the measurement results of luminance changes in a 100-μm diameter-region of a display device. Note that a text image was displayed on the display device while being scrolled. The text image includes 25 lines per page. Each line includes 49 letters with a font size of 20 point.

FIG. 54A shows a change in luminance observed when the text image was displayed while being scrolled at a speed of 2.5 pages/sec.

FIG. 54B shows a change in luminance observed when the letters in the text image were displayed with a higher gray level than those in FIG. 54A. Specifically, the luminance of the letters was approximately 50% of that of the background image while the text image was scrolled at a speed of 5 pages/sec.

FIG. 54C shows a change in luminance observed when the letters in the text image were displayed with the same gray level as those in FIG. 54A while the text image was scrolled at a speed of 5 pages/sec.

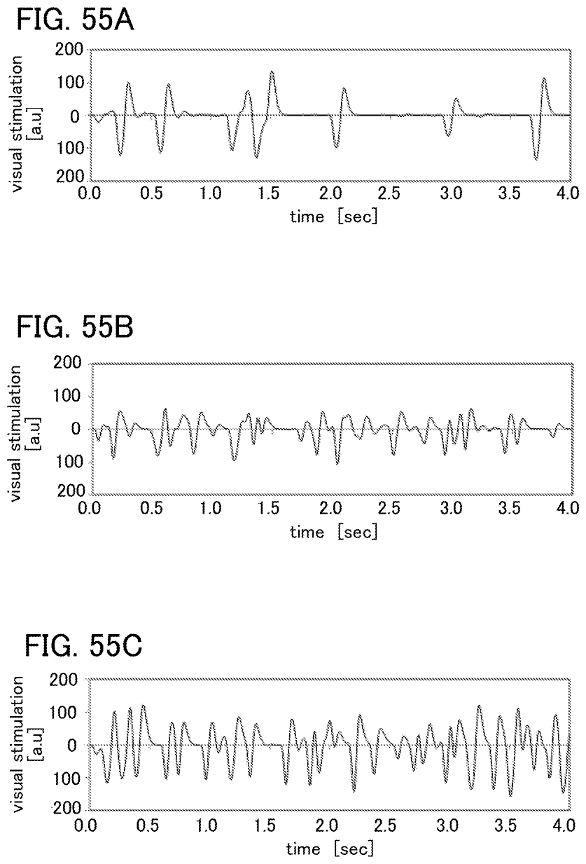

FIGS. 55A to 55C show the calculation results of changes in visual stimulation based on the luminance changes shown in FIGS. 54A to 54C. The calculation was performed using the Barten model, which agrees well with results of previous sensitivity evaluation. The Barten model is shown by the following equation (1).

$$\begin{matrix}[ Formula 1 ] & \\ S ( u , w ) = \frac{\frac{{M}_{opt} ( u )}{k}}{\sqrt{\frac{2}{T} ( \frac{1}{{X}_{0}^{2}} + \frac{1}{{X}_{max}^{2}} + \frac{{u}^{2}}{{N}_{max}^{2}} ) ( \frac{1}{η pE} + \frac{{Φ}_{0}}{{[ {H}_{1} ( w ) \{ 1 - {H}_{2} ( w ) F ( u ) \} ]}^{2}} )}} & ( 1 )\end{matrix}$$

In the equation, u and w are a parameter of the frequency of spatial modulation and a parameter of the frequency of temporal modulation, respectively. In addition, k represents a signal-noise ratio, T represents visual integration time, X₀ represents the size of an object, Xₘₐₓ represents the upper limit of integration, Nₘₐₓ represents the maximum number of integration cycles of bright and dark, η represents quantum efficiency, p represents a quantum conversion factor, E represents retinal illuminance, Φ₀ represents the spectral density of neural noise.

In the equation (1), Mₒₚₜ(u) represents a visual transfer function relating to spatial luminance modulation and is shown by the following equation (2). In the equation (2), σ depends on the pupil diameter as a parameter and corresponds to the standard deviation of a line-spread function, where the structures of visual organs such as the ocular media and the retina are taken into consideration.

[Formula 2]

Mₒₚₜ(u)=e^{-2π}^{²}^{σ}^{²}^{u}^{²} (2)

In the equation (1), H₁(w) and H₂(w) each represent a transfer function relating to temporal modulation and are shown by the following equation (3), where r represents a time constant. The solution of the equation (1) agrees well with the results of sensitivity evaluation in the case where 7 and 4 are substituted for n in H₁(w) and H₂(w), respectively.

$$\begin{matrix}[ Formula 3 ] & \\ H ( w ) = \frac{1}{{\{ 1 + {( 2 π w τ )}^{2} \}}^{n / 2}} & ( 3 )\end{matrix}$$

In addition, F(u) in the equation (1) represents a function of lateral inhibition and is shown by the following equation (4). In the equation (4), u₀ represents the spatial frequency of lateral inhibition.

[Formula 4]

F(u)=1−\sqrt{1−e^{-(u/u}^{₀}⁾^{²}} (4)

FIG. 55A shows the calculation result of the change in visual stimulation based on the luminance change shown in FIG. 54A, which was obtained using the Barten model.

FIG. 55B shows the calculation result of the change in visual stimulation based on the luminance change shown in FIG. 54B, which was obtained using the Barten model.

FIG. 55C shows the calculation result of the change in visual stimulation based on the luminance change shown in FIG. 54C, which was obtained using the Barten model.

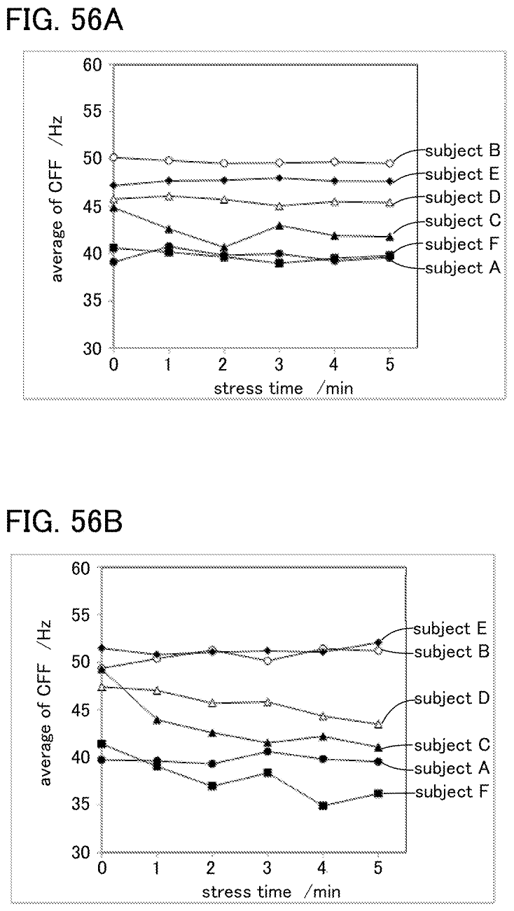

FIGS. 56A and 56B show the measurement results of the critical fusion frequencies (CFF) of six subjects who observed the text images of FIGS. 54A to 54C. Specifically, the text image was observed for a minute while being scrolled, and then, the CFF was measured ten times, and the measurement values were averaged. This process was repeated five times, and added time was counted as time of stressing.

FIG. 56A shows the measurement results of the CFFs of the six subjects who observed the text image of FIG. 54B.

FIG. 56B shows the measurement results of the CFFs of the six subjects who observed the text image of FIG. 54C.

Note that AQUOS PAD SH-06F produced by Sharp Corporation was used and text images are displayed and scrolled. The screen diagonal of the display panel was 7.0 inches, the pixel density was 323 ppi, and each pixel includes a VA-mode liquid crystal element and a transistor including an oxide semiconductor.

For the CFF measurement, a Roken-type digital flicker value tester, model RDF-1 produced by SIBATA SCIENTIFIC TECHNOLOGY LTD. was used.

### <Result>

When compared in the same period, a luminance change at a low scroll speed (FIG. 54A and FIG. 55A) was smaller than that at a high scroll speed (FIG. 54C and FIG. 55C); accordingly, visual stimulation was suppressed when the scroll speed was low.

Comparison between luminance changes at a high scroll speed in the same period (FIGS. 54B and 54C and FIGS. 55B and 55C) showed that a luminance change in the text image displaying letters with a high gray level (i.e., the contrast is low) (FIG. 54B and FIG. 55B) was smaller, and thus, visual stimulation was suppressed.

In addition, decreases in the CFFs of the subjects who repeatedly observed the text image scrolled at a high speed were suppressed when the letters in the text image were displayed with a high gray level (i.e., when the contrast was low) (see FIGS. 56A and 56B).

Therefore, eye strain on the subject accumulated by high-speed scrolling can be reduced by displaying letters with a high gray level (i.e., displaying a low-contrast text image).

Specifically, when the letters with a high gray level (i.e., the low-contrast text image) were displayed, no decrease was observed in the CFFs of the subjects (see FIG. 56A).

On the other hand, when the gray level of letters in the text image was not changed (i.e., the contrast was high), the CFFs of the subject A, the subject C, the subject D, the subject F were decreased (see FIG. 56B).

This application is based on Japanese Patent Application serial no. 2015-040972 filed with Japan Patent Office on Mar. 3, 2015, the entire contents of which are hereby incorporated by reference.

What is claimed is:

1. A liquid crystal display device comprising:
a first oxide semiconductor layer;
a gate electrode overlapping the first oxide semiconductor layer with a first insulating film interposed between the gate electrode and the first oxide semiconductor layer;
a second oxide semiconductor layer overlapping the first oxide semiconductor layer with a second insulating film interposed between the first oxide semiconductor layer and the second oxide semiconductor layer;
a pixel electrode electrically connected to the first oxide semiconductor layer; and
a common electrode including a slit over the pixel electrode,
wherein the second oxide semiconductor layer includes a region overlapping the gate electrode with the second insulating film, the first oxide semiconductor layer, and the first insulating film interposed between the second oxide semiconductor layer and the gate electrode, and
wherein the slit includes a region overlapping the pixel electrode and a region not overlapping the pixel electrode.

2. The liquid crystal display device according to claim 1, wherein each of the first oxide semiconductor layer, the second oxide semiconductor layer and the pixel electrode includes In, Ga and Zn.

3. The liquid crystal display device according to claim 1, wherein the pixel electrode includes a comb-like shape.

4. The liquid crystal display device according to claim 1, wherein a capacitor is formed between the pixel electrode and the common electrode.

5. The liquid crystal display device according to claim 1, wherein the pixel electrode has a higher hydrogen concentration than the first oxide semiconductor layer.
